(19) United States
(12) Patent Application Publication
(10) Pub. No.: US 2025/0040437 A1
(43) Pub. Date: Jan. 30, 2025

(54) HETEROCYCLIC COMPOUND AND ORGANIC LIGHT-EMITTING DEVICE INCLUDING THE SAME

(71) Applicant: Samsung Electronics Co., Ltd., Suwon-si (KR)

(72) Inventors: Yusuke MARUYAMA, Suwon-si (KR); Sangmo KIM, Suwon-si (KR); Jiwhan KIM, Suwon-si (KR); Sungho NAM, Suwon-si (KR); Eunkyung LEE, Suwon-si (KR); Sooghang IHN, Suwon-si (KR); Daun JEONG, Hwaseong-si (KR); Yongsik JUNG, Suwon-si (KR); Jun CHWAE, Suwon-si (KR); Eunsuk KWON, Suwon-si (KR)

(21) Appl. No.: 18/787,326

(22) Filed: Jul. 29, 2024

(30) Foreign Application Priority Data
Jul. 28, 2023 (KR) 10-2023-0098941

(51) Int. Cl. H10K 85/60; C07F 5/02; C09K 11/02; C09K 11/06; H10K 50/12

(52) U.S. Cl. CPC H10K 85/658; C07F 5/027; C09K 11/02; C09K 11/06; H10K 50/121

(57) ABSTRACT

A heterocyclic compound represented by Formula 1 and an organic light-emitting device including the same:

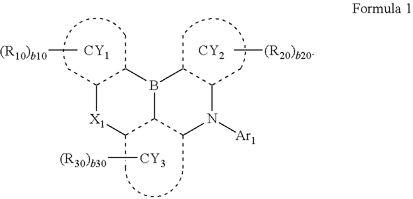

### CROSS-REFERENCE TO RELATED APPLICATION

This application is based on and claims priority under 35 U.S.C. § 119 to Korean Patent Application No. 10-2023-0098941, filed on Jul. 28, 2023, in the Korean Intellectual Property Office, the content of which is herein incorporated by reference in its entirety.

### BACKGROUND

### 1. Field

The disclosure relates to a heterocyclic compound and an organic light-emitting device including the same.

### 2. Description of the Related Art

Organic light-emitting devices are self-emissive devices, which have improved characteristics in terms of viewing angles, response time, brightness, driving voltage, and response speed, and produce full-color images.

OLEDs include an anode, a cathode, and an organic layer between the anode and the cathode and including an emission layer. A hole transport region may be between the anode and the emission layer, and an electron transport region may be between the emission layer and the cathode. Holes provided from the anode may move toward the emission layer through the hole transport region, and electrons provided from the cathode may move toward the emission layer through the electron transport region. The holes and the electrons recombine in the emission layer to produce excitons. The excitons may transition from an excited state to a ground state, thus generating light.

### SUMMARY

Provided are a heterocyclic compound and an organic light-emitting device including the same.

Additional aspects will be set forth in part in the description which follows and, in part, will be apparent from the description, or may be learned by practice of the presented embodiments of the disclosure.

According to an aspect of the disclosure, provided is a heterocyclic compound represented by Formula 1:

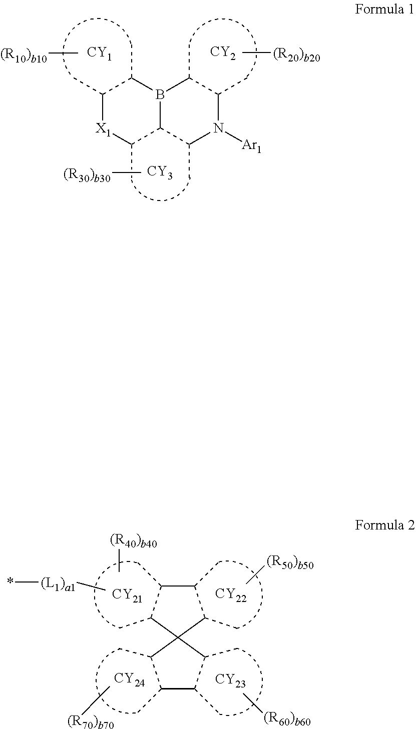

wherein, in Formulae 1 and 2,
X₁ is a single bond, O, S, Se, N(Ar₂), N(R₁), C(R₁)(R₂), Si(R₁)(R₂), Ge(R₁)(R₂), P(R₁), P(═O)(R₁), S(═O)₂, or C(═O),
CY₁ to CY₃ are each independently a C₅-C₃₀ carbocyclic group or a substituted or unsubstituted C₁-C₃₀ heterocyclic group,
Ar₁ and Ar₂ are each independently a group represented by Formula 2,
L₁ is a single bond, a substituted or unsubstituted C₅-C₃₀ carbocyclic group, or a substituted or unsubstituted C₁-C₃₀ heterocyclic group,
a1 is 1, 2, or 3,
CY₂₁ to CY₂₄ are each independently a C₅-C₃₀ carbocyclic group or a substituted or unsubstituted C₁-C₃₀ heterocyclic group,
R₁, R₂, R₁₀, R₂₀, R₃₀, R₄₀, R₅₀, R₆₀, and R₇₀ are each independently a group represented by Formula 2, hydrogen, deuterium, —F, —Cl, —Br, —I, —SF₅, a hydroxyl group, a cyano group, a nitro group, an amidino group, a hydrazino group, a hydrazono group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₇-C₆₀ alkylaryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkylheteroaryl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, a substituted or unsubstituted monovalent non-aromatic condensed heteropolycyclic group, —N(Q₁)(Q₂), —Si(Q₁)(Q₂)(Q₃), —Ge(Q₁)(Q₂)(Q₃), —C(═O)(Q₁), —S(═O)(Q₁), —S(═O)₂(Q₁), —B(Q₁)(Q₂), —P(Q₁)(Q₂), —P(═O)(Q₁)(Q₂), —P(═S)(Q₁)(Q₂), or a group represented by Formula 3,

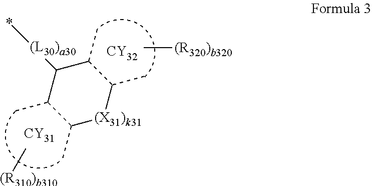

wherein, in Formula 3,
X₃₁ is a single bond, O, S, N(R₃₀₁), or C(R₃₀₁)(R₃₀₂),
k31 is 0 or 1,
CY₃₁ and CY₃₂ are each independently a C₅-C₃₀ carbocyclic group or a C₁-C₃₀ heterocyclic group,
L₃₀ is a single bond, a substituted or unsubstituted C₅-C₃₀ carbocyclic group, or a substituted or unsubstituted C₁-C₃₀ heterocyclic group,
a30 is 0, 1, 2, or 3,
R₃₀₁, R₃₀₂, R₃₁₀, and R₃₂₀ are each independently hydrogen, deuterium, —F, —Cl, —Br, —I, —SF₅, a hydroxyl group, a cyano group, a nitro group, an amidino group, a hydrazino group, a hydrazono group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₇-C₆₀ alkylaryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkylheteroaryl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, a substituted or unsubstituted monovalent non-aromatic condensed heteropolycyclic group, —N(Q₁)(Q₂), —Si(Q₁)(Q₂)(Q₃), —Ge(Q₁)(Q₂)(Q₃), —C(═O)(Q₁), —S(═O)(Q₁), —S(═O)₂(Q₁), —B(Q₁)(Q₂), —P(Q₁)(Q₂), —P(═O)(Q₁)(Q₂), or —P(═S)(Q₁)(Q₂),
b310 and b320 are each independently 1, 2, 3, 4, 5, 6, 7, or 8,
b10, b20, b30, b40, b50, b60, and b70 are each independently 1, 2, 3, 4, 5, 6, 7, 8, 9, 10, 11, 12, 13, or 14,
neighboring two or more of R₁, R₂, R₁₀, R₂₀, R₃₀, R₄₀, R₅₀, R₆₀, R₇₀, R₃₀₁, R₃₀₂, R₃₁₀, and R₃₂₀ are optionally bonded to each other to form a substituted or unsubstituted C₅-C₃₀ carbocyclic group or a substituted or unsubstituted C₁-C₃₀ heterocyclic group,
at least one substituent of the substituted C₅-C₃₀ carbocyclic group, the substituted C₁-C₃₀ heterocyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₁-C₁₀ heterocycloalkyl group, the substituted C₃-C₁₀ cycloalkenyl group, the substituted C₂-C₁₀ heterocycloalkenyl group, the substituted C₆-C₆₀ aryl group, the substituted C₇-C₆₀ alkylaryl group, the substituted C₆-C₆₀ aryloxy group, the substituted C₆-C₆₀ arylthio group, the substituted C₁-C₆₀ heteroaryl group, the substituted C₂-C₆₀ alkylheteroaryl group, the substituted C₁-C₆₀ heteroaryloxy group, the substituted C₁-C₆₀ heteroarylthio group, the substituted monovalent non-aromatic condensed polycyclic group, and the substituted monovalent non-aromatic condensed heteropolycyclic group is
deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, or a C₁-C₆₀ alkoxy group,
a C₁-C₆₀ alkyl group, a C₂-C₆₀ alkenyl group, a C₂-C₆₀ alkynyl group, or a C₁-C₆₀ alkoxy group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₃-C₁₀ cycloalkyl group, a C₁-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₁₁)(Q₁₂), —Si(Q₁₁)(Q₁₂)(Q₁₃), —Ge(Q₁₁)(Q₁₂)(Q₁₃), —C(═O)(Q₁₁), —S(═O)(Q₁₁), —S(═O)₂(Q₁₁), —B(Q₁₁)(Q₁₂), —P(Q₁₁)(Q₁₂), —P(═O)(Q₁₁)(Q₁₂), —P(═S)(Q₁₁)(Q₁₂), or any combination thereof,
a C₃-C₁₀ cycloalkyl group, a C₁-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, or a monovalent non-aromatic condensed heteropolycyclic group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₂₁)(Q₂₂), —Si(Q₂₁)(Q₂₂)(Q₂₃), —Ge(Q₂₁)(Q₂₂)(Q₂₃), —C(═O)(Q₂₁), —S(═O)(Q₂₁), —S(═O)₂(Q₂₁), —B(Q₂₁)(Q₂₂), —P(Q₂₁)(Q₂₂), —P(═O)(Q₂₁)(Q₂₂), —P(═S)(Q₂₁)(Q₂₂), or any combination thereof,
—N(Q₃₁)(Q₃₂), —Si(Q₃₁)(Q₃₂)(Q₃₃), —Ge(Q₃₁)(Q₃₂)(Q₃₃), —C(═O)(Q₃₁), —S(═O)(Q₃₁), —S(═O)₂(Q₃₁), —B(Q₃₁)(Q₃₂), —P(Q₃₁)(Q₃₂), —P(═O)(Q₃₁)(Q₃₂), or —P(Q₃₁)(Q₃₂), or
any combination thereof,
Q₁ to Q₃, Q₁₁ to Q₁₃, Q₂₁ to Q₂₃, and Q₃₁ to Q₃₃ are each independently hydrogen, deuterium, —F, —Cl, —Br, —I, a hydroxyl group, a cyano group, a nitro group, an amidino group, a hydrazine group, a hydrazone group, a carboxylic acid or a salt thereof, a sulfonic acid or a salt thereof, a phosphoric acid or a salt thereof, a C₁-C₆₀ alkyl group unsubstituted or substituted with deuterium, a C₁-C₆₀ alkyl group, a C₆-C₆₀ aryl group, or any combination thereof, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₂-C₁₀ heterocycloalkenyl group, a C₆-C₆₀ aryl group unsubstituted or substituted with deuterium, a C₁-C₆₀ alkyl group, a C₆-C₆₀ aryl group, or any combination thereof, a C₆-C₆₀ aryloxy group, a C₆-C₆₀ arylthio group, a C₁-C₆₀ heteroaryl group, a monovalent non-aromatic condensed polycyclic group, or a monovalent non-aromatic condensed heteropolycyclic group, and
* indicates a binding site to an adjacent atom.

According to another aspect of the disclosure, an organic light-emitting device includes the heterocyclic compound.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic cross-sectional view of an organic light-emitting device according to an embodiment; and

FIGS. 2 to 6 are each a schematic diagram illustrating energy transfer of an organic light-emitting device according to an embodiment.

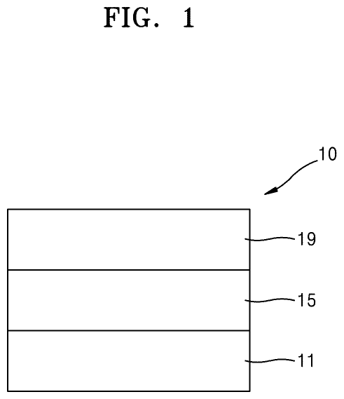

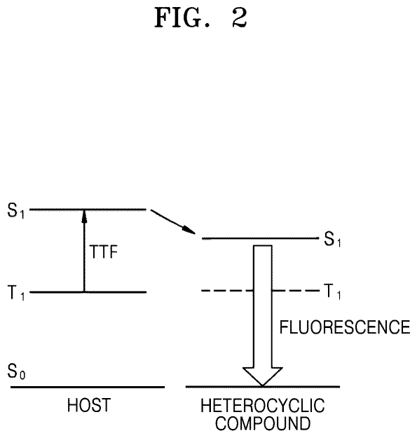

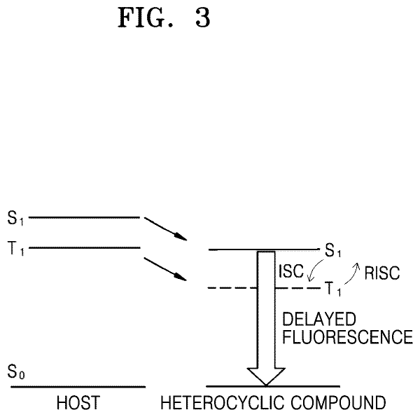

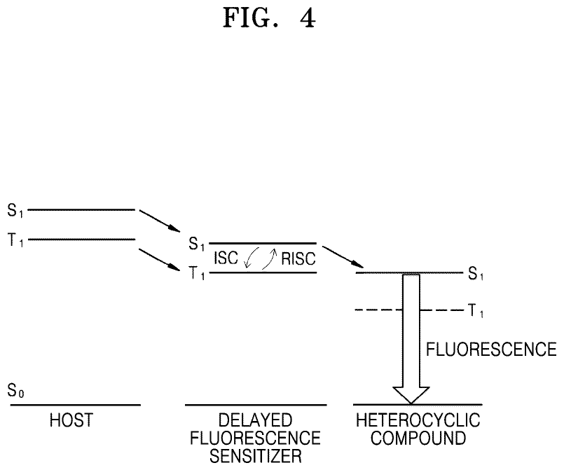

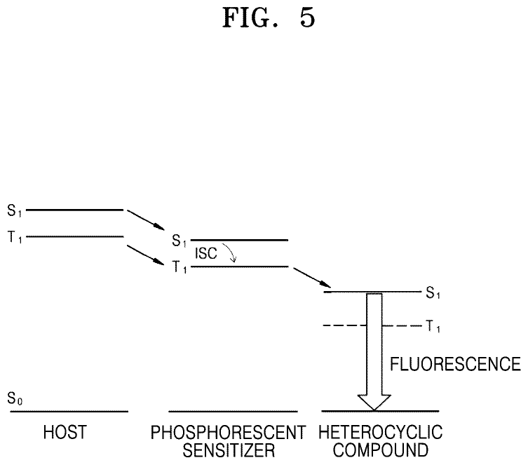

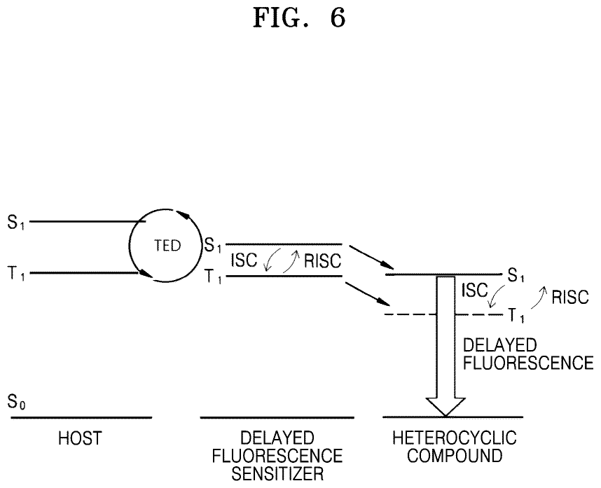

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects.

It will be understood that when an element is referred to as being “on” another element, it can be directly on the other element or intervening elements may be present therebetween In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a,” “an,” “the,” and “at least one” do not denote a limitation of quantity, and are intended to cover both the singular and plural, unless the context clearly indicates otherwise. For example, “an element” has the same meaning as “at least one element,” unless the context clearly indicates otherwise. Expressions such as “at least one of,” when preceding a list of elements, modify the entire list of elements and do not modify the individual elements of the list.

“Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

A heterocyclic compound according to an embodiment may be represented by Formula 1:

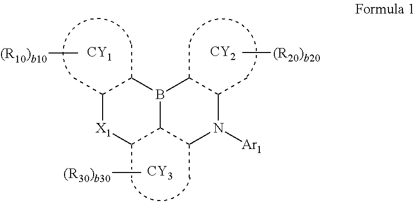

In Formula 1, X₁ may be a single bond, O, S, Se, N(Ar₂), N(R₁), C(R₁)(R₂), Si(R₁)(R₂), Ge(R₁)(R₂), B(R₁), P(R₁), P(═O)(R₁), S(═O)₂, or C(═O).

In an embodiment, X₁ may be a single bond, O, S, Se, N(Ar₂), N(R₁), C(R₁)(R₂), or Si(R₁)(R₂).

In Formula 1, CY₁ to CY₃ may each independently be a C₅-C₃₀ carbocyclic group or a substituted or unsubstituted C₁-C₃₀ heterocyclic group.

In an embodiment, CY₁ to CY₃ may each independently be i) a first ring, ii) a second ring, iii) a condensed ring in which at least two first rings are condensed, iv) a condensed ring in which at least two second rings are condensed, or v) a condensed ring in which at least one first ring is condensed with at least one second ring,
the first ring may be a cyclopentane group, a cyclopentadiene group, a furan group, a thiophene group, a pyrrole group, a silole group, an indene group, a benzofuran group, a benzothiophene group, an indole group, a benzosilole group, an oxazole group, an isoxazole group, an oxadiazole group, an isoxadiazole group, an oxatriazole group, an isoxatriazole group, a thiazole group, an isothiazole group, a thiadiazole group, an isothiadiazole group, a thiatriazole group, an isothiatriazole group, a pyrazole group, an imidazole group, a triazole group, a tetrazole group, an azasilole group, a diazasilole group, or a triazasilole group, and
the second ring may be an adamantane group, a norbornene group, a bicyclo[1.1.1]pentane group, a bicyclo[2.1.1]hexane group, a bicyclo[2.2.1]heptane(norbornane) group, a bicyclo[2.2.2]octane group, a cyclohexane group, a cyclohexene group, a benzene group, a pyridine group, a pyrimidine group, a pyrazine group, a pyridazine group, or a triazine group.

In an embodiment, CY₁ to CY₃ may each independently be a C₆-C₃₀ aromatic carbocyclic group or a C₁-C₃₀ aromatic heterocyclic group.

In an embodiment, CY₁ to CY₃ may each independently be a benzene group, a naphthalene group, an anthracene group, a phenanthrene group, a triphenylene group, a pyrene group, a chrysene group, a 1,2,3,4-tetrahydronaphthalene group, a benzothiophene group, a benzofuran group, an indole group, an indene group, a benzosilole group, a benzoborole group, a benzophosphole group, a benzoselenophene group, a benzogermole group, a dibenzothiophene group, a dibenzofuran group, a carbazole group, a fluorene group, a dibenzosilole group, a dibenzoborole group, a dibenzophosphole group, a dibenzoselenophene group, a dibenzogermole group, a dibenzothiophene 5-oxide group, 9H-fluorene-9-one group, a dibenzothiophene 5,5-dioxide group, an azabenzothiophene group, an azabenzofuran group, an azaindole group, an azaindene group, an azabenzosilole group, an azabenzoborole group, an azabenzophosphole group, an azabenzoselenophene group, an azabenzogermole group, an azadibenzothiophene group, an azadibenzofuran group, an azacarbazole group, an azafluorene group, an azadibenzosilole group, an azadibenzoborole group, an azadibenzophosphole group, an azadibenzoselenophene group, an azadibenzogermole group, an azadibenzothiophene 5-oxide group, an aza-9H-fluoren-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a 5,6,7,8-tetrahydroisoquinoline group, a 5,6,7,8-tetrahydroquinoline group, an adamantane group, a norbornane group, or a norbornene group.

In an embodiment, CY₁ to CY₃ may each independently be a benzene group, a naphthalene group, a phenanthrene group, a fluorene group, a spirobifluorene group, a pyridine group, a pyrimidine group, a quinoline group, an isoquinoline group, a phthalazine group, a naphthyridine group, a quinoxaline group, a quinazoline group, a carbazole group, a dibenzofuran group, a dibenzothiophene group, a dibenzosilole group, a dibenzoborole group, a dibenzophosphole group, a dibenzoselenophene group, a dibenzogermole group, a dibenzothiophene 5-oxide group, 9H-fluoren-9-one group, or a dibenzothiophene 5,5-dioxide group.

In an embodiment, CY₁ and CY₂ may each independently be a group represented by any one of Formulae 1-1 to 1-9:

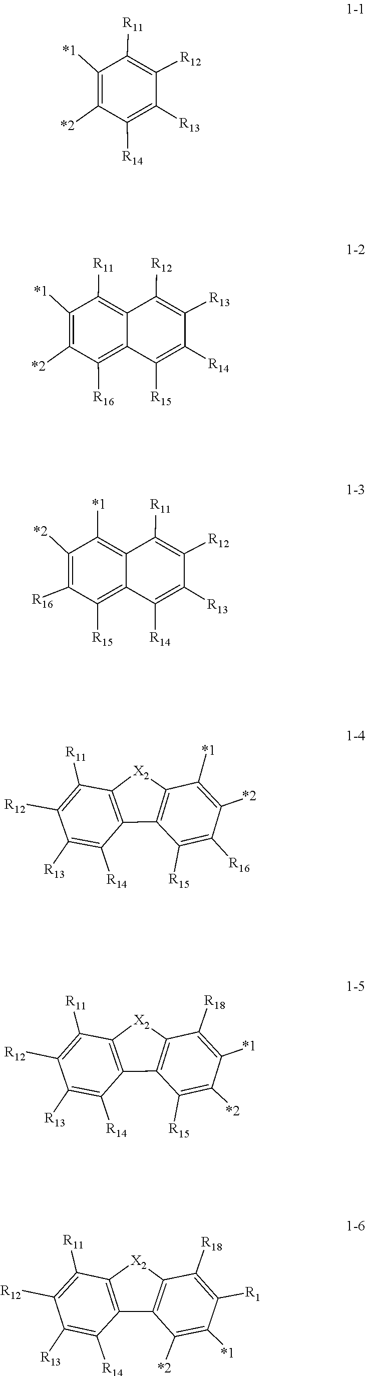

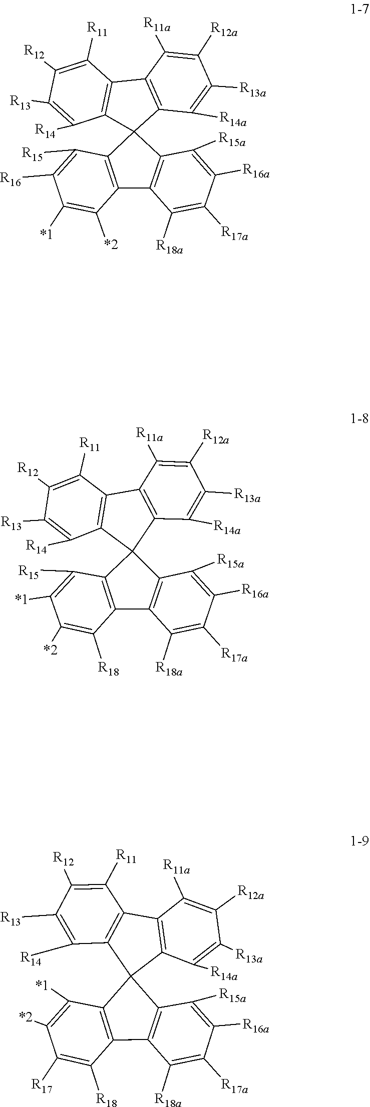

wherein, in Formulae 1-1 to 1-9,
R₁₁ to R₁₈ and R₁₁ₐ to R₁₈ₐ are each independently the same as described in connection with R₁₀,
X₂ may be O, S, Se, N(R₃), C(R₃)(R₄), Si(R₃)(R₄), Ge(R₃)(R₄), B(R₃), P(R₃), P(═O)(R₃), S(═O)₂, or C(═O),
R₃ and R₄ are each independently the same as described in connection with R₁, and
^{*1} and ^{*2} each indicate a binding site to an adjacent atom.

In an embodiment, any one of ^{*1} and ^{*2} in Formulae 1-1 to 1-9 may be a binding site to a B atom in Formula 1.

For example, ^{*1} in Formulae 1-1 to 1-9 may be a binding site to a B atom in Formula 1.

In another example, ^{*2} in Formulae 1-1 to 1-9 may be a binding site to a B atom in Formula 1.

In Formula 2, CY₂₁ to CY₂₄ may each independently be a C₅-C₃₀ carbocyclic group or a substituted or unsubstituted C₁-C₃₀ heterocyclic group.

In an embodiment, CY₂₁ to CY₂₄ may each independently be i) a first ring, ii) a second ring, iii) a condensed ring in which at least two first rings are condensed, iv) a condensed ring in which at least two second rings are condensed, or v) a condensed ring in which at least one first ring is condensed with at least one second ring,
the first ring may be a cyclopentane group, a cyclopentadiene group, a furan group, a thiophene group, a pyrrole group, a silole group, an indene group, a benzofuran group, a benzothiophene group, an indole group, a benzosilole group, an oxazole group, an isoxazole group, an oxadiazole group, an isoxadiazole group, an oxatriazole group, an isoxatriazole group, a thiazole group, an isothiazole group, a thiadiazole group, an isothiadiazole group, a thiatriazole group, an isothiatriazole group, a pyrazole group, an imidazole group, a triazole group, a tetrazole group, an azasilole group, a diazasilole group, or a triazasilole group, and
the second ring may be an adamantane group, a norbornene group, a bicyclo[1.1.1]pentane group, a bicyclo[2.1.1]hexane group, a bicyclo[2.2.1]heptane(norbornane) group, a bicyclo[2.2.2]octane group, a cyclohexane group, a cyclohexene group, a benzene group, a pyridine group, a pyrimidine group, a pyrazine group, a pyridazine group, or a triazine group.

In an embodiment, CY₂₁ to CY₂₄ may each independently be a C₆-C₃₀ aromatic carbocyclic group or a C₁-C₃₀ aromatic heterocyclic group.

In an embodiment, CY₂₁ to CY₂₄ may each independently be a benzene group, a naphthalene group, an anthracene group, a phenanthrene group, a triphenylene group, a pyrene group, a chrysene group, a 1,2,3,4-tetrahydronaphthalene group, a benzothiophene group, a benzofuran group, an indole group, an indene group, a benzosilole group, a benzoborole group, a benzophosphole group, a benzoselenophene group, a benzogermole group, a dibenzothiophene group, a dibenzofuran group, a carbazole group, a fluorene group, a dibenzosilole group, a dibenzoborole group, a dibenzophosphole group, a dibenzoselenophene group, a dibenzogermole group, a dibenzothiophene 5-oxide group, 9H-fluoren-9-one group, a dibenzothiophene 5,5-dioxide group, an azabenzothiophene group, an azabenzofuran group, an azaindole group, an azaindene group, an azabenzosilole group, an azabenzoborole group, an azabenzophosphole group, an azabenzoselenophene group, an azabenzogermole group, an azadibenzothiophene group, an azadibenzofuran group, an azacarbazole group, an azafluorene group, an azadibenzosilole group, an azadibenzoborole group, an azadibenzophosphole group, an azadibenzoselenophene group, an azadibenzogermole group, an azadibenzothiophene 5-oxide group, an aza-9H-fluoren-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a 5,6,7,8-tetrahydroisoquinoline group, a 5,6,7,8-tetrahydroquinoline group, an adamantane group, a norbornane group, or a norbornene group.

In an embodiment, CY₂₁ to CY₂₄ may each independently be a benzene group, a naphthalene group, a phenanthrene group, a pyridine group, a pyrimidine group, a quinoline group, an isoquinoline group, a phthalazine group, a naphthyridine group, a quinoxaline group, or a quinazoline group.

In an embodiment, CY₂₁ to CY₂₄ may each be a benzene group.

In an embodiment, a group represented by Formula 2 may be a group represented by any one of Formulae 2A to 2D:

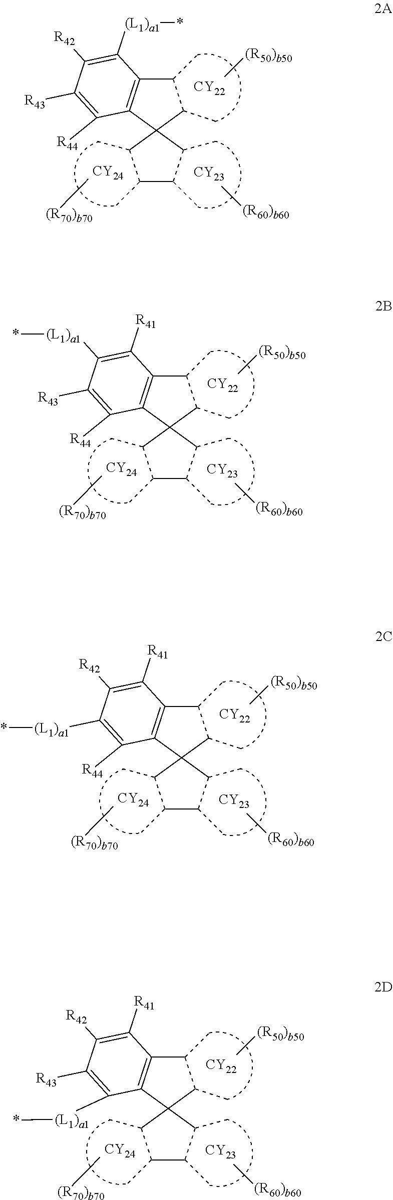

wherein, in Formulae 2A to 2D,
CY₂₂ to CY₂₄ , L₁, a1, R₅₀, R₆₀, R₇₀, b50, b60, and b70 are each the same as described above,
R₄₁ to R₄₄ are each the same as described in connection with R₄₀, and
* indicates a binding site to an adjacent atom.

In an embodiment, a group represented by Formula 2 may be a group represented by any one of Formulae 2-1 to 2-4:

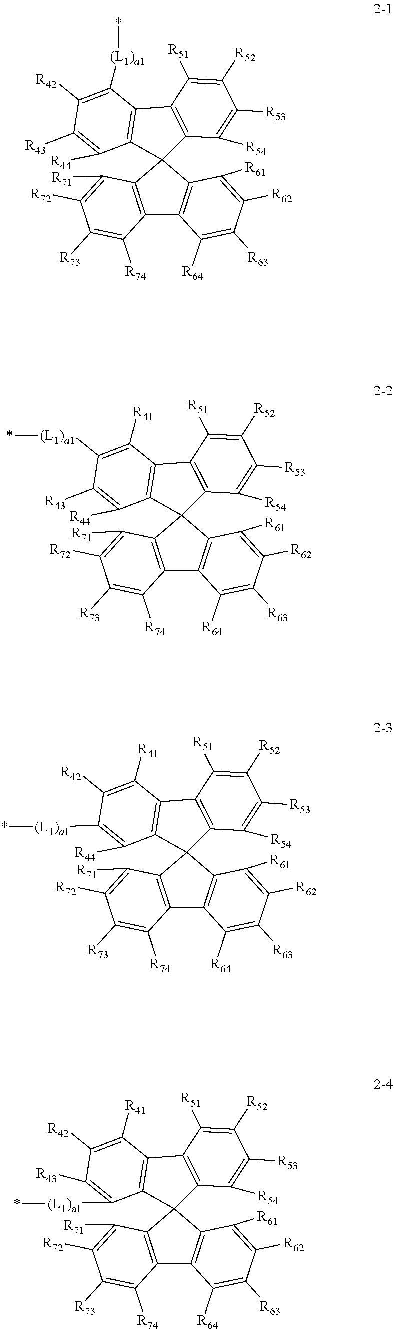

wherein, in Formulae 2-1 to 2-4,
L₁ and a1 are each the same as described above,
R₄₁ to R₄₄ are each the same as described in connection with R₄₀,
R₅₁ to R₅₄ are each the same as described in connection with R₅₀,
R₆₁ to R₆₄ are each the same as described in connection with R₆₀,
R₇₁ to R₇₄ are each the same as described in connection with R₇₀, and
* indicates a binding site to an adjacent atom.

In Formula 2, L₁ may be a single bond, a substituted or unsubstituted C₅-C₃₀ carbocyclic group, or a substituted or unsubstituted C₁-C₃₀ heterocyclic group.

In an embodiment, L₁ may be a single bond, a phenylene group, a naphthylene group, a phenanthrenylene group, a fluorenylene group, or a pyrenylene group; or
a phenylene group, a naphthylene group, a phenanthrenylene group, a fluorenylene group, or a pyrenylene group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, deuterium-containing C₁-C₂₀ alkyl group, a fluorinated C₁-C₂₀ alkyl group, a C₁-C₂₀ alkoxy group, a phenyl group, a naphthyl group, an anthracenyl group, or any combination thereof.

In an embodiment, L₁ may be a single bond.

In Formula 2, a1 may be 1, 2, or 3.

In an embodiment, a1 may be 1.

In Formula 2, * indicates a binding site to an adjacent atom.

In Formulae 1 and 2, R₁, R₂, R₁₀, R₂₀, R₃₀, R₄₀, R₅₀, R₆₀, and R₇₀ may each independently be a group represented by Formula 2, hydrogen, deuterium, —F, —Cl, —Br, —I, —SF₅, a hydroxyl group, a cyano group, a nitro group, an amidino group, a hydrazino group, a hydrazono group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₇-C₆₀ alkylaryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkylheteroaryl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, a substituted or unsubstituted monovalent non-aromatic condensed heteropolycyclic group, —N(Q₁)(Q₂), —Si(Q₁)(Q₂)(Q₃), —Ge(Q₁)(Q₂)(Q₃), —C(═O)(Q₁), —S(═O)(Q₁), —S(═O)₂(Q₁), —B(Q₁)(Q₂), —P(Q₁)(Q₂), —P(═O)(Q₁)(Q₂), —P(═S)(Q₁)(Q₂), or a group represented by Formula 3:

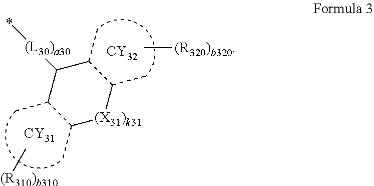

In Formula 3, X₃₁ may be a single bond, O, S, N(R₃₀₁), or C(R₃₀₁)(R₃₀₂).

In Formula 3, k31 may be 0 or 1. When k31 is 0, (X₃₁)k₃₁ is absent.

In Formula 3, CY₃₁ and CY₃₂ may each independently be a C₅-C₃₀ carbocyclic group or a C₁-C₃₀ heterocyclic group.

In an embodiment, CY₃₁ and CY₃₂ may each independently be a benzene group, a naphthalene group, a 1,2,3,4-tetrahydronaphthalene group, a thiophene group, a furan group, a pyrrole group, a cyclopentadiene group, a silole group, a benzothiophene group, a benzofuran group, an indole group, an indene group, a benzosilole group, a dibenzothiophene group, a dibenzofuran group, a carbazole group, a fluorene group, or a dibenzosilole group.

In Formula 3, L₃₀ may be a single bond, a substituted or unsubstituted C₅-C₃₀ carbocyclic group, or a substituted or unsubstituted C₁-C₃₀ heterocyclic group.

In Formula 3, a30 may be 0, 1, 2, or 3.

In an embodiment, a30 may be 0 or 1.

In Formula 3, R₃₀₁, R₃₀₂, R₃₁₀, and R₃₂₀ may each independently be hydrogen, deuterium, —F, —Cl, —Br, —I, —SF₅, a hydroxyl group, a cyano group, a nitro group, an amidino group, a hydrazino group, a hydrazono group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₇-C₆₀ alkylaryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkylheteroaryl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, a substituted or unsubstituted monovalent non-aromatic condensed heteropolycyclic group, —N(Q₁)(Q₂), —Si(Q₁)(Q₂)(Q₃), —Ge(Q₁)(Q₂)(Q₃), —C(═O)(Q₁), —S(═O)(Q₁), —S(═O)₂(Q₁), —B(Q₁)(Q₂), —P(Q₁)(Q₂), —P(═O)(Q₁)(Q₂), or —P(═S)(Q₁)(Q₂).

In an embodiment, R₃₀₁, R₃₀₂, R₃₁₀, and R₃₂₀ may each independently be:
hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, —SF₅, a C₁-C₂₀ alkyl group, or a C₁-C₂₀ alkoxy group;
a C₁-C₂₀ alkyl group or a C₁-C₂₀ alkoxy group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a deuterium-containing C₁-C₂₀ alkyl group, a fluorinated C₁-C₂₀ alkyl group, a cyclopentyl group, a cyclohexyl group, a cycloheptyl group, a cyclooctyl group, an adamantanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group(norbornanyl group), a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.1]heptyl group, a (C₁-C₂₀ alkyl)bicyclo[2.2.2]octyl group, a silolanyl group, a phenyl group, a (C₁-C₂₀ alkyl)phenyl group, a biphenyl group, a terphenyl group, a naphthyl group, a 1,2,3,4-tetrahydronaphthyl group, a pyridinyl group, a pyrimidinyl group, or any combination thereof;
a cyclopentyl group, a cyclohexyl group, a cycloheptyl group, a cyclooctyl group, an adamantanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a silolanyl group, a phenyl group, a (C₁-C₂₀ alkyl)phenyl group, a biphenyl group, a terphenyl group, a naphthyl group, a 1,2,3,4-tetrahydronaphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, or an azadibenzothiophenyl group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a deuterium-containing C₁-C₂₀ alkyl group, a fluorinated C₁-C₂₀ alkyl group, a C₁-C₂₀ alkoxy group, a cyclopentyl group, a cyclohexyl group, a cycloheptyl group, a cyclooctyl group, an adamantanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.1]heptyl group, a (C₁-C₂₀ alkyl)bicyclo[2.2.2]octyl group, a silolanyl group, a phenyl group, a (C₁-C₂₀ alkyl)phenyl group, a biphenyl group, a terphenyl group, a naphthyl group, a 1,2,3,4-tetrahydronaphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, or any combination thereof; or
—N(Q₁)(Q₂), —Si(Q₁)(Q₂)(Q₃), —Ge(Q₁)(Q₂)(Q₃), —C(═O)(Q₁), —S(═O)(Q₁), —S(═O)₂(Q₁), —B(Q₁)(Q₂), —P(Q₁)(Q₂), —P(═O)(Q₁)(Q₂), or —P(═S)(Q₁)(Q₂).

In an embodiment, R₃₀₁, R₃₀₂, R₃₁₀, and R₃₂₀ may each independently be hydrogen, deuterium, a methyl group, an ethyl group, an n-propyl group, an iso-propyl group, an n-butyl group, an isobutyl group, a sec-butyl group, a tert-butyl group, an n-pentyl group, an isopentyl group, a 2-methylbutyl group, a sec-pentyl group, a tert-pentyl group, a neo-pentyl group, a 3-pentyl group, a 3-methyl-2-butyl group, a phenyl group, a biphenyl group, a C₁-C₂₀ alkylphenyl group, or a naphthyl group.

In Formula 3, b310 and b320 may each independently be 1, 2, 3, 4, 5, 6, 7, or 8.

In an embodiment, R₁, R₂, R₁₀, R₂₀, R₃₀, R₄₀, R₅₀, R₆₀, and R₇₀ may each independently be: a group represented by Formula 2, a group represented by Formula 3, hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, —SF₅, a C₁-C₂₀ alkyl group, or a C₁-C₂₀ alkoxy group;
a C₁-C₂₀ alkyl group or a C₁-C₂₀ alkoxy group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a deuterium-containing C₁-C₂₀ alkyl group, a fluorinated C₁-C₂₀ alkyl group, a cyclopentyl group, a cyclohexyl group, a cycloheptyl group, a cyclooctyl group, an adamantanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group (norbornanyl group), a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.1]heptyl group, a (C₁-C₂₀ alkyl)bicyclo[2.2.2]octyl group, a silolanyl group, a phenyl group, a (C₁-C₂₀ alkyl)phenyl group, a biphenyl group, a terphenyl group, a naphthyl group, a 1,2,3,4-tetrahydronaphthyl group, a pyridinyl group, a pyrimidinyl group, or any combination thereof;
a cyclopentyl group, a cyclohexyl group, a cycloheptyl group, a cyclooctyl group, an adamantanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a silolanyl group, a phenyl group, a (C₁-C₂₀ alkyl)phenyl group, a biphenyl group, a terphenyl group, a naphthyl group, a 1,2,3,4-tetrahydronaphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, or an azadibenzothiophenyl group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a deuterium-containing C₁-C₂₀ alkyl group, a fluorinated C₁-C₂₀ alkyl group, a C₁-C₂₀ alkoxy group, a cyclopentyl group, a cyclohexyl group, a cycloheptyl group, a cyclooctyl group, an adamantanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.1]heptyl group, a (C₁-C₂₀ alkyl)bicyclo[2.2.2]octyl group, a silolanyl group, a phenyl group, a (C₁-C₂₀ alkyl)phenyl group, a biphenyl group, a terphenyl group, a naphthyl group, a 1,2,3,4-tetrahydronaphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, or any combination thereof; or

—N(Q₁)(Q₂), —Si(Q₁)(Q₂)(Q₃), —Ge(Q₁)(Q₂)(Q₃), —C(═O)(Q₁), —S(═O)(Q₁), —S(═O)₂(Q₁), —B(Q₁)(Q₂), —P(Q₁)(Q₂), —P(═O)(Q₁)(Q₂), or —P(═S)(Q₁)(Q₂).

In an embodiment, R₁, R₂, R₁₀, R₂₀, R₃₀, R₄₀, R₅₀, R₆₀, and R₇₀ may each independently be:
a group represented by Formula 2, a group represented by Formula 3, hydrogen, deuterium, —F, —Cl, —Br, —I, —CD₃, —CD₂H, —CDH₂, —CF₃, —CF₂H, —CFH₂, a C₁-C₆₀ alkyl group, a C₂-C₆₀ alkenyl group, a C₂-C₆₀ alkynyl group, or a C₁-C₆₀ alkoxy group; or
a group represented by any one of Formulae 9-1 to 9-61, 9-201 to 9-244, 10-1 to 10-154, and 10-201 to 10-350:

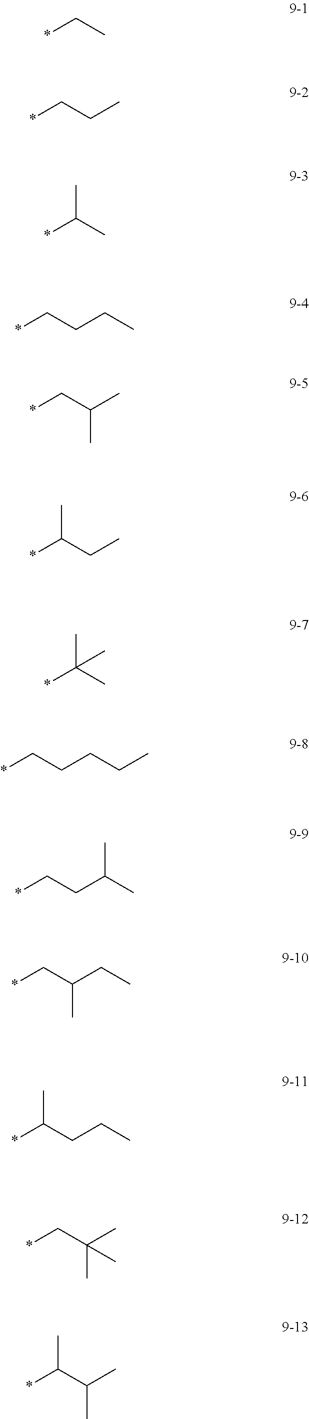

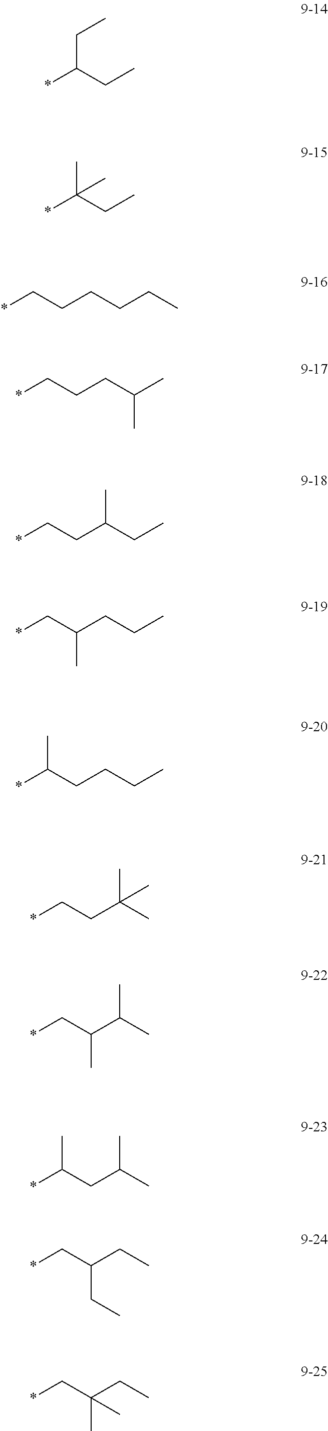

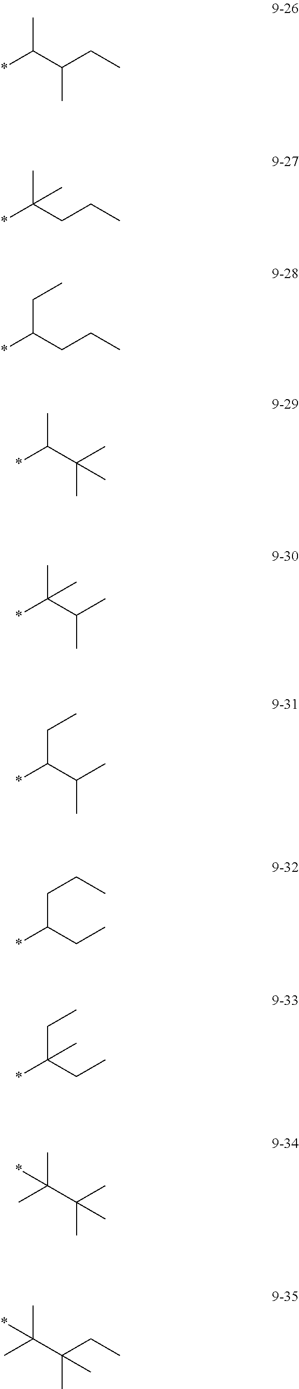

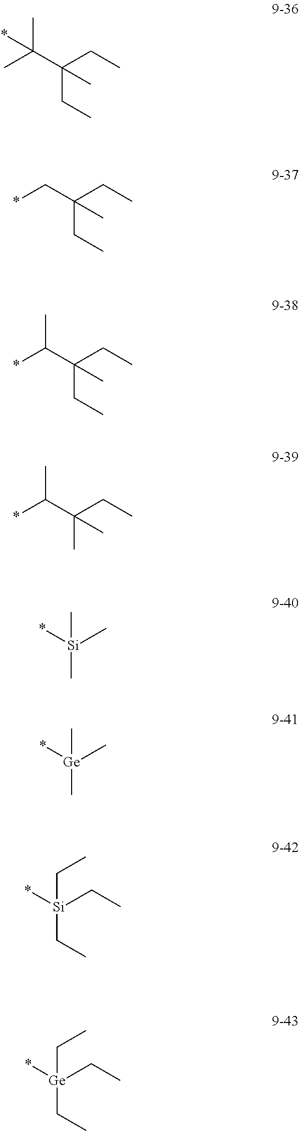

What is claimed is:

1. A heterocyclic compound represented by Formula 1: 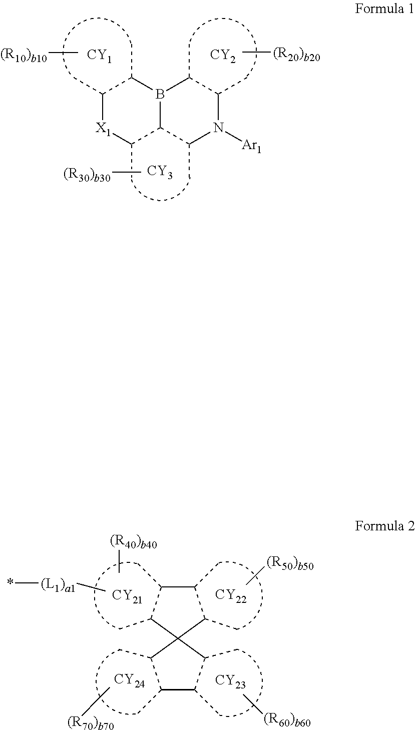
wherein, in Formulae 1 and 2,
X₁ is a single bond, O, S, Se, N(Ar₂), N(R₁), C(R₁)(R₂), Si(R₁)(R₂), Ge(R₁)(R₂), B(R₁), P(R₁), P(═O)(R₁), S(═O)₂, or C(═O),
CY₁ to CY₃ are each independently a C₅-C₃₀ carbocyclic group or a substituted or unsubstituted C₁-C₃₀ heterocyclic group,
Ar₁ and Ar₂ are each independently a group represented by Formula 2,
L₁ is a single bond, a substituted or unsubstituted C₅-C₃₀ carbocyclic group, or a substituted or unsubstituted C₁-C₃₀ heterocyclic group,
a1 is 1, 2, or 3,
CY₂₁ to CY₂₄ are each independently a C₅-C₃₀ carbocyclic group or a substituted or unsubstituted C₁-C₃₀ heterocyclic group,
R₁, R₂, R₁₀, R₂₀, R₃₀, R₄₀, R₅₀, R₆₀, and R₇₀ are each independently a group represented by Formula 2, hydrogen, deuterium, —F, —Cl, —Br, —I, —SF₅, a hydroxyl group, a cyano group, a nitro group, an amidino group, a hydrazino group, a hydrazono group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₇-C₆₀ alkylaryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkylheteroaryl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, a substituted or unsubstituted monovalent non-aromatic condensed heteropolycyclic group, —N(Q₁)(Q₂), —Si(Q₁)(Q₂)(Q₃), —Ge(Q₁)(Q₂)(Q₃), —C(═O)(Q₁), —S(═O)(Q₁), —S(═O)₂(Q₁), —B(Q₁)(Q₂), —P(Q₁)(Q₂), —P(═O)(Q₁)(Q₂), —P(═S)(Q₁)(Q₂), or a group represented by Formula 3, 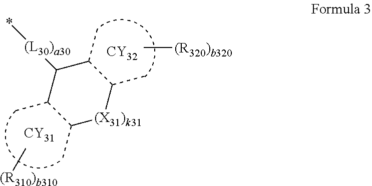
wherein, in Formula 3,
X₃₁ is a single bond, O, S, N(R₃₀₁), or C(R₃₀₁)(R₃₀₂),
k31 is 0 or 1,
CY₃₁ and CY₃₂ are each independently a C₅-C₃₀ carbocyclic group or a C₁-C₃₀ heterocyclic group,
L₃₀ is a single bond, a substituted or unsubstituted C₅-C₃₀ carbocyclic group, or a substituted or unsubstituted C₁-C₃₀ heterocyclic group,
a30 is 0, 1, 2, or 3,
R₃₀₁, R₃₀₂, R₃₁₀, and R₃₂₀ are each independently hydrogen, deuterium, —F, —Cl, —Br, —I, —SF₅, a hydroxyl group, a cyano group, a nitro group, an amidino group, a hydrazino group, a hydrazono group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₇-C₆₀ alkylaryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted C₂-C₆₀ alkylheteroaryl group, a substituted or unsubstituted C₁-C₆₀ heteroaryloxy group, a substituted or unsubstituted C₁-C₆₀ heteroarylthio group, a substituted or unsubstituted monovalent non-aromatic condensed polycyclic group, a substituted or unsubstituted monovalent non-aromatic condensed heteropolycyclic group, —N(Q₁)(Q₂), —Si(Q₁)(Q₂)(Q₃), —Ge(Q₁)(Q₂)(Q₃), —C(═O)(Q₁), —S(═O)(Q₁), —S(═O)₂(Q₁), —B(Q₁)(Q₂), —P(Q₁)(Q₂), —P(═O)(Q₁)(Q₂), or —P(═S)(Q₁)(Q₂),
b310 and b320 are each independently 1, 2, 3, 4, 5, 6, 7, or 8,
b10, b20, b30, b40, b50, b60, and b70 are each independently 1, 2, 3, 4, 5, 6, 7, 8, 9, 10, 11, 12, 13, or 14,
neighboring two or more of R₁, R₂, R₁₀, R₂₀, R₃₀, R₄₀, R₅₀, R₆₀, R₇₀, R₃₀₁, R₃₀₂, R₃₁₀, and R₃₂₀ are optionally bonded to each other to form a substituted or unsubstituted C₅-C₃₀ carbocyclic group or a C₁-C₃₀ heterocyclic group,
at least one substituent of the substituted C₅-C₃₀ carbocyclic group, the substituted C₁-C₃₀ heterocyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₁-C₁₀ heterocycloalkyl group, the substituted C₃-C₁₀ cycloalkenyl group, the substituted C₂-C₁₀ heterocycloalkenyl group, the substituted C₆-C₆₀ aryl group, the substituted C₇-C₆₀ alkylaryl group, the substituted C₆-C₆₀ aryloxy group, the substituted C₆-C₆₀ arylthio group, the substituted C₁-C₆₀ heteroaryl group, the substituted C₂-C₆₀ alkylheteroaryl group, the substituted C₁-C₆₀ heteroaryloxy group, the substituted C₁-C₆₀ heteroarylthio group, the substituted monovalent non-aromatic condensed polycyclic group, and the substituted monovalent non-aromatic condensed heteropolycyclic group is:
deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, or a C₁-C₆₀ alkoxy group;
a C₁-C₆₀ alkyl group, a C₂-C₆₀ alkenyl group, a C₂-C₆₀ alkynyl group, or a C₁-C₆₀ alkoxy group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₃-C₁₀ cycloalkyl group, a C₁-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₁₁)(Q₁₂), —Si(Q₁₁)(Q₁₂)(Q₁₃), —Ge(Q₁₁)(Q₁₂)(Q₁₃), —C(═O)(Q₁₁), —S(═O)(Q₁₁), —S(═O)₂(Q₁₁), —B(Q₁₁)(Q₁₂), —P(Q₁₁)(Q₁₂), —P(═O)(Q₁₁)(Q₁₂), —P(═S)(Q₁₁)(Q₁₂), or any combination thereof;
a C₃-C₁₀ cycloalkyl group, a C₁-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, or a monovalent non-aromatic condensed heteropolycyclic group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₂₁)(Q₂₂), —Si(Q₂₁)(Q₂₂)(Q₂₃), —Ge(Q₂₁)(Q₂₂)(Q₂₃), —C(═O)(Q₂₁), —S(═O)(Q₂₁), —S(═O)₂(Q₂₁), —B(Q₂₁)(Q₂₂), —P(Q₂₁)(Q₂₂), —P(═O)(Q₂₁)(Q₂₂), —P(═S)(Q₂₁)(Q₂₂), or any combination thereof;
—N(Q₃₁)(Q₃₂), —Si(Q₃₁)(Q₃₂)(Q₃₃), —Ge(Q₃₁)(Q₃₂)(Q₃₃), —C(═O)(Q₃₁), —S(═O)(Q₃₁), —S(═O)₂(Q₃₁), —B(Q₃₁)(Q₃₂), —P(Q₃₁)(Q₃₂), —P(═O)(Q₃₁)(Q₃₂), or —P(Q₃₁)(Q₃₂); or
any combination thereof,
Q₁ to Q₃, Q₁₁ to Q₁₃, Q₂₁ to Q₂₃, and Q₃₁ to Q₃₃ are each independently: hydrogen; deuterium; —F; —Cl; —Br; —I; a hydroxyl group; a cyano group; a nitro group; an amidino group; a hydrazine group; a hydrazone group; a carboxylic acid group or a salt thereof; a sulfonic acid group or a salt thereof; a phosphoric acid group or a salt thereof; a C₁-C₆₀ alkyl group unsubstituted or substituted with deuterium, a C₁-C₆₀ alkyl group, a C₆-C₆₀ aryl group, or any combination thereof; a C₂-C₆₀ alkenyl group; a C₂-C₆₀ alkynyl group; a C₁-C₆₀ alkoxy group; a C₃-C₁₀ cycloalkyl group; a C₁-C₁₀ heterocycloalkyl group; a C₃-C₁₀ cycloalkenyl group; a C₂-C₁₀ heterocycloalkenyl group; a C₆-C₆₀ aryl group unsubstituted or substituted with deuterium, a C₁-C₆₀ alkyl group, a C₆-C₆₀ aryl group, or any combination thereof; a C₆-C₆₀ aryloxy group; a C₆-C₆₀ arylthio group; a C₁-C₆₀ heteroaryl group; a monovalent non-aromatic condensed polycyclic group; or a monovalent non-aromatic condensed heteropolycyclic group, and
* indicates a binding site to an adjacent atom.

2. The heterocyclic compound of claim 1, wherein CY₁ to CY₃ are each independently a benzene group, a naphthalene group, a phenanthrene group, a fluorene group, a spirobifluorene group, a pyridine group, a pyrimidine group, a quinoline group, an isoquinoline group, a phthalazine group, a naphthyridine group, a quinoxaline group, a quinazoline group, a carbazole group, a dibenzofuran group, a dibenzothiophene group, a dibenzosilole group, a dibenzoborole group, a dibenzophosphole group, a dibenzoselenophene group, a dibenzogermole group, a dibenzothiophene 5-oxide group, 9H-fluoren-9-one group, or a dibenzothiophene 5,5-dioxide group.

3. The heterocyclic compound of claim 1, wherein CY₁ and CY₂ are each independently a group represented by any one of Formulae 1-1 to 1-9: 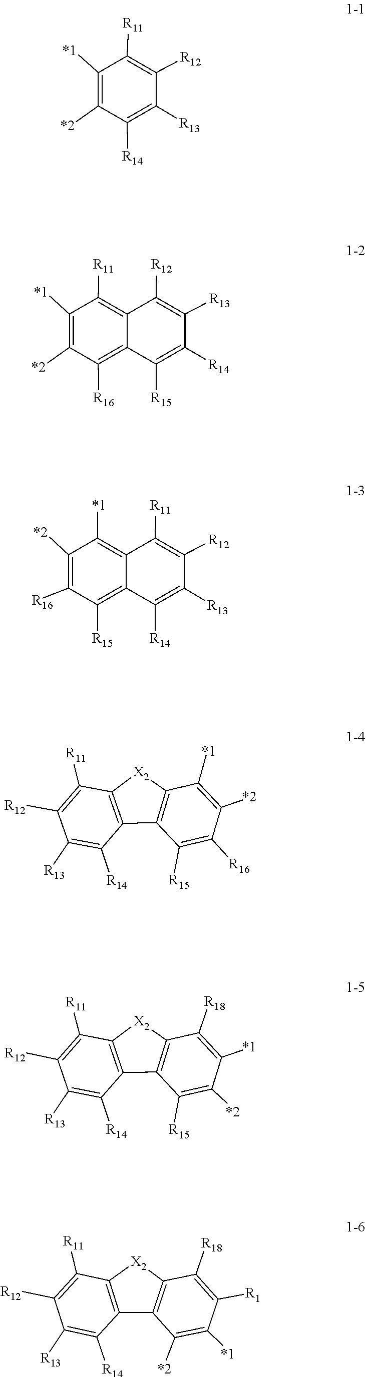 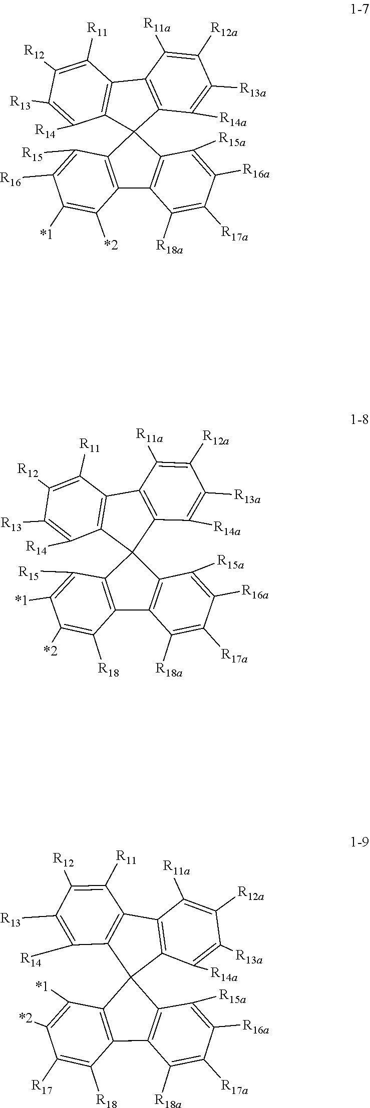
wherein, in Formulae 1-1 to 1-9,
R₁₁ to R₁₈ and R₁₁ₐ to R₁₈ₐ are each independently as described in connection with R₁₀ in claim 1,
X₂ is O, S, Se, N(R₃), C(R₃)(R₄), Si(R₃)(R₄), Ge(R₃)(R₄), B(R₃), P(R₃), P(═O)(R₃), S(═O)₃, or C(═O),
R₃ and R₄ are each independently as described in connection with R₁ in claim 1, and
^{*1} and ^{*2} each indicate a binding site to an adjacent atom.

4. The heterocyclic compound of claim 1, wherein CY₂₁ to CY₂₄ are each independently a benzene group, a naphthalene group, a phenanthrene group, a pyridine group, a pyrimidine group, a quinoline group, an isoquinoline group, a phthalazine group, a naphthyridine group, a quinoxaline group, or a quinazoline group.

5. The heterocyclic compound of claim 1, wherein the group represented by Formula 2 is a group represented by any one of Formulae 2A to 2D: 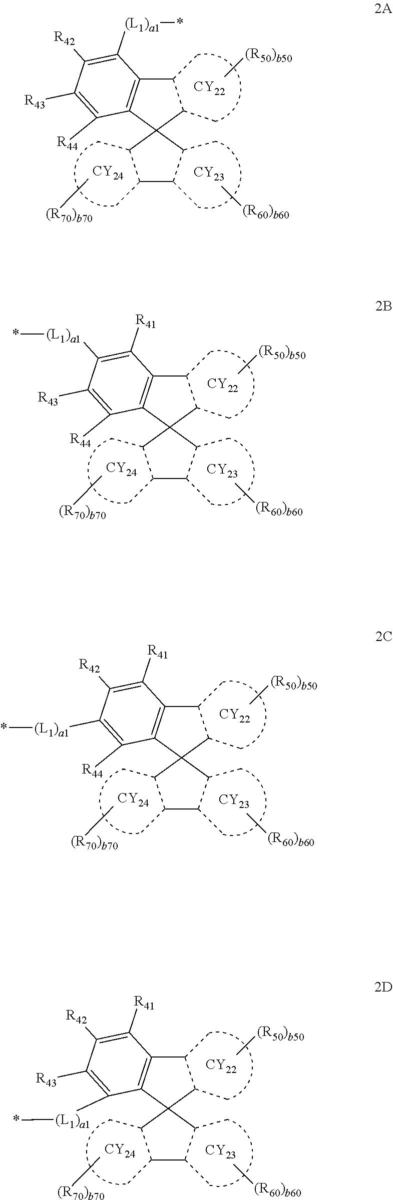
wherein, in Formulae 2A to 2D,
CY₂₂ to CY₂₄, L₁, a₁, R₅₀, R₆₀, R₇₀, b50, b60, and b70 are each as described in claim 1,
R₄₁ to R₄₄ are each as described in connection with R₄₀ in claim 1, and
* indicates a binding site to an adjacent atom.

6. The heterocyclic compound of claim 1, wherein the group represented by Formula 2 is a group represented by any one of Formulae 2-1 to 2-4: 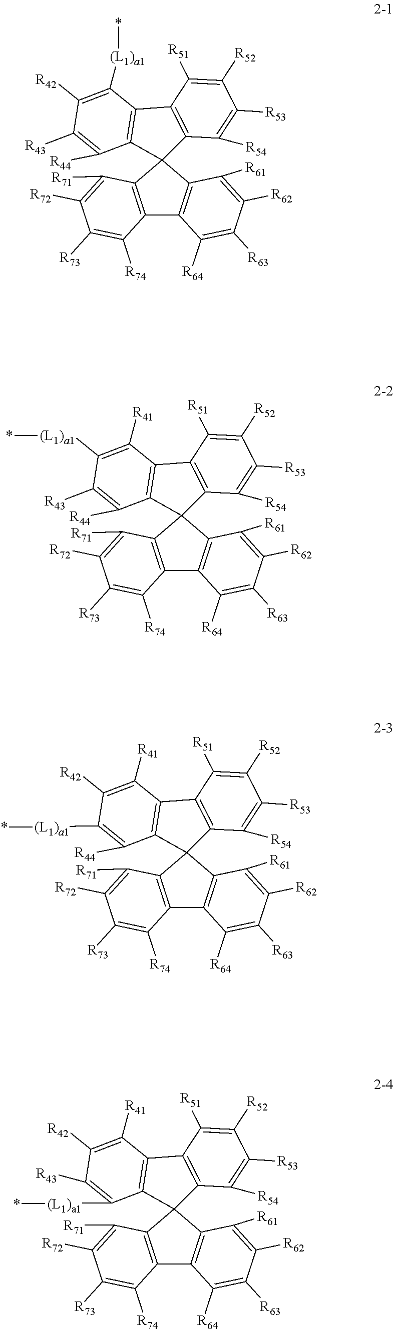
wherein, in Formulae 2-1 to 2-4,
L₁ and a1 are each as described in claim 1,
R₄₁ to R₄₄ are each as described in connection with R₄₀ in claim 1,
R₅₁ to R₅₄ are each as described in connection with R₅₀ in claim 1,
R₆₁ to R₆₄ are each as described in connection with R₆₀ in claim 1,
R₇₁ to R₇₄ are each as described in connection with R₇₀ in claim 1, and
* indicates a binding site to an adjacent atom.

7. The heterocyclic compound of claim 1, wherein L₁ is: a single bond, a phenylene group, a naphthylene group, a phenanthrenylene group, a fluorenylene group, or a pyrenylene group; or
a phenylene group, a naphthylene group, a phenanthrenylene group, a fluorenylene group, or a pyrenylene group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, deuterium-containing C₁-C₂₀ alkyl group, a fluorinated C₁-C₂₀ alkyl group, a C₁-C₂₀ alkoxy group, a phenyl group, a naphthyl group, an anthracenyl group, or any combination thereof.

8. The heterocyclic compound of claim 1, wherein R₁, R₂, R₁₀, R₂₀, R₃₀, R₄₀, R₅₀, R₆₀, R₇₀, R₃₀₁, R₃₀₂, R₃₁₀, and R₃₂₀ are each independently:
hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, —SF₅, a C₁-C₂₀ alkyl group, or a C₁-C₂₀ alkoxy group;
a C₁-C₂₀ alkyl group or a C₁-C₂₀ alkoxy group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a deuterium-containing C₁-C₂₀ alkyl group, a fluorinated C₁-C₂₀ alkyl group, a cyclopentyl group, a cyclohexyl group, a cycloheptyl group, a cyclooctyl group, an adamantanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group (norbornanyl group), a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.1]heptyl group, a (C₁-C₂₀ alkyl)bicyclo[2.2.2]octyl group, a silolanyl group, a phenyl group, a (C₁-C₂₀ alkyl)phenyl group, a biphenyl group, a terphenyl group, a naphthyl group, a 1,2,3,4-tetrahydronaphthyl group, a pyridinyl group, a pyrimidinyl group, or any combination thereof;
a cyclopentyl group, a cyclohexyl group, a cycloheptyl group, a cyclooctyl group, an adamantanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a silolanyl group, a phenyl group, a (C₁-C₂₀ alkyl)phenyl group, a biphenyl group, a terphenyl group, a naphthyl group, a 1,2,3,4-tetrahydronaphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, or an azadibenzothiophenyl group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a deuterium-containing C₁-C₂₀ alkyl group, a fluorinated C₁-C₂₀ alkyl group, a C₁-C₂₀ alkoxy group, a cyclopentyl group, a cyclohexyl group, a cycloheptyl group, a cyclooctyl group, an adamantanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.1]heptyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.1]heptyl group, a (C₁-C₂₀ alkyl)bicyclo[2.2.2]octyl group, a silolanyl group, a phenyl group, a (C₁-C₂₀ alkyl)phenyl group, a biphenyl group, a terphenyl group, a naphthyl group, a 1,2,3,4-tetrahydronaphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, or any combination thereof; or
—N(Q₁)(Q₂), —Si(Q₁)(Q₂)(Q₃), —Ge(Q₁)(Q₂)(Q₃), —B(Q₁)(Q₂), —P(═O)(Q₁)(Q₂), or —P(Q₁)(Q₂).

9. The heterocyclic compound of claim 1, wherein at least one of R₁₀, R₂₀, and R₃₀ is a group represented by Formula 3.

10. The heterocyclic compound of claim 1, wherein the group represented by Formula 3 is represented by any one of Formulae 3-1 to 3-3: 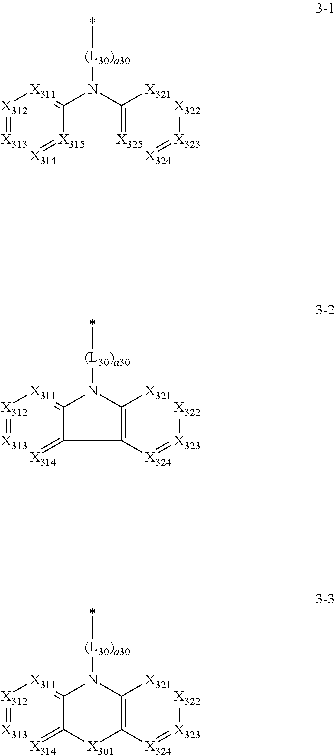
wherein, in Formulae 3-1 to 3-3,
L₃₀ and a30 are each as described in claim 1,
X₃₀₁ is as described in connection with X₃₁ in claim 1,
X₃₁₁ is C(R₃₁₁) or N, X₃₁₂ is C(R₃₁₂) or N, X₃₁₃ is C(R₃₁₃) or N, X₃₁₄ is C(R₃₁₄) or N, X₃₁₅ is C(R₃₁₅) or N,
X₃₂₁ is C(R₃₂₁) or N, X₃₂₂ is C(R₃₂₂) or N, X₃₂₃ is C(R₃₂₃) or N, X₃₂₄ is C(R₃₂₄) or N, X₃₂₅ is C(R₃₂₅) or N,
R₃₁₁ to R₃₁₅ are each independently as described in connection with R₃₁₀ in claim 1,
R₃₂₁ to R₃₂₅ are each independently as described in connection with R₃₂₀ in claim 1, and
* indicates a binding site to an adjacent atom.

11. The heterocyclic compound of claim 1, wherein the heterocyclic compound is represented by Formula 11-1 or 11-2: 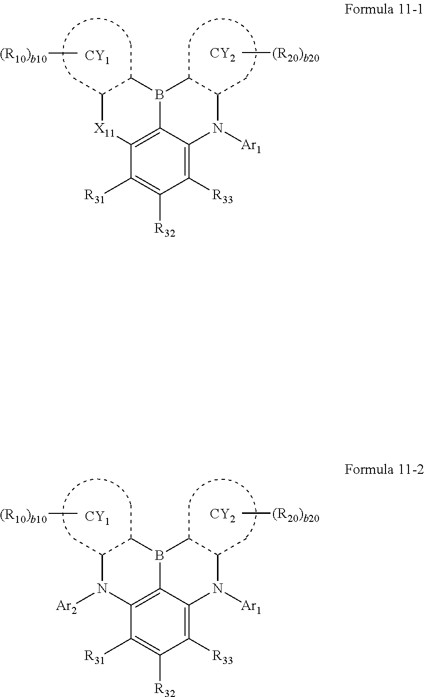
wherein, in Formulae 11-1 and 11-2,
CY₁ , CY₂ , Ar₁, Ar₂, R₁₀, R₂₀, b10, and b20 are each as described in claim 1,
X₁₁ is a single bond, O, S, Se, N(R₁), C(R₁)(R₂), Si(R₁)(R₂), Ge(R₁)(R₂), B(R₁), P(R₁), P(═O)(R₁), S(═O)₂, or C(═O), R₁ and R₂ are each as described in claim 1, and
R₃₁ to R₃₃ are each independently as described in connection with R₃₀ in claim 1.

12. The heterocyclic compound of claim 1, wherein the heterocyclic compound has a symmetrical structure or an asymmetrical structure.

13. The heterocyclic compound of claim 1, wherein the heterocyclic compound is one of Compounds 1 to 360:

[symbol]

14. An organic light-emitting device comprising:
a first electrode;
a second electrode; and
an organic layer arranged between the first electrode and the second electrode and comprising an emission layer,
wherein the organic layer comprises the heterocyclic compound of claim 1.

15. The organic light-emitting device of claim 14, wherein the emission layer comprises the heterocyclic compound.

16. The organic light-emitting device of claim 15, wherein the emission layer comprises a host and an emitter, and
the emitter comprises the heterocyclic compound.

17. The organic light-emitting device of claim 16, wherein an amount of the host is greater than that of the heterocyclic compound.

18. The organic light-emitting device of claim 16, wherein the emission layer further comprises a sensitizer.

19. The organic light-emitting device of claim 18, wherein the sensitizer comprises a phosphorescent dopant.

20. The organic light-emitting device of claim 15, wherein the emission layer emits blue light having a maximum emission wavelength of about 400 nm to about 490 nm. 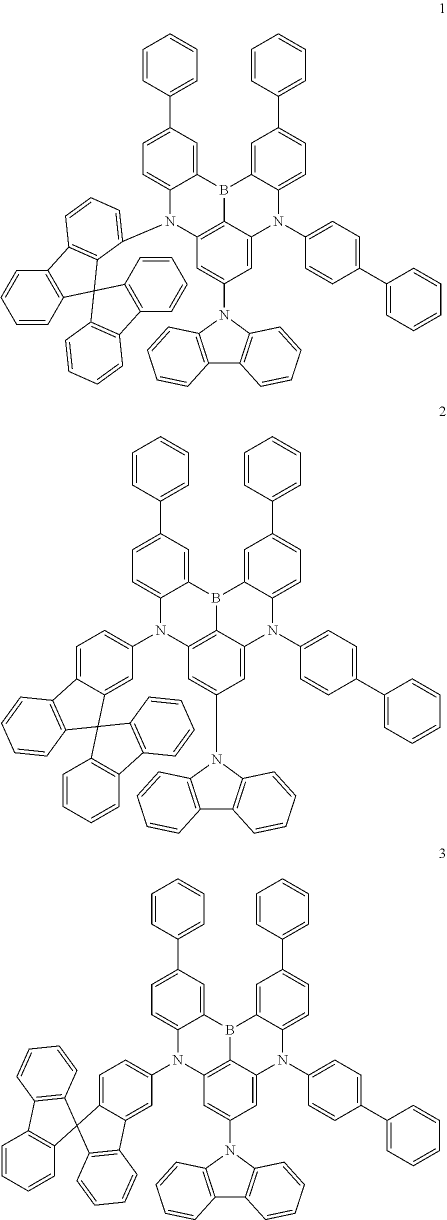 [SMILES: c1ccc(-c2ccc(N3c4ccc(-c5ccccc5)cc4B4c5cc(-c6ccccc6)ccc5N(c5cccc6c5C5(c7ccccc7-c7ccccc75)c5ccccc5-6)c5cc(-n6c7ccccc7c7ccccc76)cc3c54)cc2)cc1 ; c1ccc(-c2ccc(N3c4ccc(-c5ccccc5)cc4B4c5cc(-c6ccccc6)ccc5N(c5ccc6c(c5)C5(c7ccccc7-c7ccccc75)c5ccccc5-6)c5cc(-n6c7ccccc7c7ccccc76)cc3c54)cc2)cc1 ; c1ccc(-c2ccc(N3c4ccc(-c5ccccc5)cc4B4c5cc(-c6ccccc6)ccc5N(c5ccc6c(c5)-c5ccccc5C65c6ccccc6-c6ccccc65)c5cc(-n6c7ccccc7c7ccccc76)cc3c54)cc2)cc1] 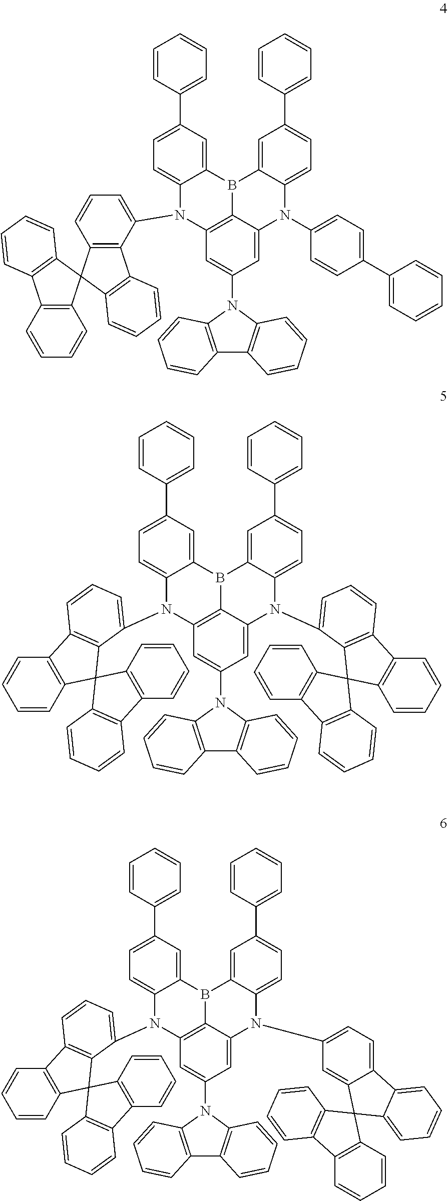 [SMILES: c1ccc(-c2ccc(N3c4ccc(-c5ccccc5)cc4B4c5cc(-c6ccccc6)ccc5N(c5cccc6c5-c5ccccc5C65c6ccccc6-c6ccccc65)c5cc(-n6c7ccccc7c7ccccc76)cc3c54)cc2)cc1 ; c1ccc(-c2ccc3c(c2)B2c4cc(-c5ccccc5)ccc4N(c4cccc5c4C4(c6ccccc6-c6ccccc64)c4ccccc4-5)c4cc(-n5c6ccccc6c6ccccc65)cc(c42)N3c2cccc3c2C2(c4ccccc4-c4ccccc42)c2ccccc2-3)cc1 ; c1ccc(-c2ccc3c(c2)B2c4cc(-c5ccccc5)ccc4N(c4cccc5c4C4(c6ccccc6-c6ccccc64)c4ccccc4-5)c4cc(-n5c6ccccc6c6ccccc65)cc(c42)N3c2ccc3c(c2)C2(c4ccccc4-c4ccccc42)c2ccccc2-3)cc1] 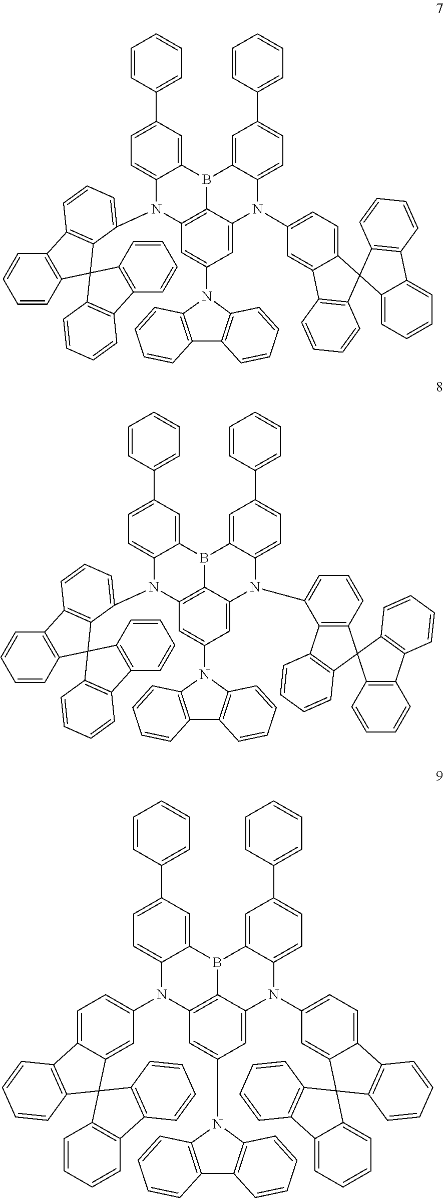 [SMILES: c1ccc(-c2ccc3c(c2)B2c4cc(-c5ccccc5)ccc4N(c4cccc5c4C4(c6ccccc6-c6ccccc64)c4ccccc4-5)c4cc(-n5c6ccccc6c6ccccc65)cc(c42)N3c2ccc3c(c2)-c2ccccc2C32c3ccccc3-c3ccccc32)cc1 ; c1ccc(-c2ccc3c(c2)B2c4cc(-c5ccccc5)ccc4N(c4cccc5c4C4(c6ccccc6-c6ccccc64)c4ccccc4-5)c4cc(-n5c6ccccc6c6ccccc65)cc(c42)N3c2cccc3c2-c2ccccc2C32c3ccccc3-c3ccccc32)cc1 ; c1ccc(-c2ccc3c(c2)B2c4cc(-c5ccccc5)ccc4N(c4ccc5c(c4)C4(c6ccccc6-c6ccccc64)c4ccccc4-5)c4cc(-n5c6ccccc6c6ccccc65)cc(c42)N3c2ccc3c(c2)C2(c4ccccc4-c4ccccc42)c2ccccc2-3)cc1] 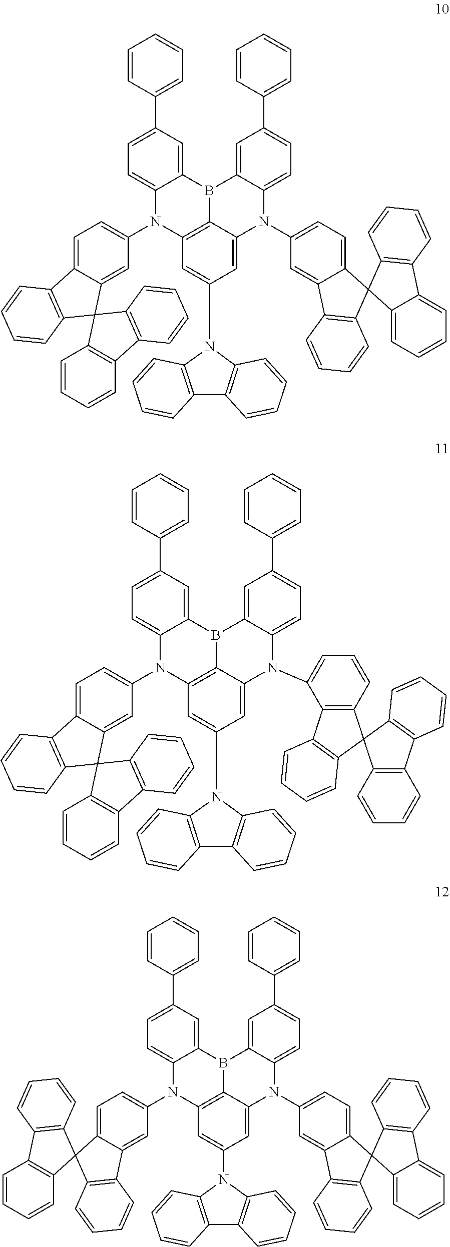 [SMILES: c1ccc(-c2ccc3c(c2)B2c4cc(-c5ccccc5)ccc4N(c4ccc5c(c4)C4(c6ccccc6-c6ccccc64)c4ccccc4-5)c4cc(-n5c6ccccc6c6ccccc65)cc(c42)N3c2ccc3c(c2)-c2ccccc2C32c3ccccc3-c3ccccc32)cc1 ; c1ccc(-c2ccc3c(c2)B2c4cc(-c5ccccc5)ccc4N(c4cccc5c4-c4ccccc4C54c5ccccc5-c5ccccc54)c4cc(-n5c6ccccc6c6ccccc65)cc(c42)N3c2ccc3c(c2)C2(c4ccccc4-c4ccccc42)c2ccccc2-3)cc1 ; c1ccc(-c2ccc3c(c2)B2c4cc(-c5ccccc5)ccc4N(c4ccc5c(c4)-c4ccccc4C54c5ccccc5-c5ccccc54)c4cc(-n5c6ccccc6c6ccccc65)cc(c42)N3c2ccc3c(c2)-c2ccccc2C32c3ccccc3-c3ccccc32)cc1] 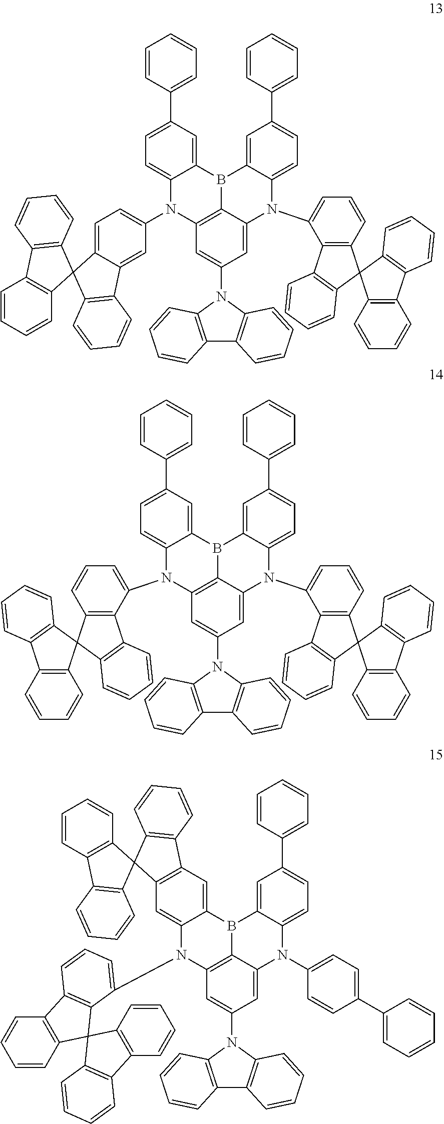 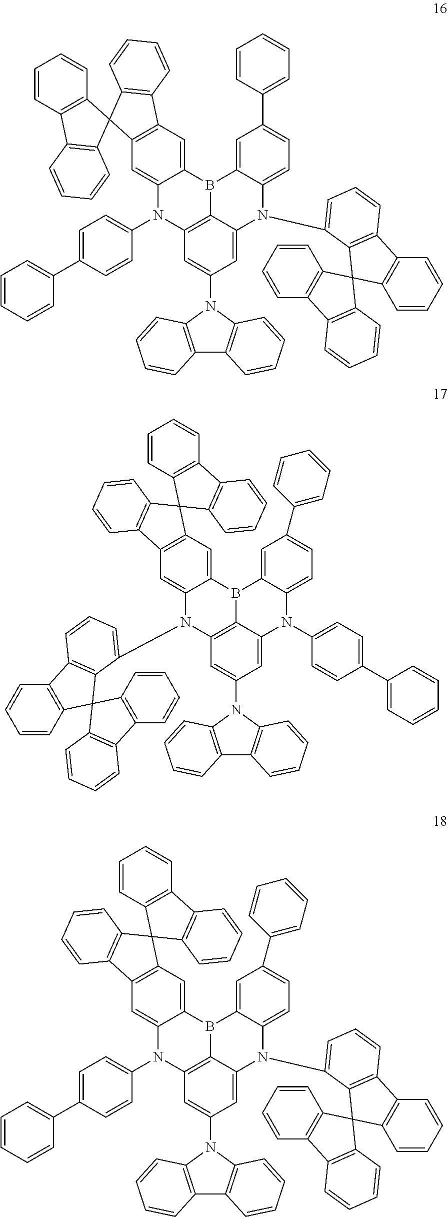 [SMILES: c1ccc(-c2ccc(N3c4cc5c(cc4B4c6cc(-c7ccccc7)ccc6N(c6cccc7c6C6(c8ccccc8-c8ccccc86)c6ccccc6-7)c6cc(-n7c8ccccc8c8ccccc87)cc3c64)-c3ccccc3C53c4ccccc4-c4ccccc43)cc2)cc1 ; c1ccc(-c2ccc(N3c4ccc(-c5ccccc5)cc4B4c5cc6c(cc5N(c5cccc7c5C5(c8ccccc8-c8ccccc85)c5ccccc5-7)c5cc(-n7c8ccccc8c8ccccc87)cc3c54)-c3ccccc3C63c4ccccc4-c4ccccc43)cc2)cc1 ; c1ccc(-c2ccc(N3c4cc5c(cc4B4c6cc(-c7ccccc7)ccc6N(c6cccc7c6C6(c8ccccc8-c8ccccc86)c6ccccc6-7)c6cc(-n7c8ccccc8c8ccccc87)cc3c64)C3(c4ccccc4-c4ccccc43)c3ccccc3-5)cc2)cc1] 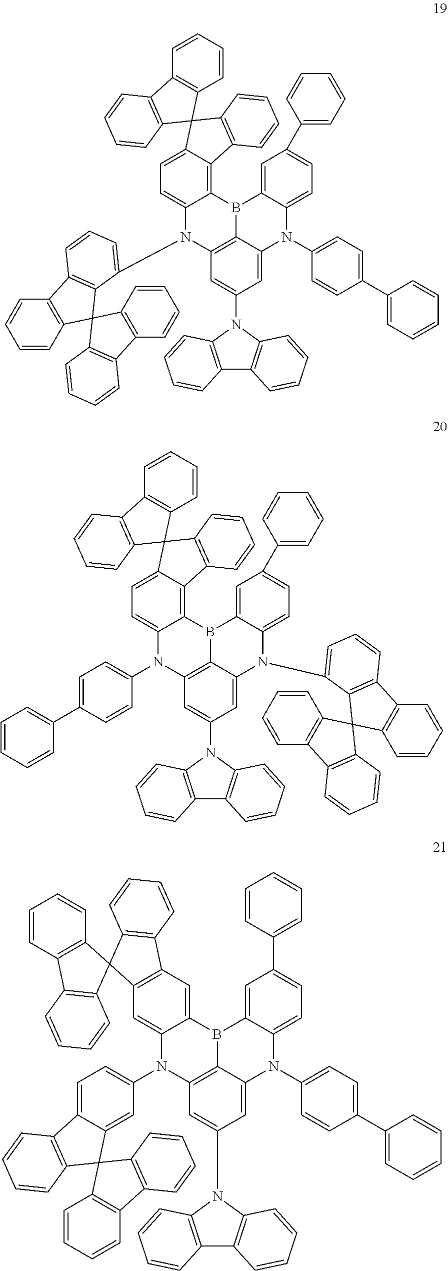 [SMILES: c1ccc(-c2ccc(N3c4ccc(-c5ccccc5)cc4B4c5c3cc(-n3c6ccccc6c6ccccc63)cc5N(c3cccc5c3C3(c6ccccc6-c6ccccc63)c3ccccc3-5)c3ccc5c(c34)-c3ccccc3C53c4ccccc4-c4ccccc43)cc2)cc1 ; c1ccc(-c2ccc(N3c4cc(-n5c6ccccc6c6ccccc65)cc5c4B(c4cc(-c6ccccc6)ccc4N5c4cccc5c4C4(c6ccccc6-c6ccccc64)c4ccccc4-5)c4c3ccc3c4-c4ccccc4C34c3ccccc3-c3ccccc34)cc2)cc1 ; c1ccc(-c2ccc(N3c4ccc(-c5ccccc5)cc4B4c5cc6c(cc5N(c5ccc7c(c5)C5(c8ccccc8-c8ccccc85)c5ccccc5-7)c5cc(-n7c8ccccc8c8ccccc87)cc3c54)C3(c4ccccc4-c4ccccc43)c3ccccc3-6)cc2)cc1] 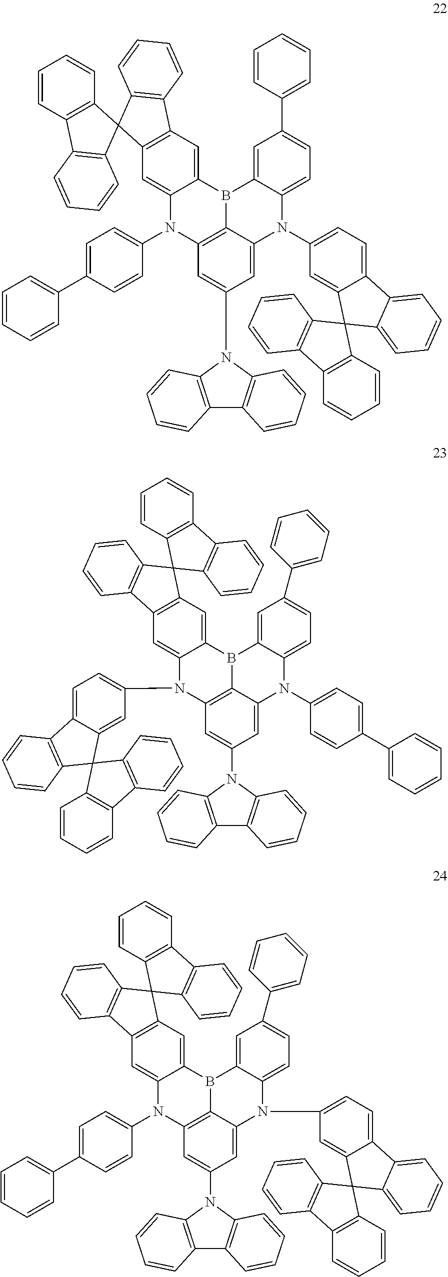 [SMILES: c1ccc(-c2ccc(N3c4cc5c(cc4B4c6cc(-c7ccccc7)ccc6N(c6ccc7c(c6)C6(c8ccccc8-c8ccccc86)c6ccccc6-7)c6cc(-n7c8ccccc8c8ccccc87)cc3c64)-c3ccccc3C53c4ccccc4-c4ccccc43)cc2)cc1 ; c1ccc(-c2ccc(N3c4ccc(-c5ccccc5)cc4B4c5cc6c(cc5N(c5ccc7c(c5)C5(c8ccccc8-c8ccccc85)c5ccccc5-7)c5cc(-n7c8ccccc8c8ccccc87)cc3c54)-c3ccccc3C63c4ccccc4-c4ccccc43)cc2)cc1 ; c1ccc(-c2ccc(N3c4cc5c(cc4B4c6cc(-c7ccccc7)ccc6N(c6ccc7c(c6)C6(c8ccccc8-c8ccccc86)c6ccccc6-7)c6cc(-n7c8ccccc8c8ccccc87)cc3c64)C3(c4ccccc4-c4ccccc43)c3ccccc3-5)cc2)cc1] 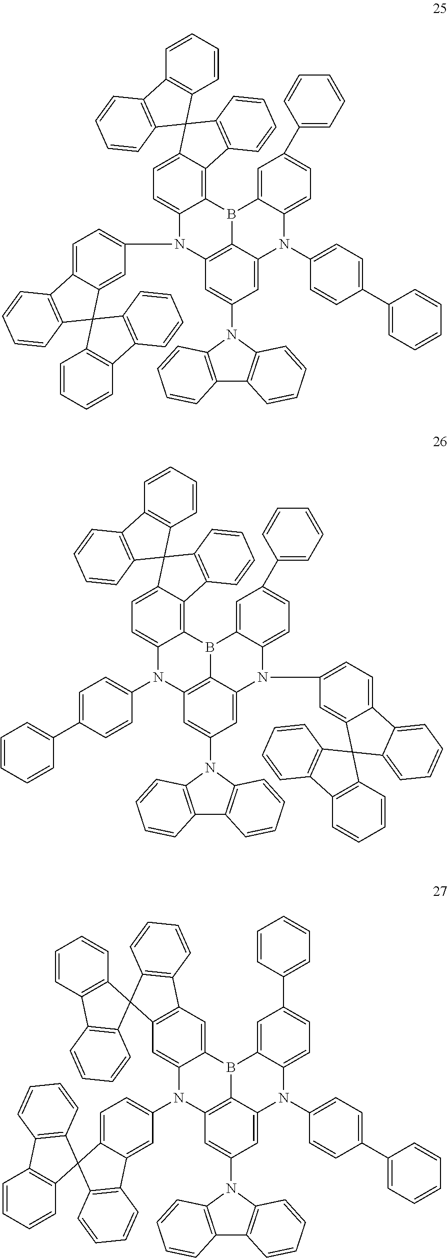 [SMILES: c1ccc(-c2ccc(N3c4ccc(-c5ccccc5)cc4B4c5c3cc(-n3c6ccccc6c6ccccc63)cc5N(c3ccc5c(c3)C3(c6ccccc6-c6ccccc63)c3ccccc3-5)c3ccc5c(c34)-c3ccccc3C53c4ccccc4-c4ccccc43)cc2)cc1 ; c1ccc(-c2ccc(N3c4cc(-n5c6ccccc6c6ccccc65)cc5c4B(c4cc(-c6ccccc6)ccc4N5c4ccc5c(c4)C4(c6ccccc6-c6ccccc64)c4ccccc4-5)c4c3ccc3c4-c4ccccc4C34c3ccccc3-c3ccccc34)cc2)cc1 ; c1ccc(-c2ccc(N3c4ccc(-c5ccccc5)cc4B4c5cc6c(cc5N(c5ccc7c(c5)-c5ccccc5C75c7ccccc7-c7ccccc75)c5cc(-n7c8ccccc8c8ccccc87)cc3c54)C3(c4ccccc4-c4ccccc43)c3ccccc3-6)cc2)cc1] 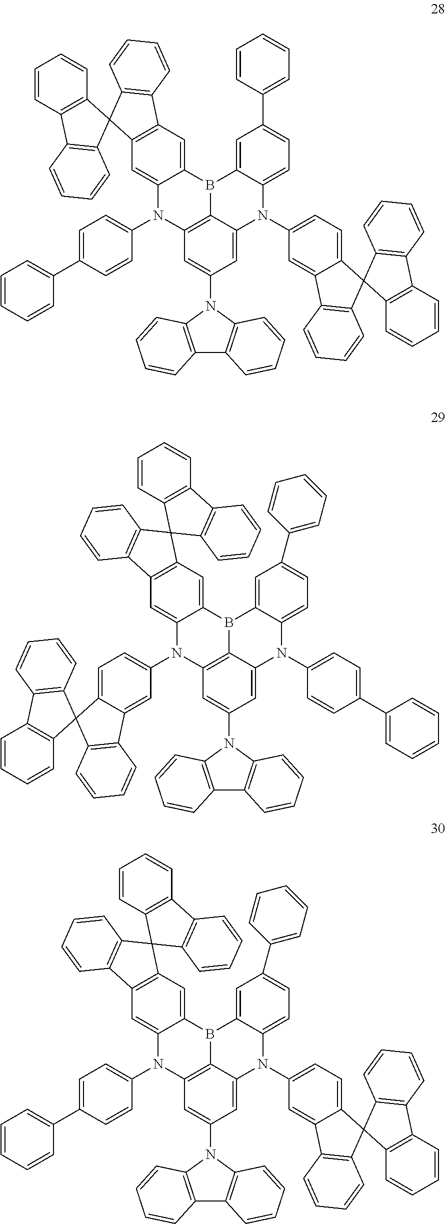 [SMILES: c1ccc(-c2ccc(N3c4cc5c(cc4B4c6cc(-c7ccccc7)ccc6N(c6ccc7c(c6)-c6ccccc6C76c7ccccc7-c7ccccc76)c6cc(-n7c8ccccc8c8ccccc87)cc3c64)-c3ccccc3C53c4ccccc4-c4ccccc43)cc2)cc1 ; c1ccc(-c2ccc(N3c4ccc(-c5ccccc5)cc4B4c5cc6c(cc5N(c5ccc7c(c5)-c5ccccc5C75c7ccccc7-c7ccccc75)c5cc(-n7c8ccccc8c8ccccc87)cc3c54)-c3ccccc3C63c4ccccc4-c4ccccc43)cc2)cc1 ; c1ccc(-c2ccc(N3c4cc5c(cc4B4c6cc(-c7ccccc7)ccc6N(c6ccc7c(c6)-c6ccccc6C76c7ccccc7-c7ccccc76)c6cc(-n7c8ccccc8c8ccccc87)cc3c64)C3(c4ccccc4-c4ccccc43)c3ccccc3-5)cc2)cc1] 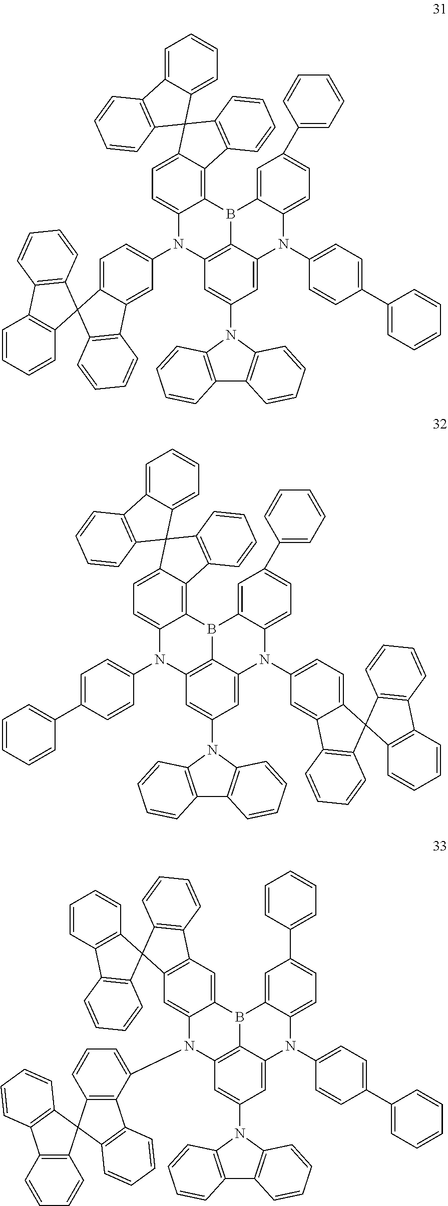 [SMILES: c1ccc(-c2ccc(N3c4ccc(-c5ccccc5)cc4B4c5c3cc(-n3c6ccccc6c6ccccc63)cc5N(c3ccc5c(c3)-c3ccccc3C53c5ccccc5-c5ccccc53)c3ccc5c(c34)-c3ccccc3C53c4ccccc4-c4ccccc43)cc2)cc1 ; c1ccc(-c2ccc(N3c4cc(-n5c6ccccc6c6ccccc65)cc5c4B(c4cc(-c6ccccc6)ccc4N5c4ccc5c(c4)-c4ccccc4C54c5ccccc5-c5ccccc54)c4c3ccc3c4-c4ccccc4C34c3ccccc3-c3ccccc34)cc2)cc1 ; c1ccc(-c2ccc(N3c4ccc(-c5ccccc5)cc4B4c5cc6c(cc5N(c5cccc7c5-c5ccccc5C75c7ccccc7-c7ccccc75)c5cc(-n7c8ccccc8c8ccccc87)cc3c54)C3(c4ccccc4-c4ccccc43)c3ccccc3-6)cc2)cc1] 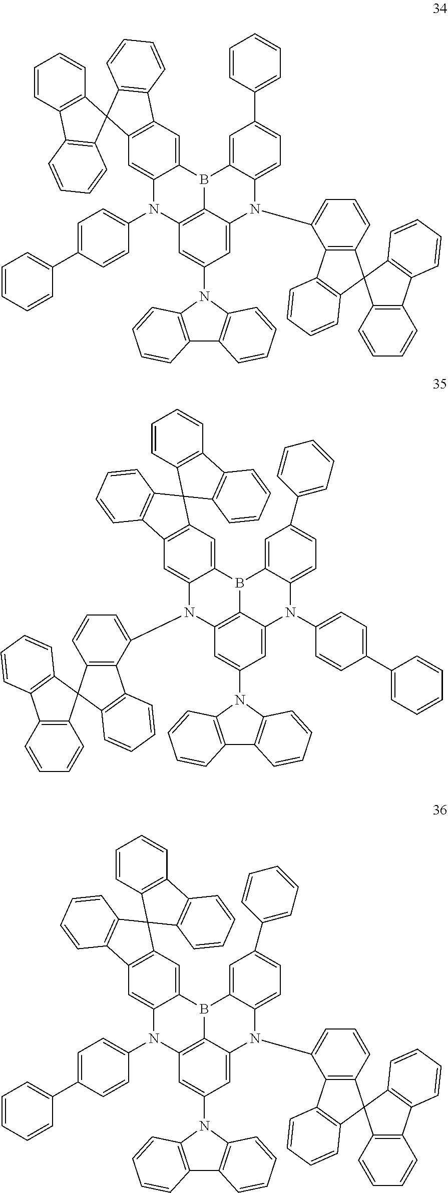 [SMILES: c1ccc(-c2ccc(N3c4cc5c(cc4B4c6cc(-c7ccccc7)ccc6N(c6cccc7c6-c6ccccc6C76c7ccccc7-c7ccccc76)c6cc(-n7c8ccccc8c8ccccc87)cc3c64)-c3ccccc3C53c4ccccc4-c4ccccc43)cc2)cc1 ; c1ccc(-c2ccc(N3c4ccc(-c5ccccc5)cc4B4c5cc6c(cc5N(c5cccc7c5-c5ccccc5C75c7ccccc7-c7ccccc75)c5cc(-n7c8ccccc8c8ccccc87)cc3c54)-c3ccccc3C63c4ccccc4-c4ccccc43)cc2)cc1 ; c1ccc(-c2ccc(N3c4cc5c(cc4B4c6cc(-c7ccccc7)ccc6N(c6cccc7c6-c6ccccc6C76c7ccccc7-c7ccccc76)c6cc(-n7c8ccccc8c8ccccc87)cc3c64)C3(c4ccccc4-c4ccccc43)c3ccccc3-5)cc2)cc1] 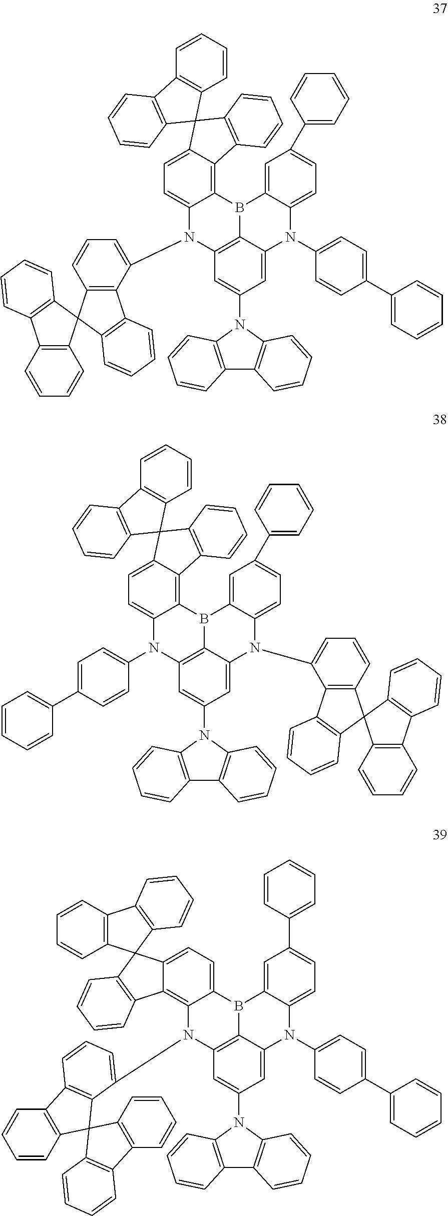 [SMILES: c1ccc(-c2ccc(N3c4ccc(-c5ccccc5)cc4B4c5c3cc(-n3c6ccccc6c6ccccc63)cc5N(c3cccc5c3-c3ccccc3C53c5ccccc5-c5ccccc53)c3ccc5c(c34)-c3ccccc3C53c4ccccc4-c4ccccc43)cc2)cc1 ; c1ccc(-c2ccc(N3c4cc(-n5c6ccccc6c6ccccc65)cc5c4B(c4cc(-c6ccccc6)ccc4N5c4cccc5c4-c4ccccc4C54c5ccccc5-c5ccccc54)c4c3ccc3c4-c4ccccc4C34c3ccccc3-c3ccccc34)cc2)cc1 ; c1ccc(-c2ccc(N3c4ccc(-c5ccccc5)cc4B4c5ccc6c(c5N(c5cccc7c5C5(c8ccccc8-c8ccccc85)c5ccccc5-7)c5cc(-n7c8ccccc8c8ccccc87)cc3c54)-c3ccccc3C63c4ccccc4-c4ccccc43)cc2)cc1] 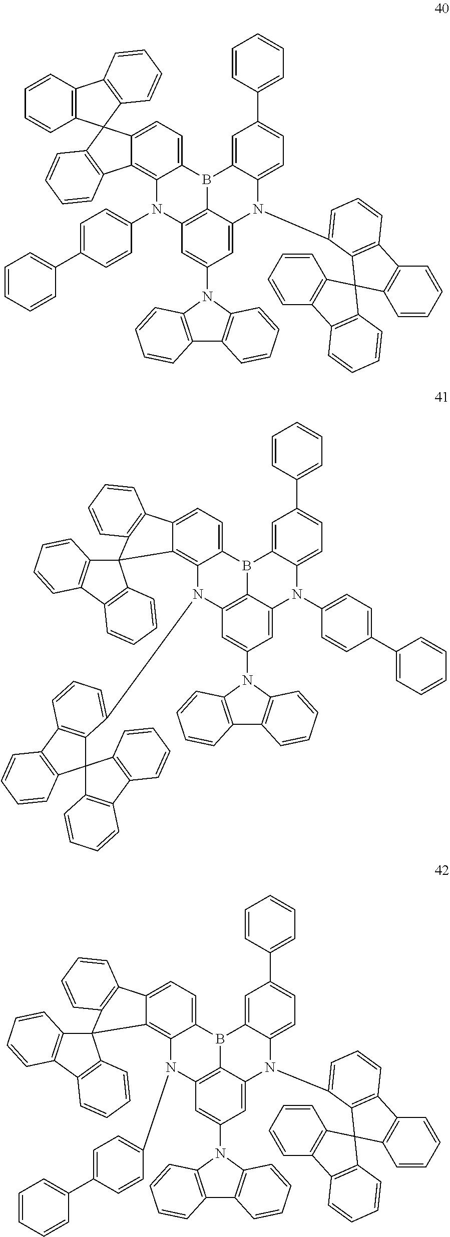 [SMILES: c1ccc(-c2ccc(N3c4cc(-n5c6ccccc6c6ccccc65)cc5c4B(c4cc(-c6ccccc6)ccc4N5c4cccc5c4C4(c6ccccc6-c6ccccc64)c4ccccc4-5)c4ccc5c(c43)-c3ccccc3C53c4ccccc4-c4ccccc43)cc2)cc1 ; c1ccc(-c2ccc(N3c4ccc(-c5ccccc5)cc4B4c5ccc6c(c5N(c5cccc7c5C5(c8ccccc8-c8ccccc85)c5ccccc5-7)c5cc(-n7c8ccccc8c8ccccc87)cc3c54)C3(c4ccccc4-c4ccccc43)c3ccccc3-6)cc2)cc1 ; c1ccc(-c2ccc(N3c4cc(-n5c6ccccc6c6ccccc65)cc5c4B(c4cc(-c6ccccc6)ccc4N5c4cccc5c4C4(c6ccccc6-c6ccccc64)c4ccccc4-5)c4ccc5c(c43)C3(c4ccccc4-c4ccccc43)c3ccccc3-5)cc2)cc1] 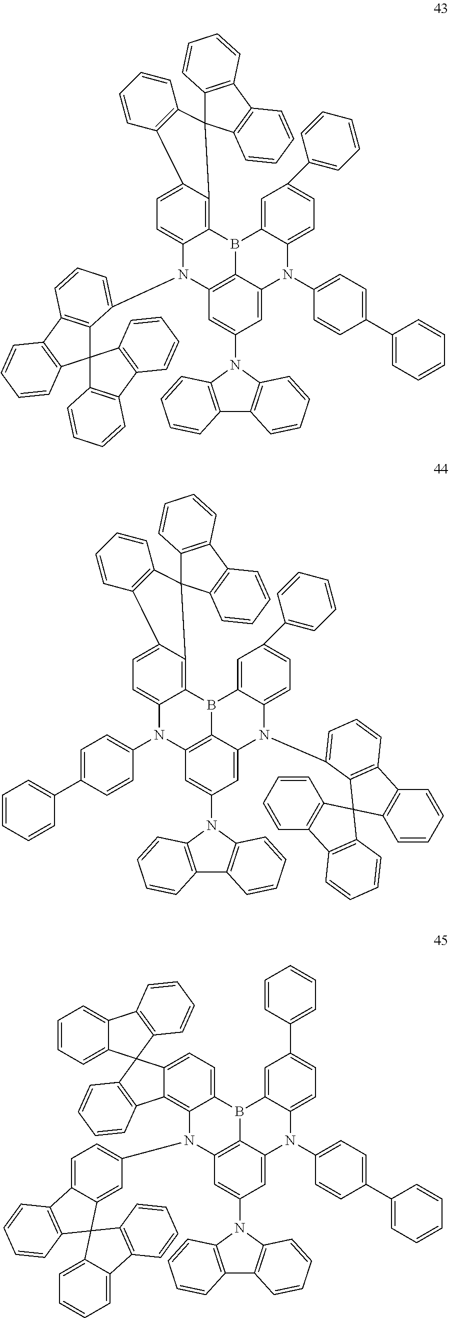 [SMILES: c1ccc(-c2ccc(N3c4ccc(-c5ccccc5)cc4B4c5c3cc(-n3c6ccccc6c6ccccc63)cc5N(c3cccc5c3C3(c6ccccc6-c6ccccc63)c3ccccc3-5)c3ccc5c(c34)C3(c4ccccc4-c4ccccc43)c3ccccc3-5)cc2)cc1 ; c1ccc(-c2ccc(N3c4cc(-n5c6ccccc6c6ccccc65)cc5c4B(c4cc(-c6ccccc6)ccc4N5c4cccc5c4C4(c6ccccc6-c6ccccc64)c4ccccc4-5)c4c3ccc3c4C4(c5ccccc5-c5ccccc54)c4ccccc4-3)cc2)cc1 ; c1ccc(-c2ccc(N3c4ccc(-c5ccccc5)cc4B4c5ccc6c(c5N(c5ccc7c(c5)C5(c8ccccc8-c8ccccc85)c5ccccc5-7)c5cc(-n7c8ccccc8c8ccccc87)cc3c54)-c3ccccc3C63c4ccccc4-c4ccccc43)cc2)cc1] 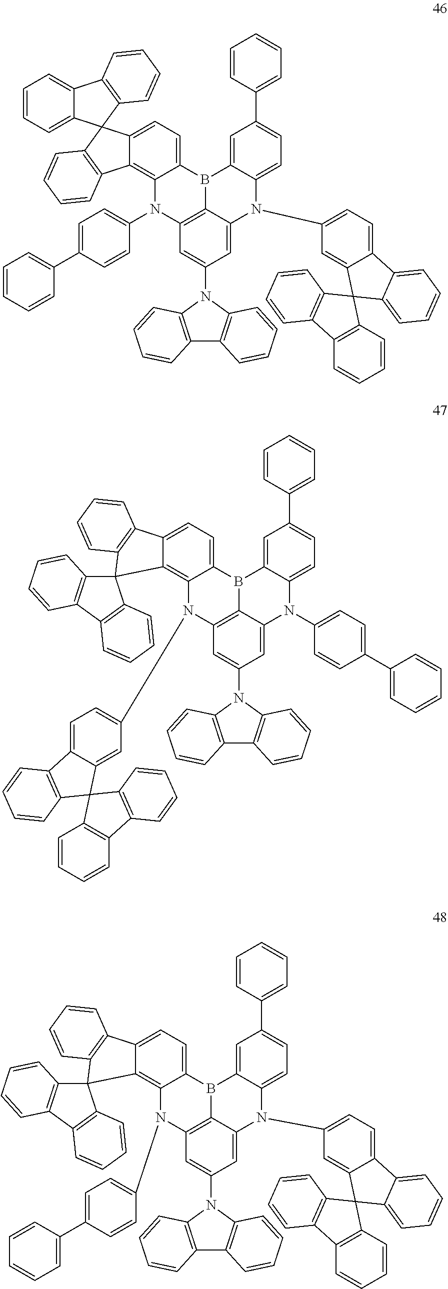 [SMILES: c1ccc(-c2ccc(N3c4cc(-n5c6ccccc6c6ccccc65)cc5c4B(c4cc(-c6ccccc6)ccc4N5c4ccc5c(c4)C4(c6ccccc6-c6ccccc64)c4ccccc4-5)c4ccc5c(c43)-c3ccccc3C53c4ccccc4-c4ccccc43)cc2)cc1 ; c1ccc(-c2ccc(N3c4ccc(-c5ccccc5)cc4B4c5ccc6c(c5N(c5ccc7c(c5)C5(c8ccccc8-c8ccccc85)c5ccccc5-7)c5cc(-n7c8ccccc8c8ccccc87)cc3c54)C3(c4ccccc4-c4ccccc43)c3ccccc3-6)cc2)cc1 ; c1ccc(-c2ccc(N3c4cc(-n5c6ccccc6c6ccccc65)cc5c4B(c4cc(-c6ccccc6)ccc4N5c4ccc5c(c4)C4(c6ccccc6-c6ccccc64)c4ccccc4-5)c4ccc5c(c43)C3(c4ccccc4-c4ccccc43)c3ccccc3-5)cc2)cc1] 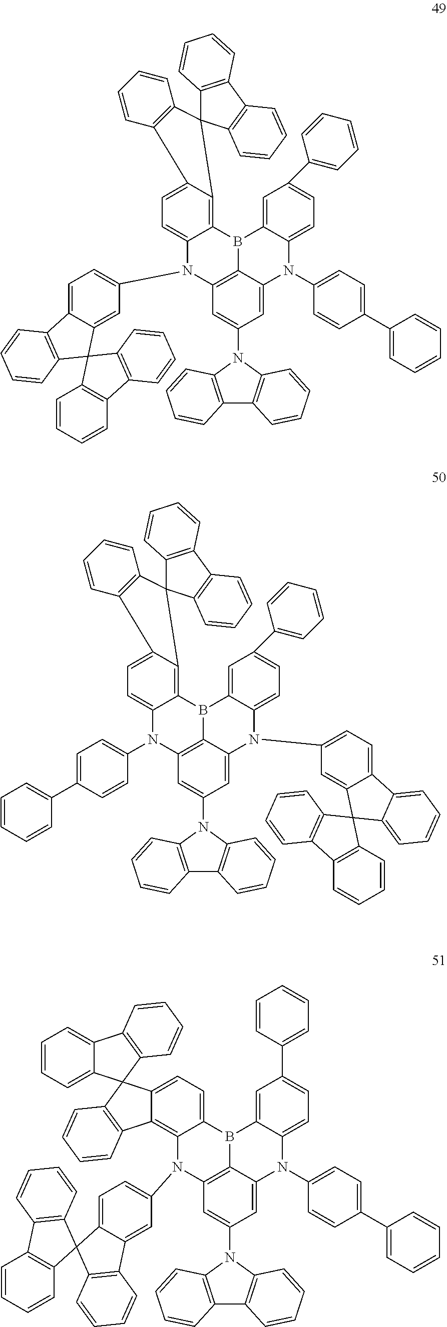 [SMILES: c1ccc(-c2ccc(N3c4ccc(-c5ccccc5)cc4B4c5c3cc(-n3c6ccccc6c6ccccc63)cc5N(c3ccc5c(c3)C3(c6ccccc6-c6ccccc63)c3ccccc3-5)c3ccc5c(c34)C3(c4ccccc4-c4ccccc43)c3ccccc3-5)cc2)cc1 ; c1ccc(-c2ccc(N3c4cc(-n5c6ccccc6c6ccccc65)cc5c4B(c4cc(-c6ccccc6)ccc4N5c4ccc5c(c4)C4(c6ccccc6-c6ccccc64)c4ccccc4-5)c4c3ccc3c4C4(c5ccccc5-c5ccccc54)c4ccccc4-3)cc2)cc1 ; c1ccc(-c2ccc(N3c4ccc(-c5ccccc5)cc4B4c5ccc6c(c5N(c5ccc7c(c5)-c5ccccc5C75c7ccccc7-c7ccccc75)c5cc(-n7c8ccccc8c8ccccc87)cc3c54)-c3ccccc3C63c4ccccc4-c4ccccc43)cc2)cc1] 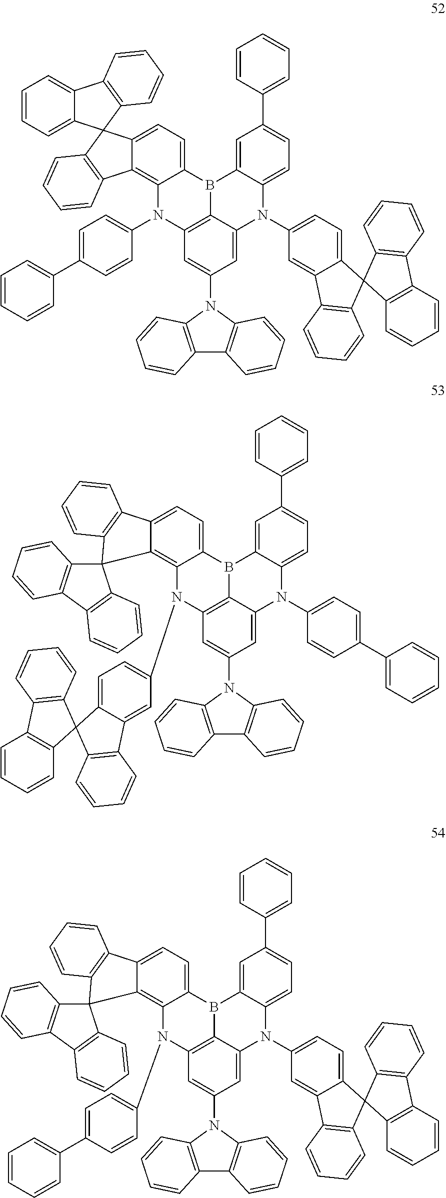 [SMILES: c1ccc(-c2ccc(N3c4cc(-n5c6ccccc6c6ccccc65)cc5c4B(c4cc(-c6ccccc6)ccc4N5c4ccc5c(c4)-c4ccccc4C54c5ccccc5-c5ccccc54)c4ccc5c(c43)-c3ccccc3C53c4ccccc4-c4ccccc43)cc2)cc1 ; c1ccc(-c2ccc(N3c4ccc(-c5ccccc5)cc4B4c5ccc6c(c5N(c5ccc7c(c5)-c5ccccc5C75c7ccccc7-c7ccccc75)c5cc(-n7c8ccccc8c8ccccc87)cc3c54)C3(c4ccccc4-c4ccccc43)c3ccccc3-6)cc2)cc1 ; c1ccc(-c2ccc(N3c4cc(-n5c6ccccc6c6ccccc65)cc5c4B(c4cc(-c6ccccc6)ccc4N5c4ccc5c(c4)-c4ccccc4C54c5ccccc5-c5ccccc54)c4ccc5c(c43)C3(c4ccccc4-c4ccccc43)c3ccccc3-5)cc2)cc1] 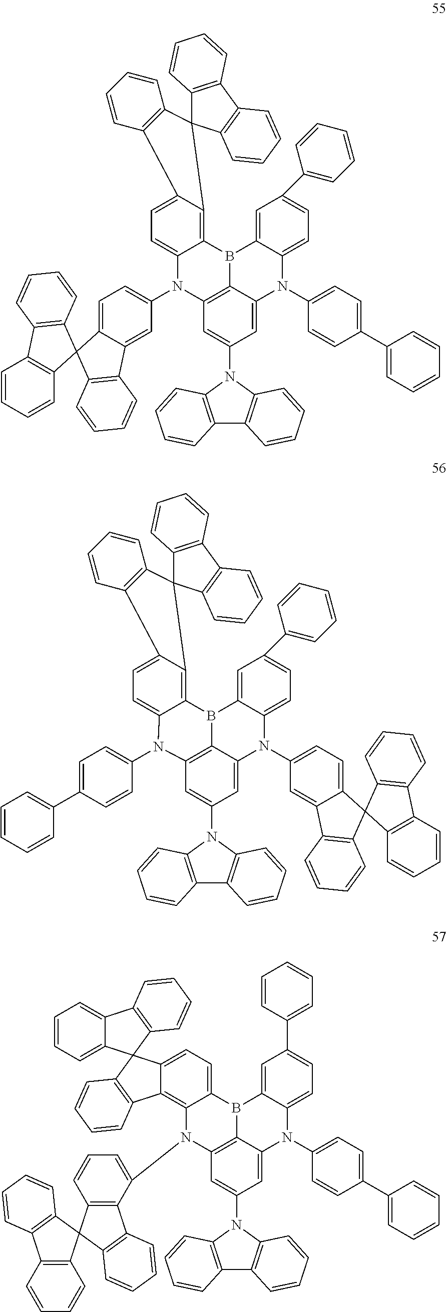 [SMILES: c1ccc(-c2ccc(N3c4ccc(-c5ccccc5)cc4B4c5c3cc(-n3c6ccccc6c6ccccc63)cc5N(c3ccc5c(c3)-c3ccccc3C53c5ccccc5-c5ccccc53)c3ccc5c(c34)C3(c4ccccc4-c4ccccc43)c3ccccc3-5)cc2)cc1 ; c1ccc(-c2ccc(N3c4cc(-n5c6ccccc6c6ccccc65)cc5c4B(c4cc(-c6ccccc6)ccc4N5c4ccc5c(c4)-c4ccccc4C54c5ccccc5-c5ccccc54)c4c3ccc3c4C4(c5ccccc5-c5ccccc54)c4ccccc4-3)cc2)cc1 ; c1ccc(-c2ccc(N3c4ccc(-c5ccccc5)cc4B4c5ccc6c(c5N(c5cccc7c5-c5ccccc5C75c7ccccc7-c7ccccc75)c5cc(-n7c8ccccc8c8ccccc87)cc3c54)-c3ccccc3C63c4ccccc4-c4ccccc43)cc2)cc1] 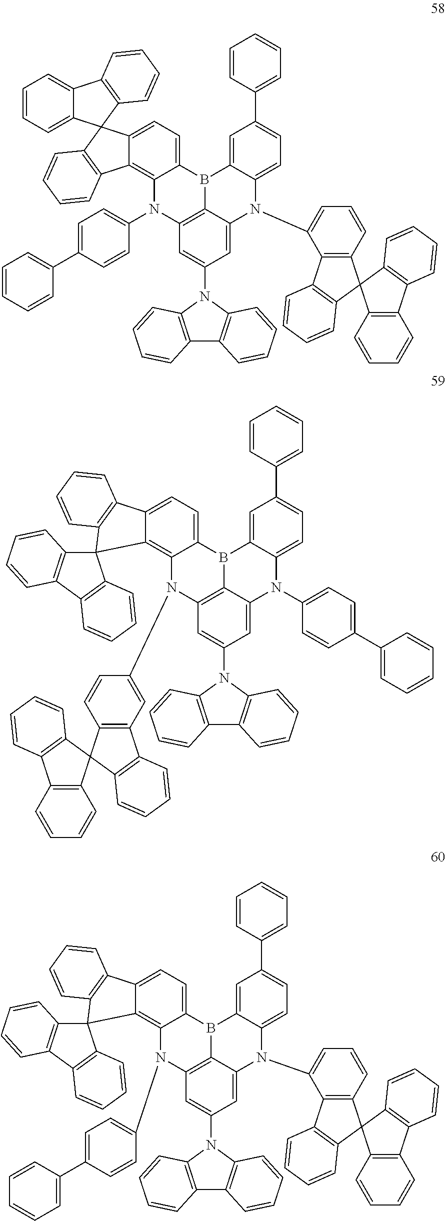 [SMILES: c1ccc(-c2ccc(N3c4cc(-n5c6ccccc6c6ccccc65)cc5c4B(c4cc(-c6ccccc6)ccc4N5c4cccc5c4-c4ccccc4C54c5ccccc5-c5ccccc54)c4ccc5c(c43)-c3ccccc3C53c4ccccc4-c4ccccc43)cc2)cc1 ; c1ccc(-c2ccc(N3c4ccc(-c5ccccc5)cc4B4c5ccc6c(c5N(c5ccc7c(c5)-c5ccccc5C75c7ccccc7-c7ccccc75)c5cc(-n7c8ccccc8c8ccccc87)cc3c54)C3(c4ccccc4-c4ccccc43)c3ccccc3-6)cc2)cc1 ; c1ccc(-c2ccc(N3c4cc(-n5c6ccccc6c6ccccc65)cc5c4B(c4cc(-c6ccccc6)ccc4N5c4cccc5c4-c4ccccc4C54c5ccccc5-c5ccccc54)c4ccc5c(c43)C3(c4ccccc4-c4ccccc43)c3ccccc3-5)cc2)cc1] 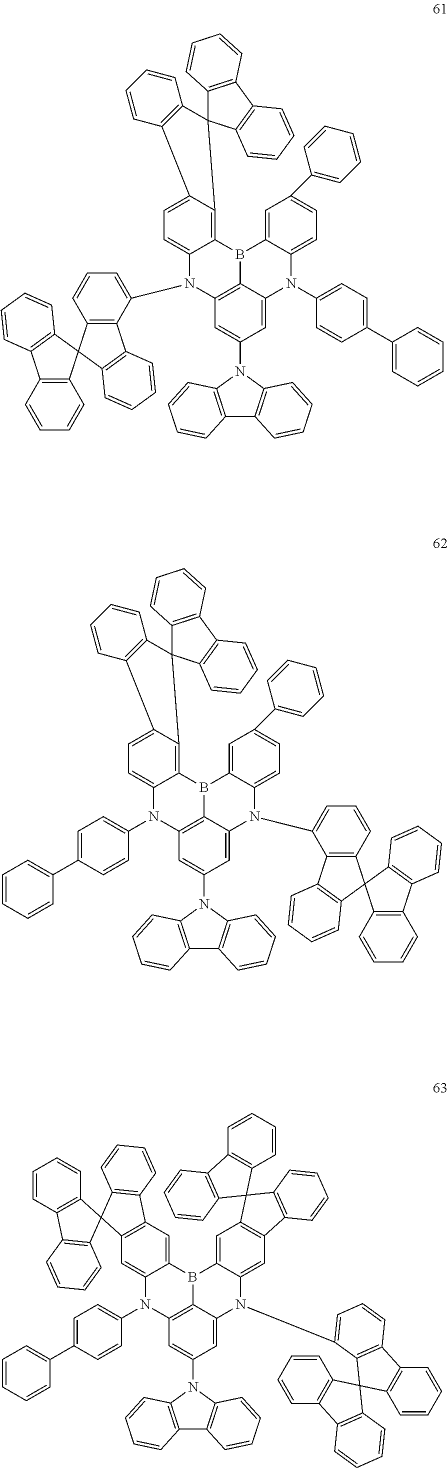 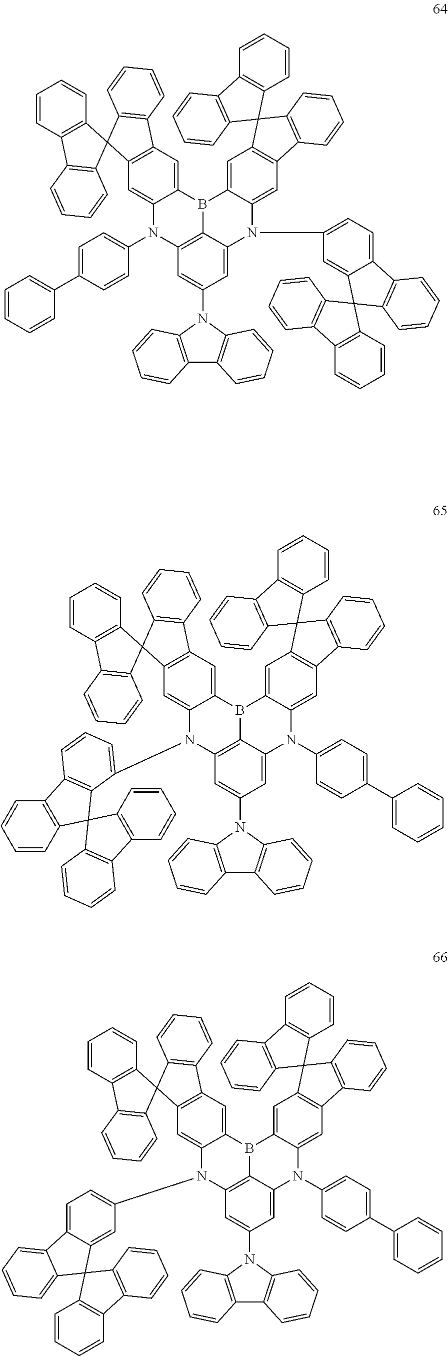 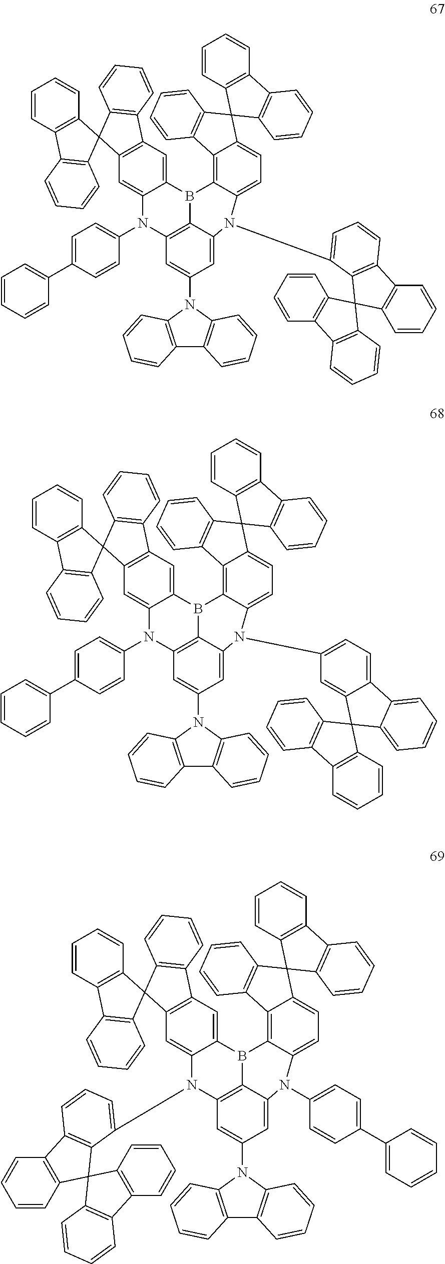 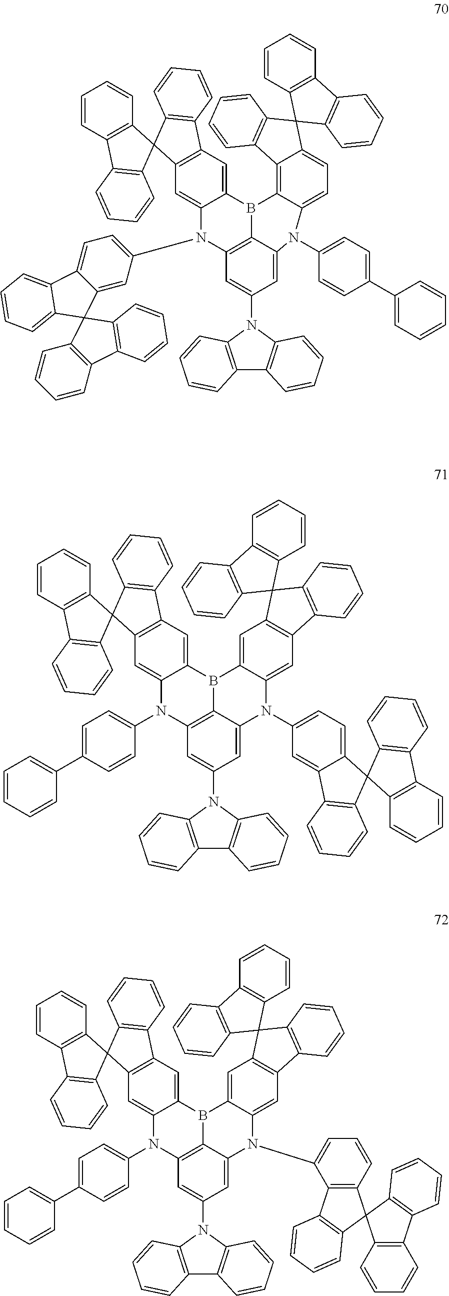 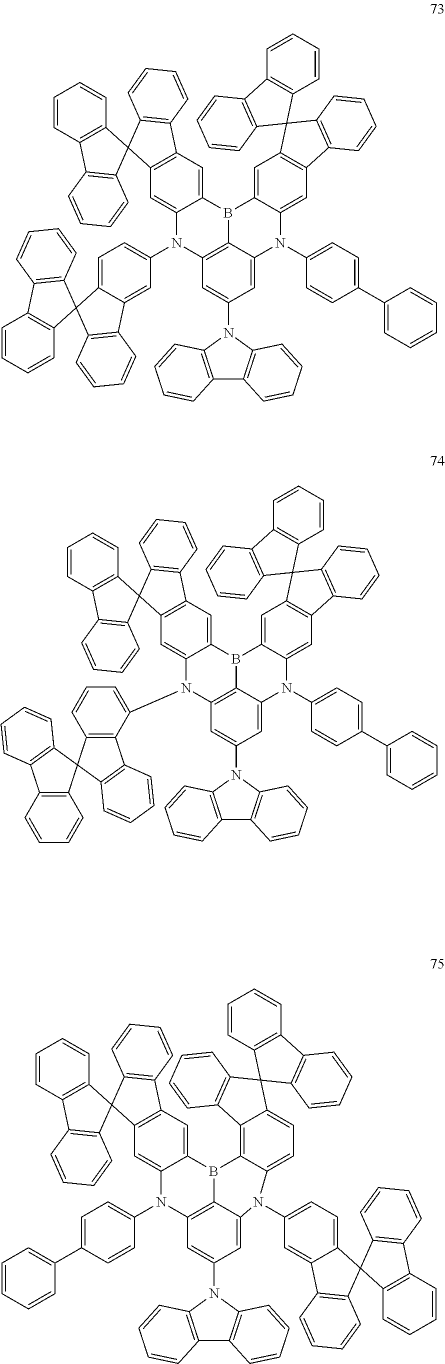 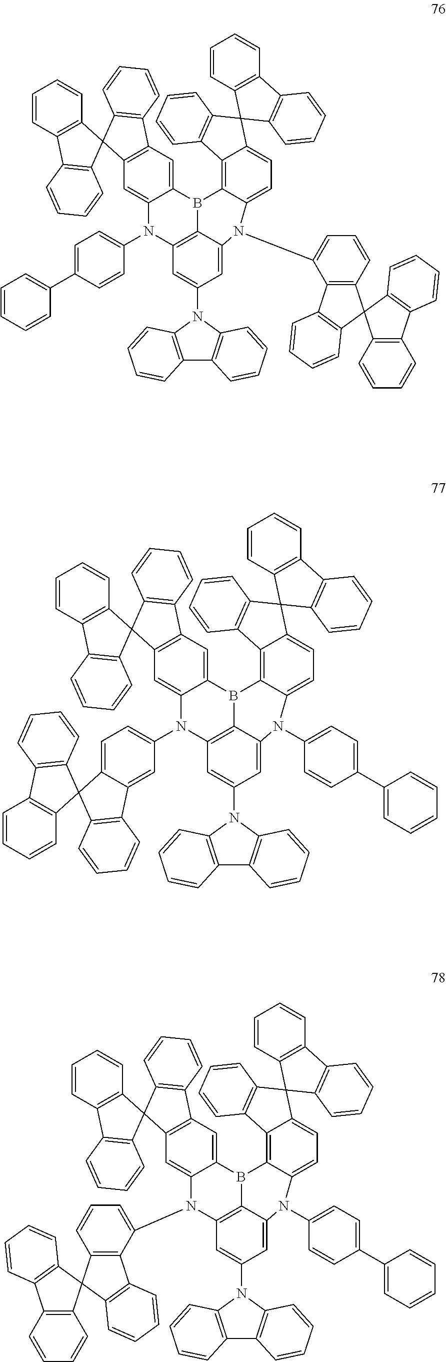 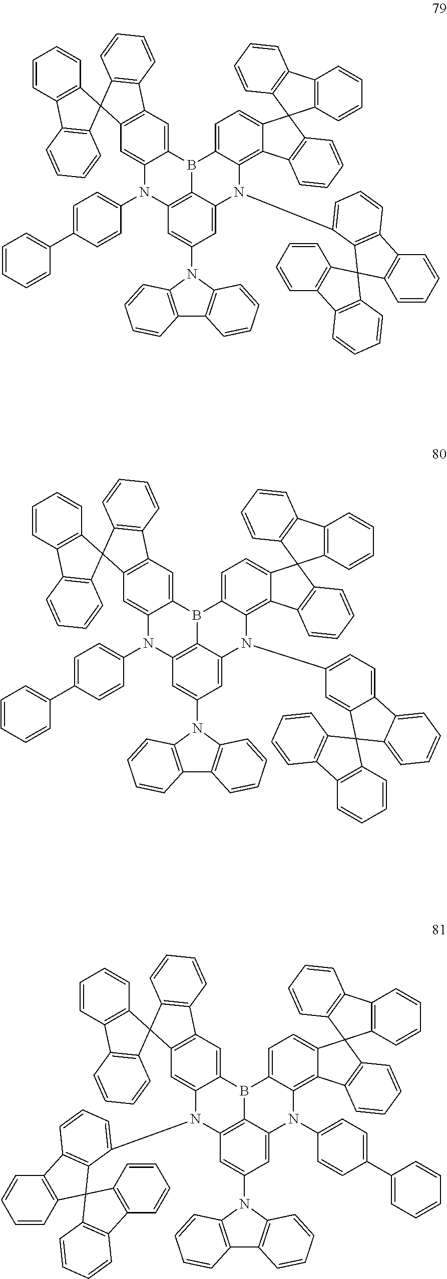 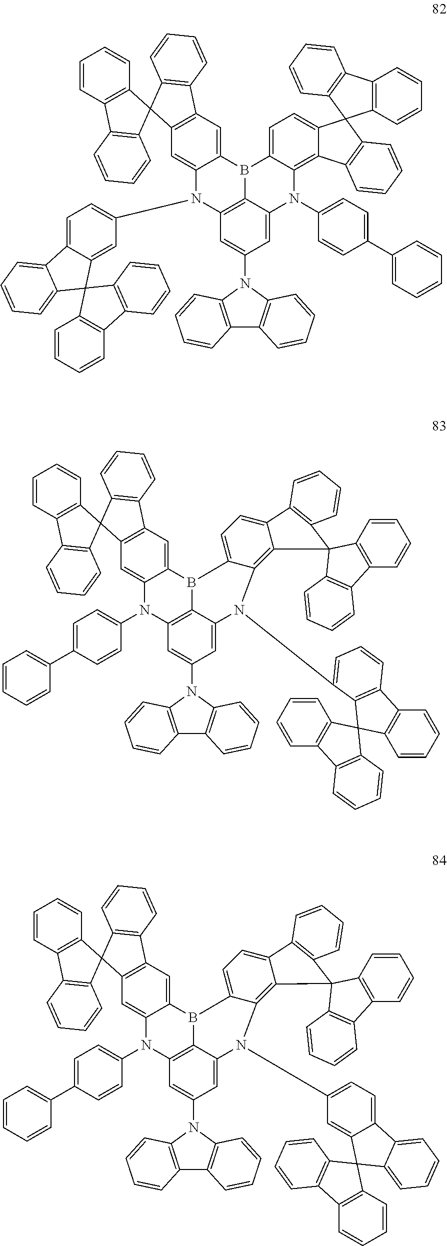 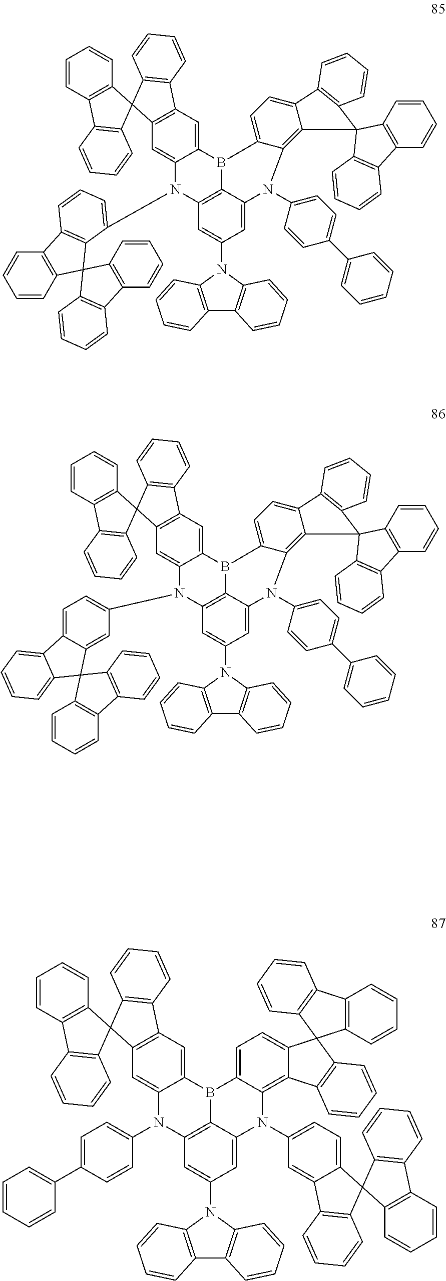 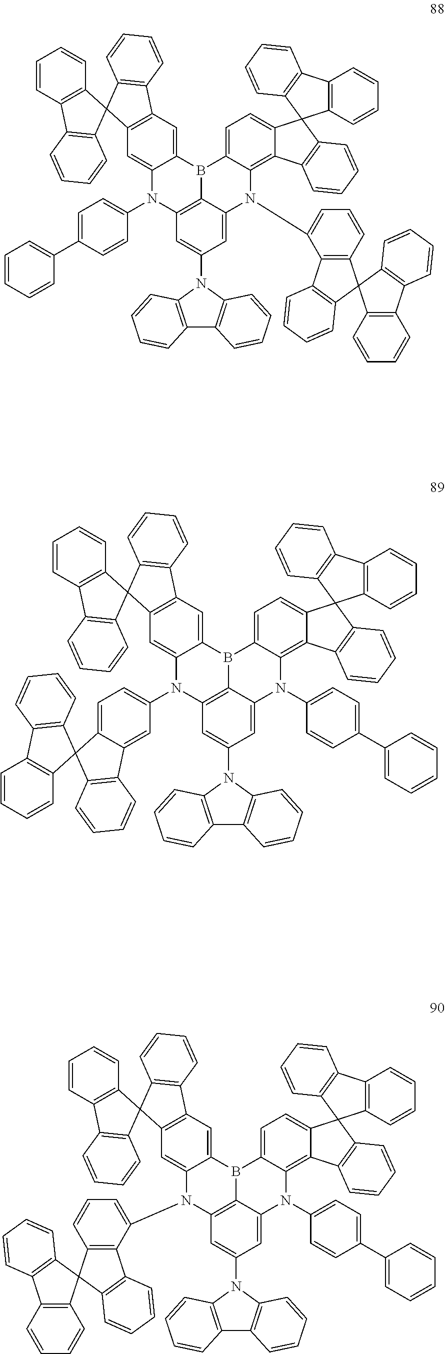 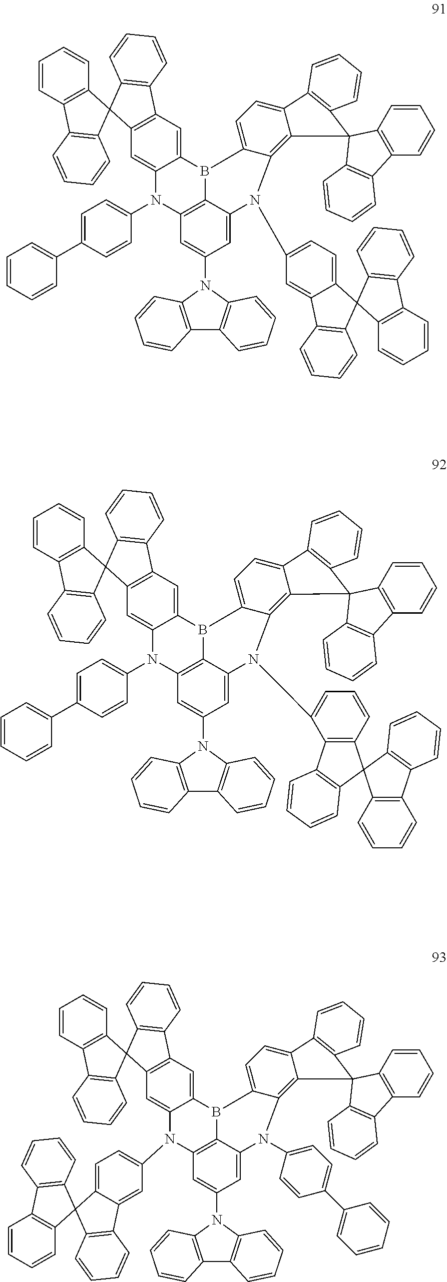 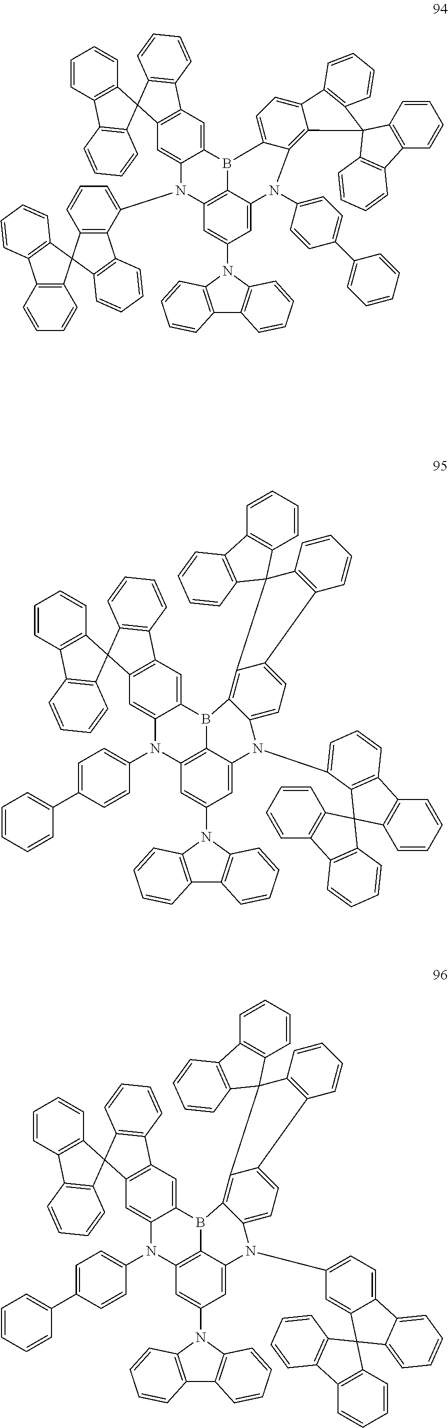 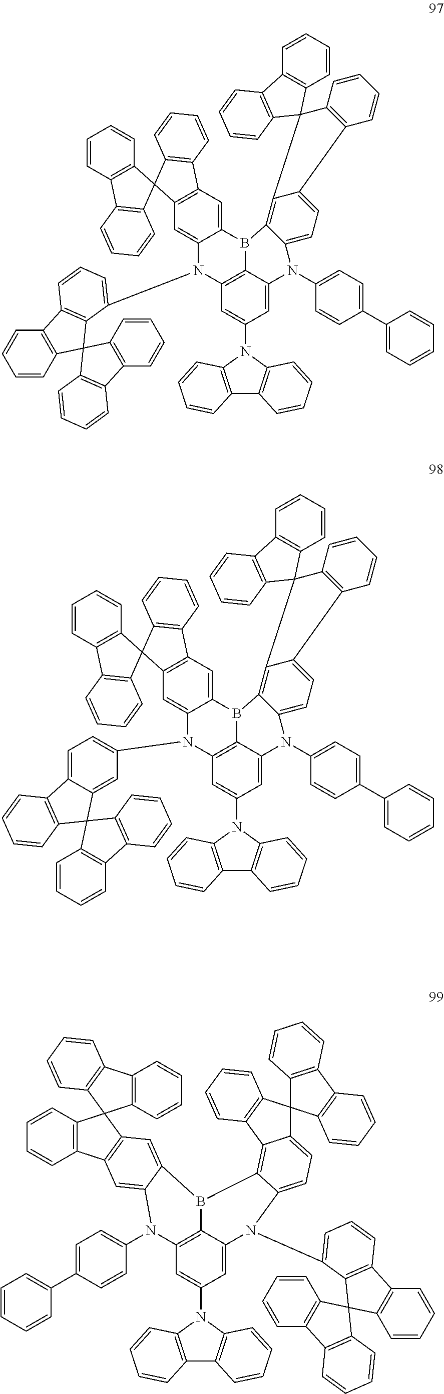 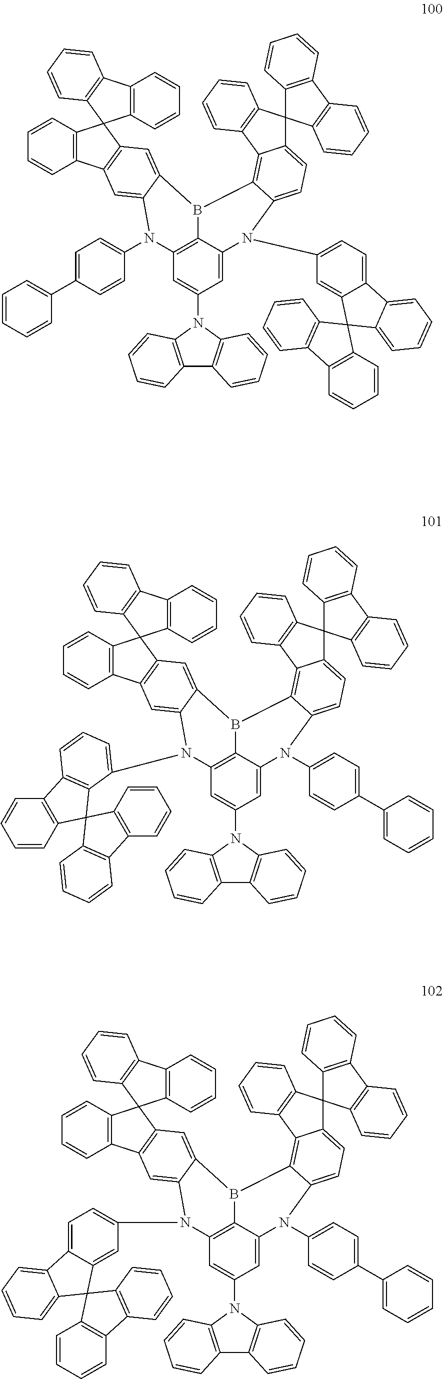 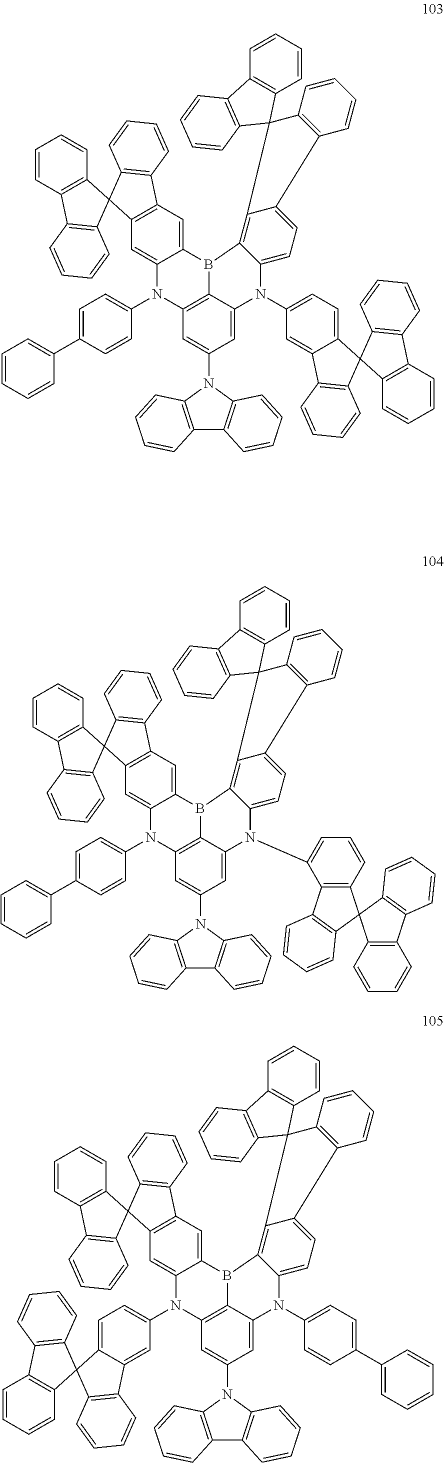 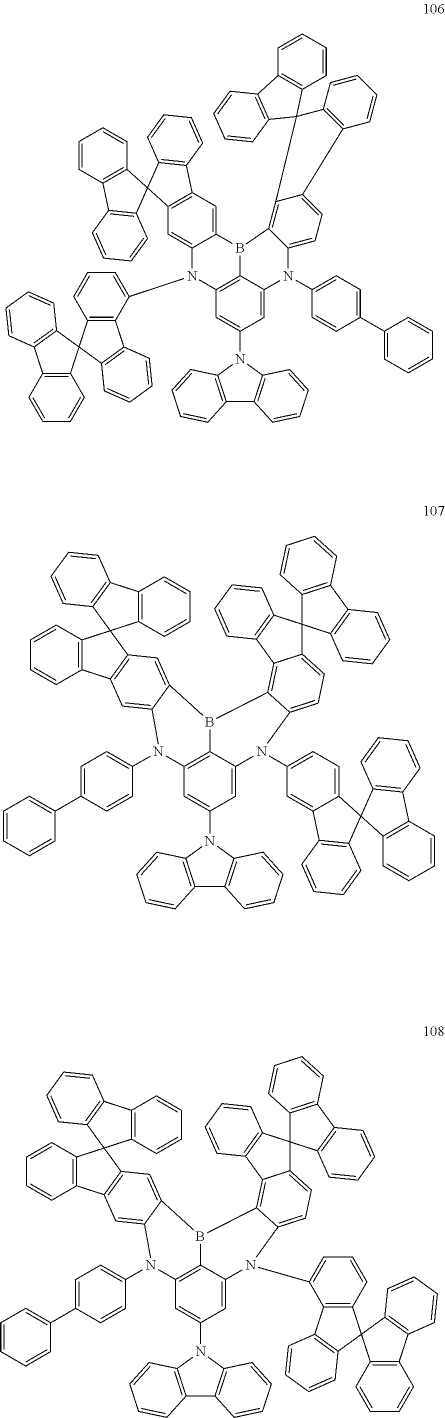 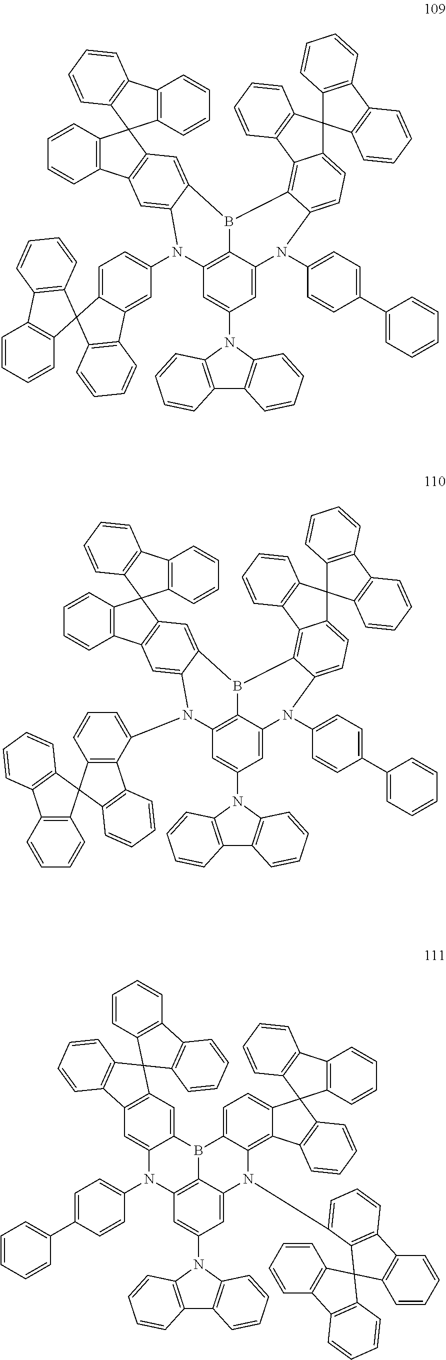 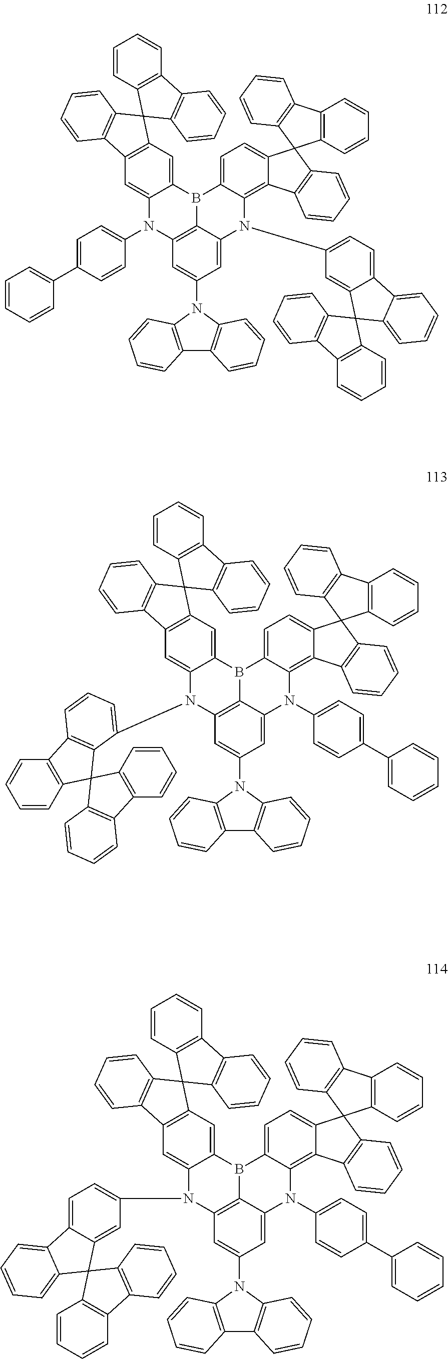 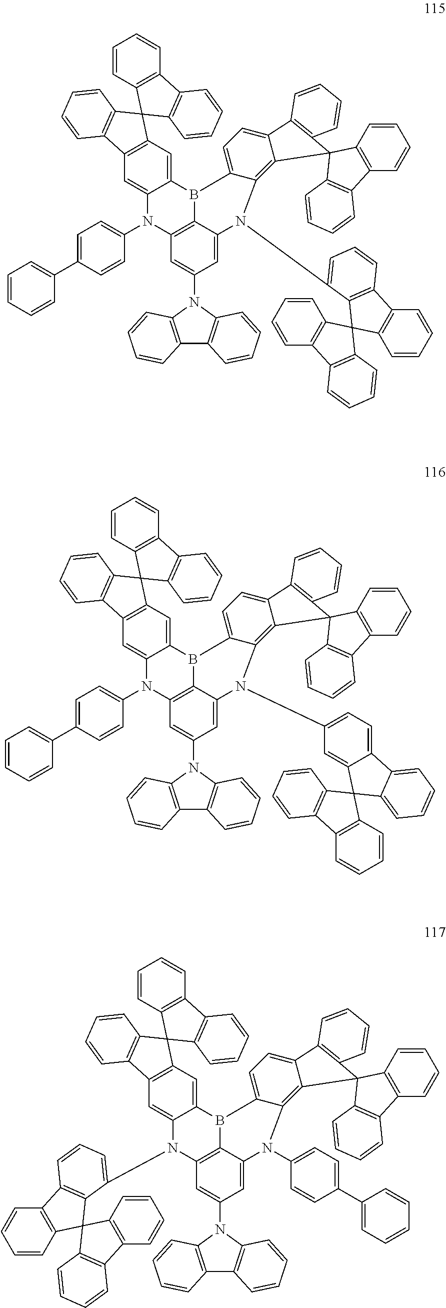 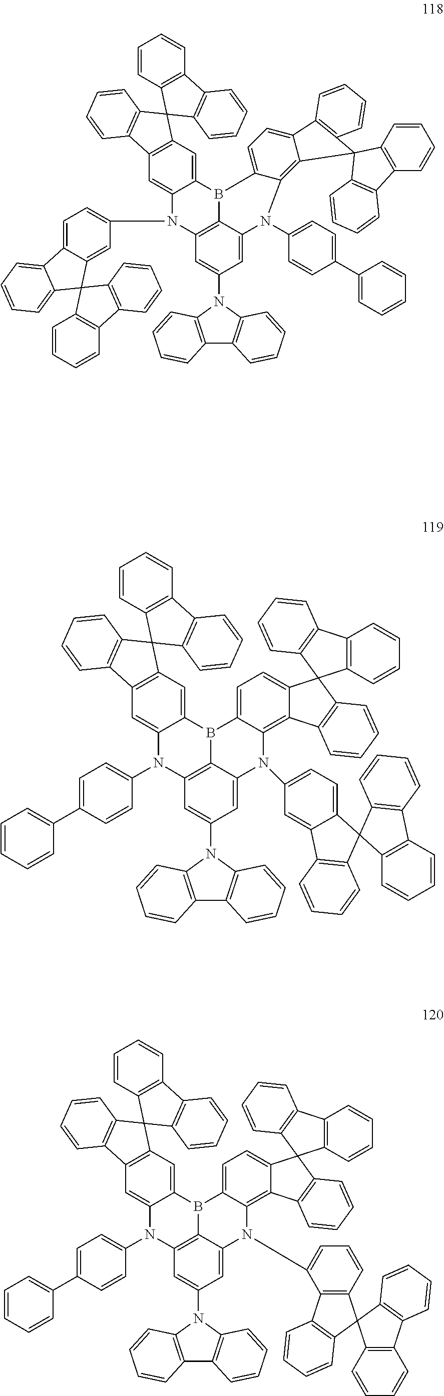 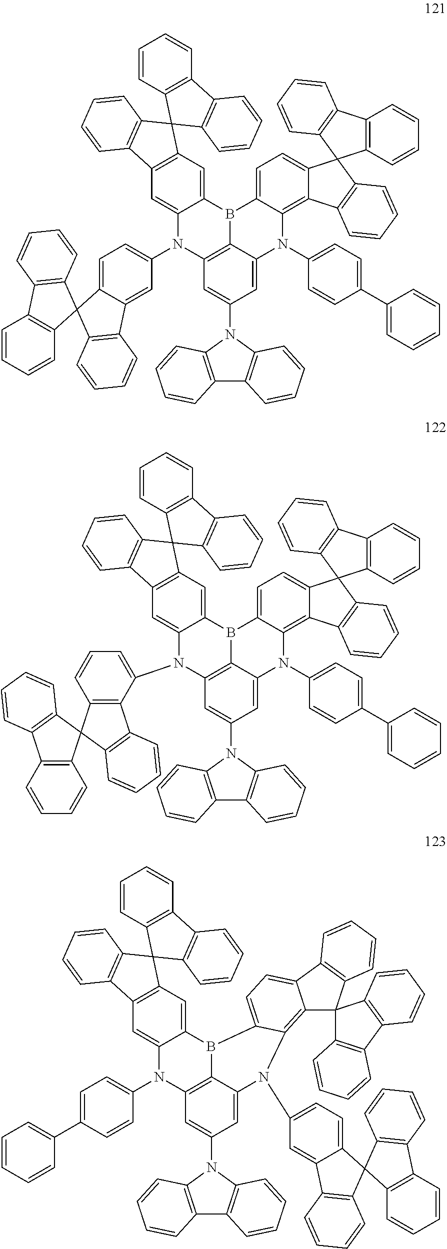 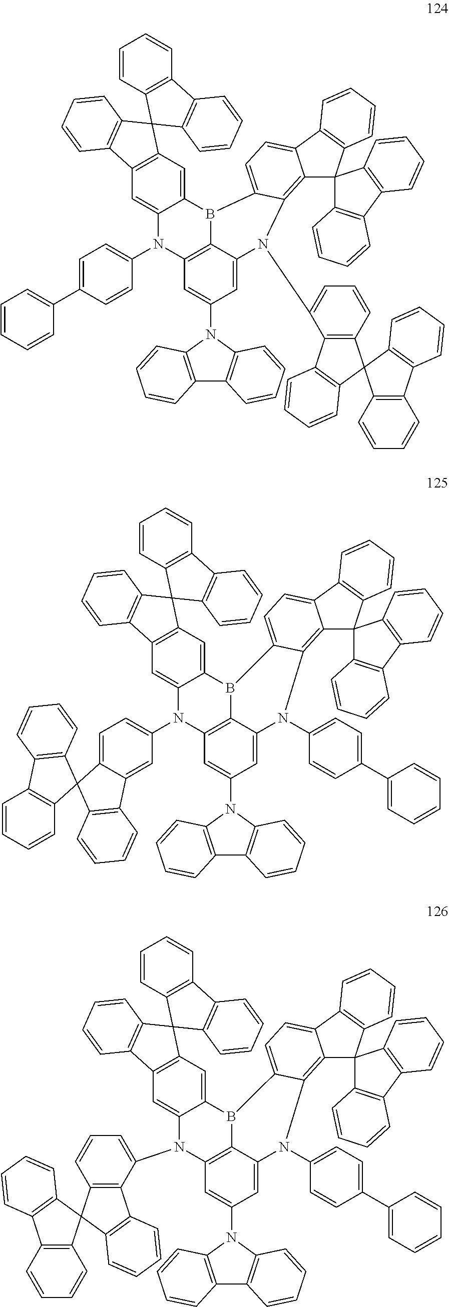 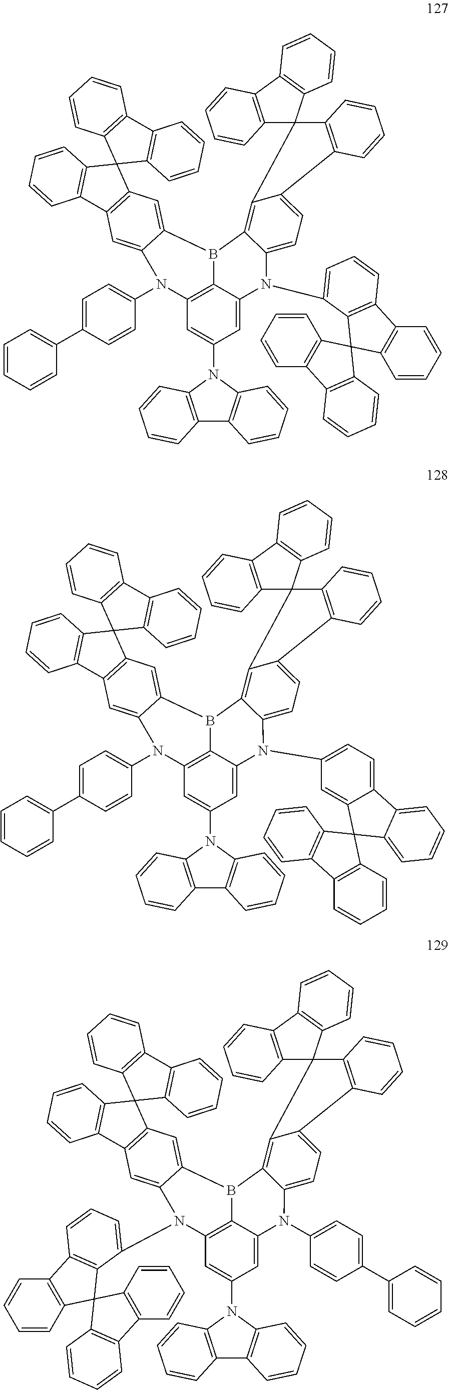 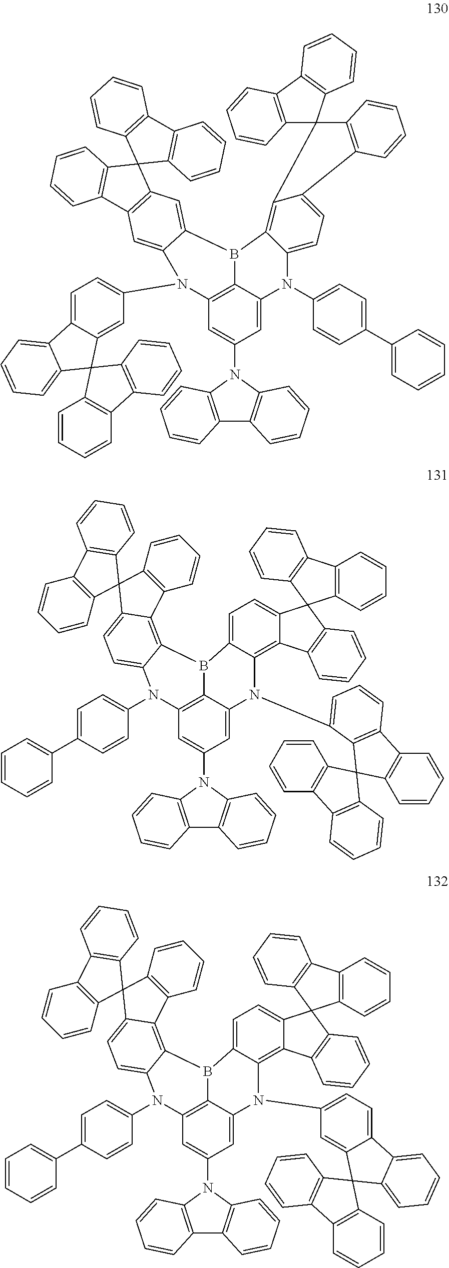 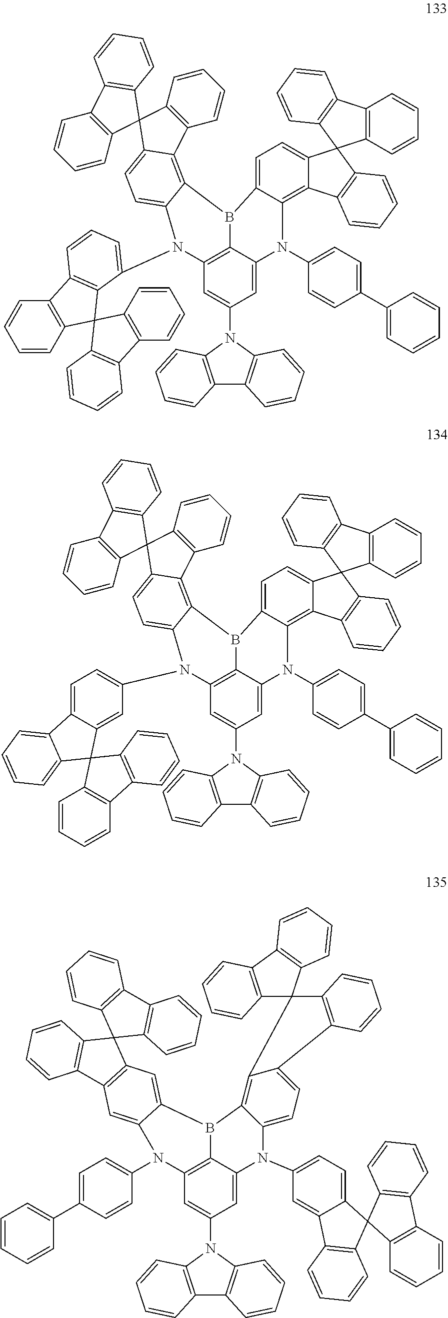 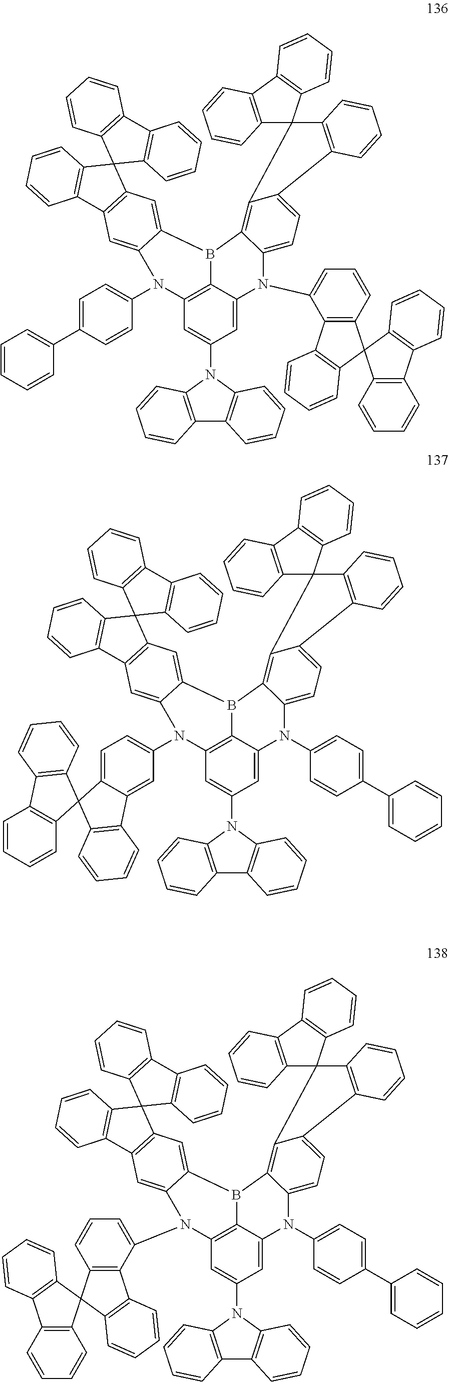 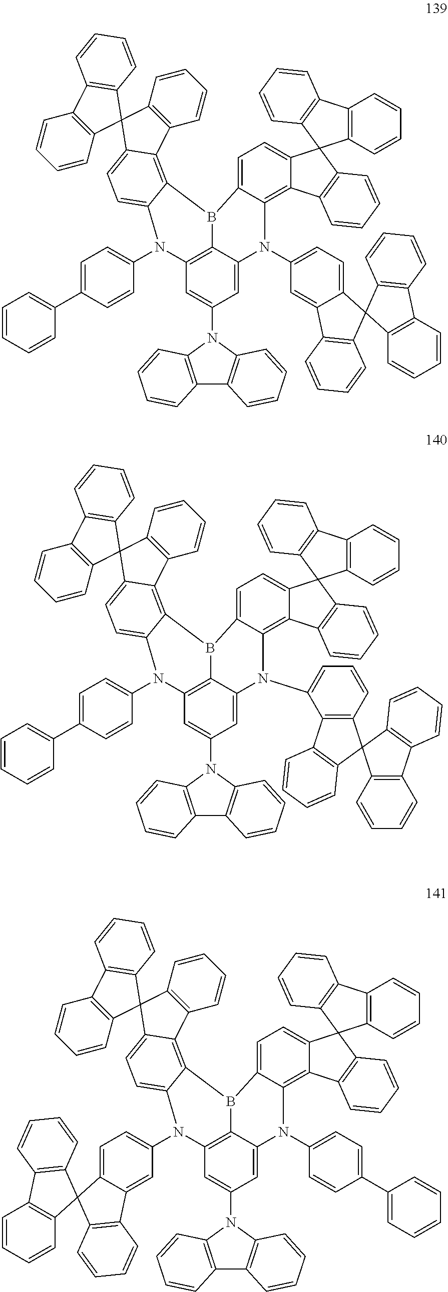 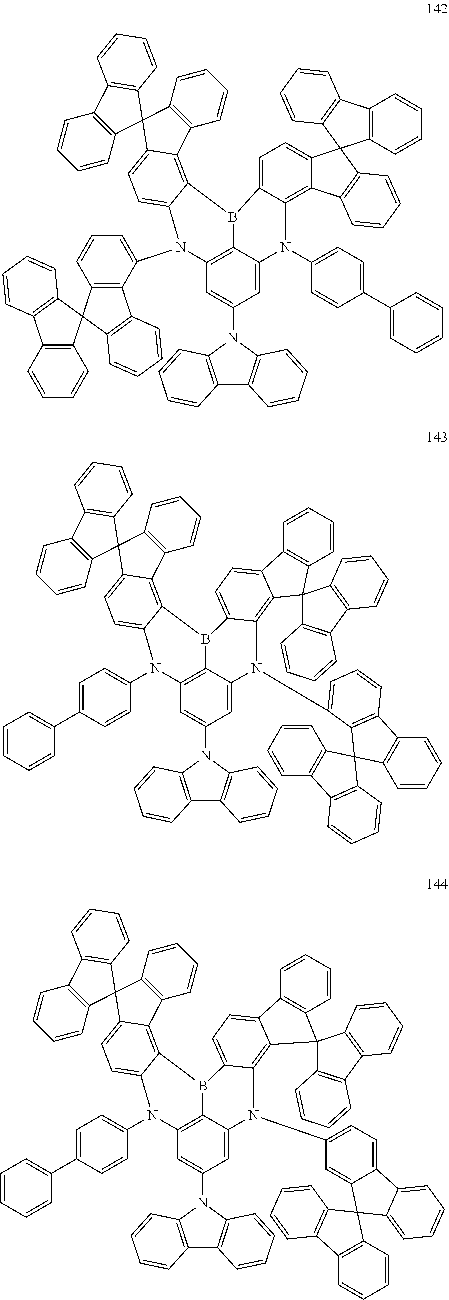 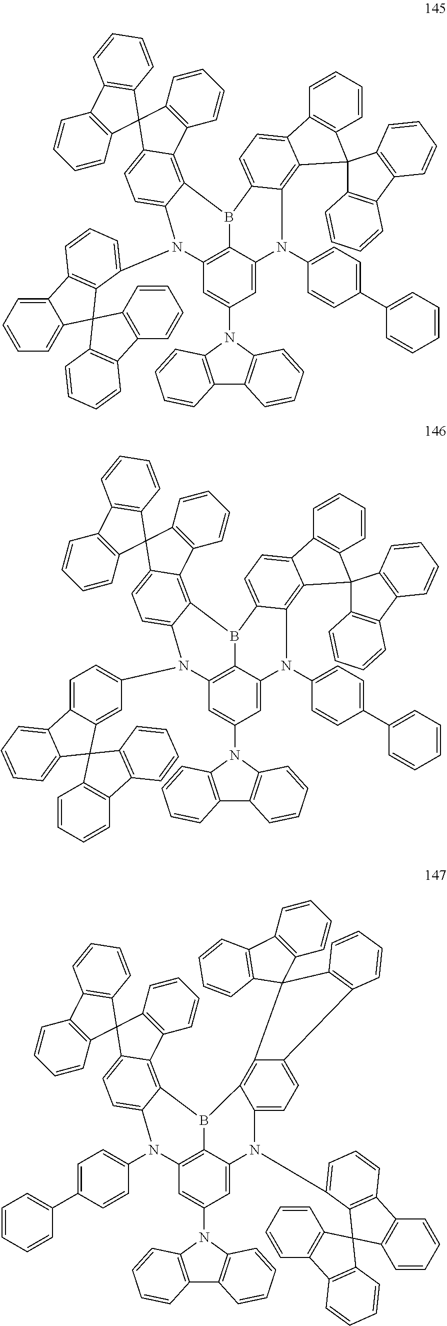 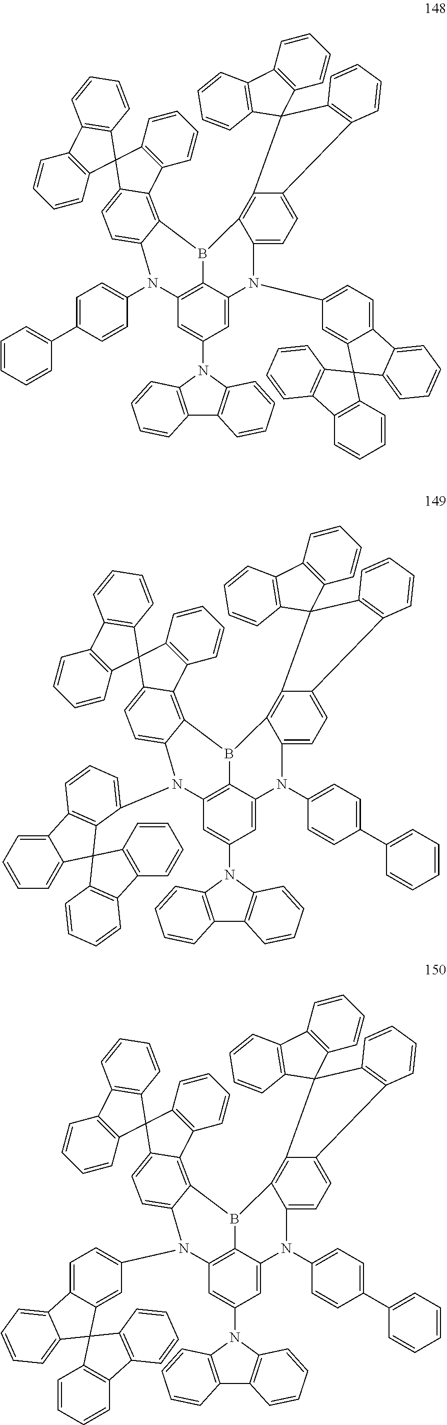 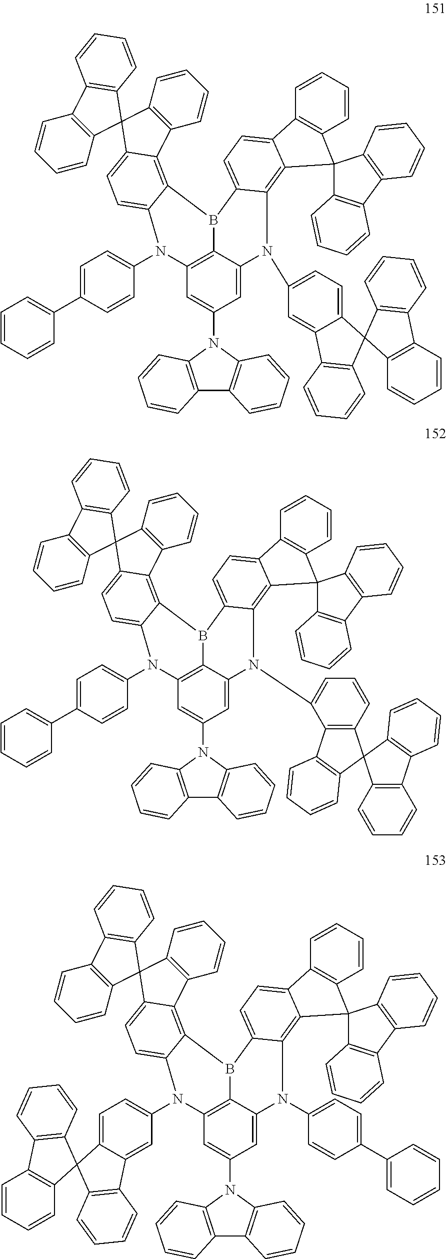 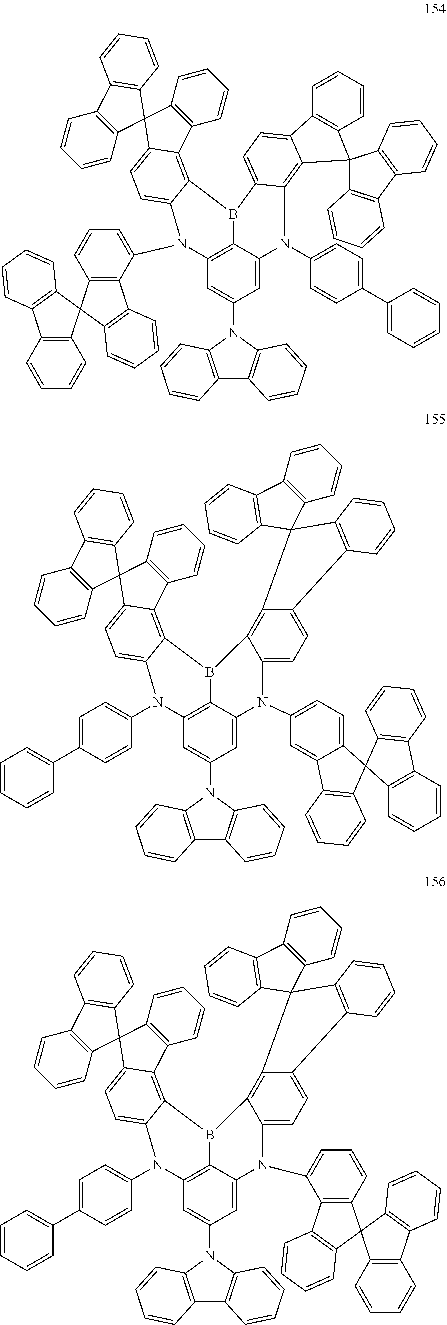 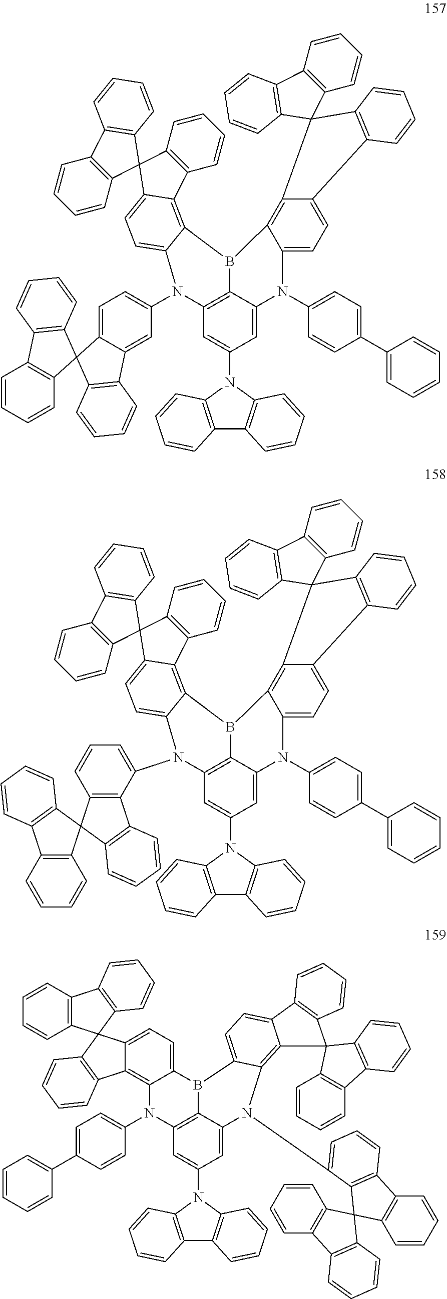 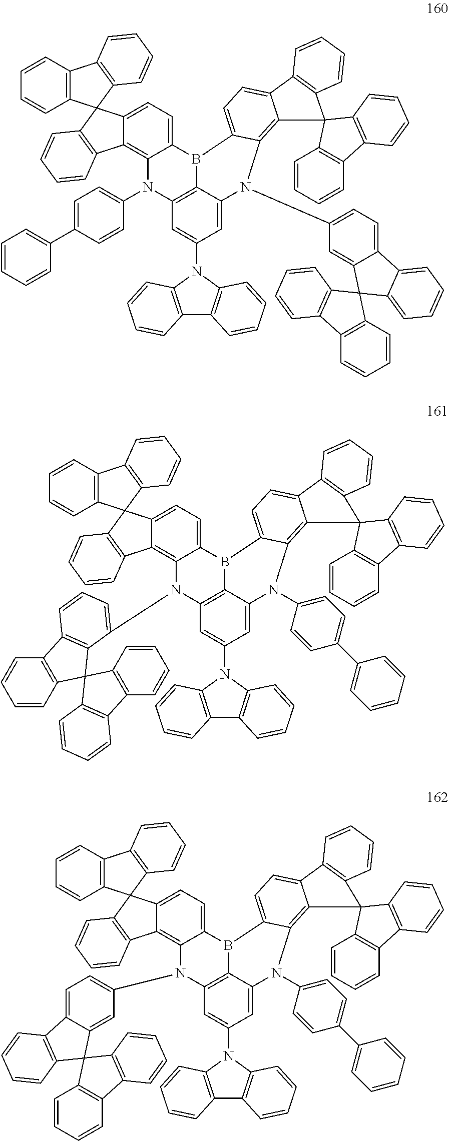 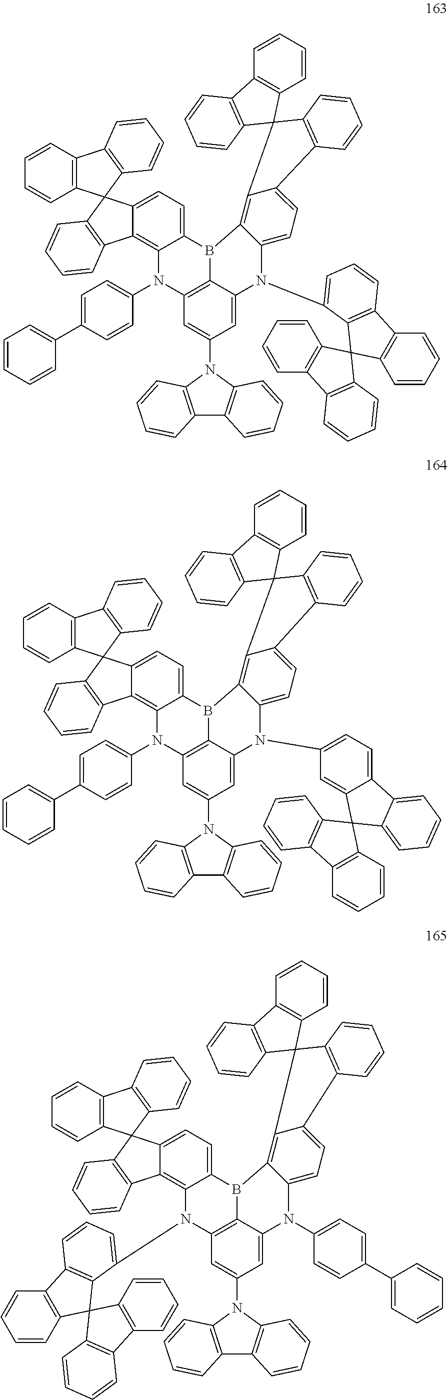 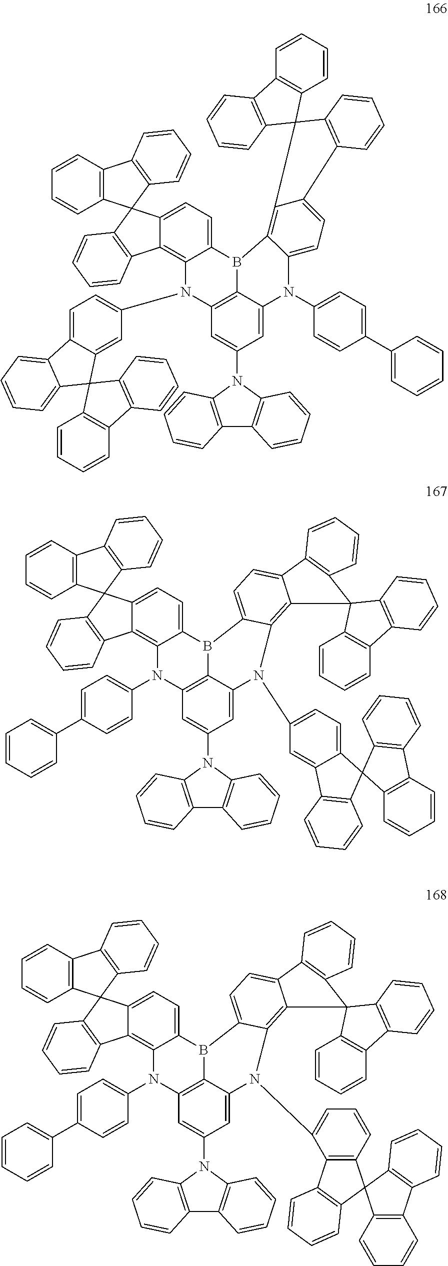 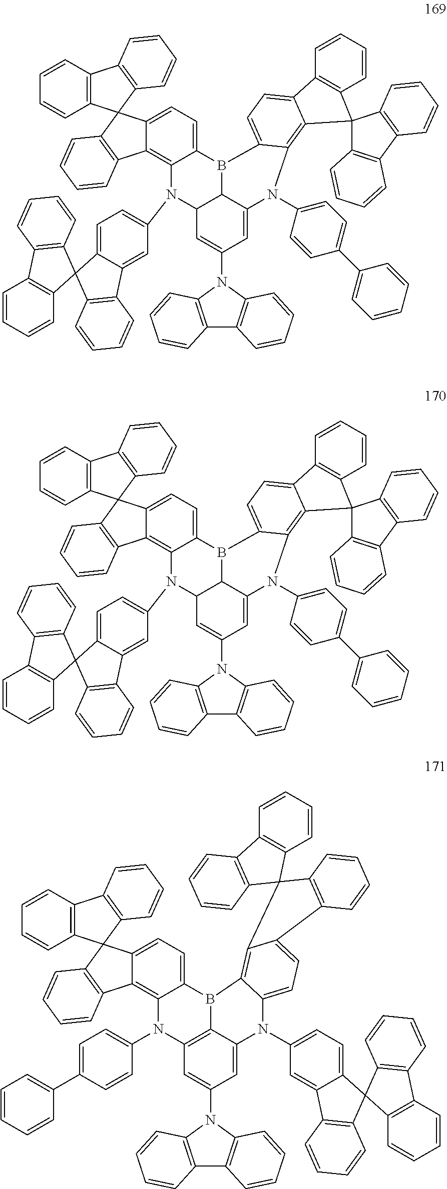 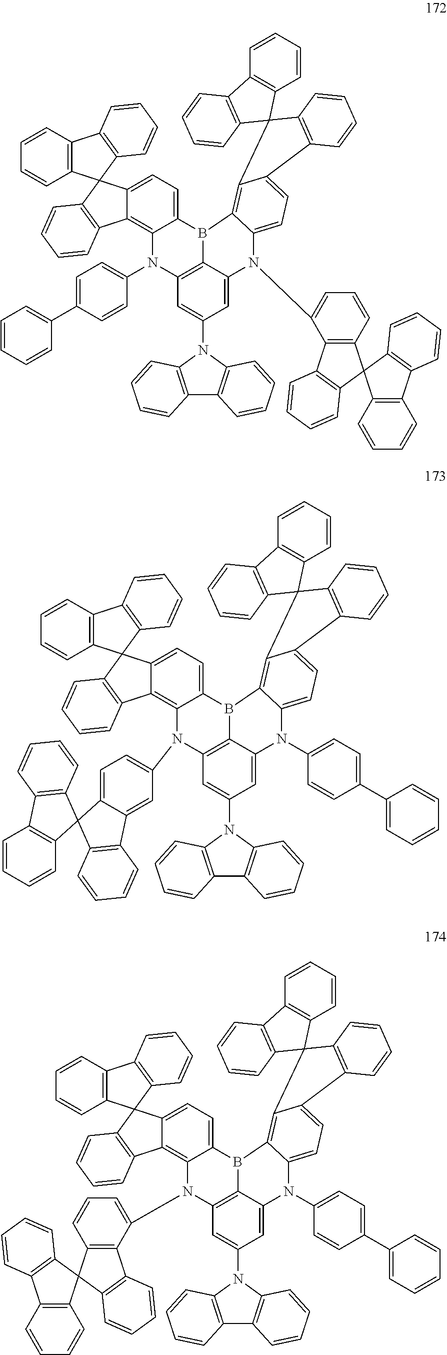 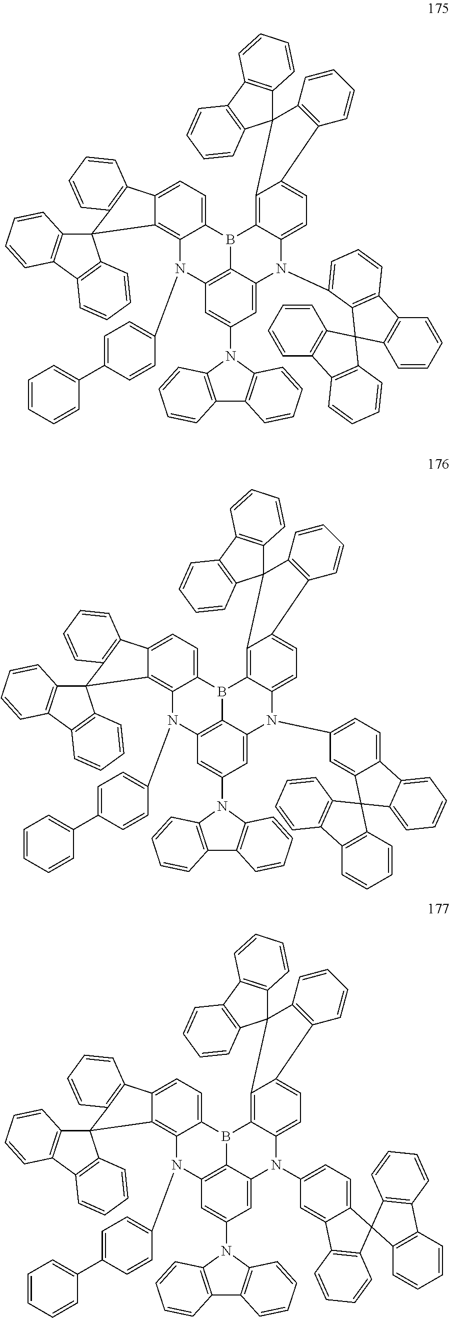 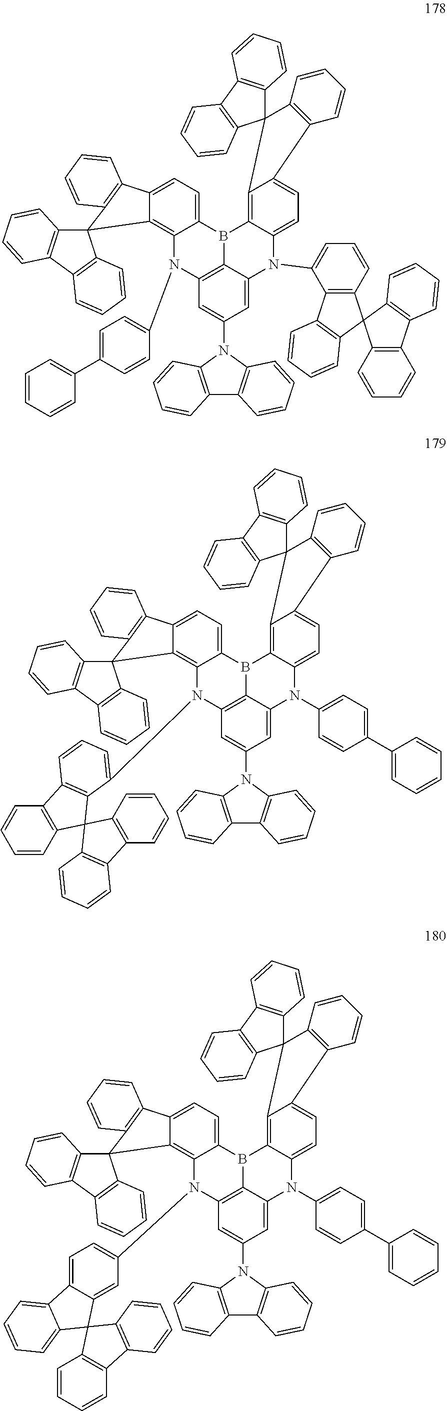 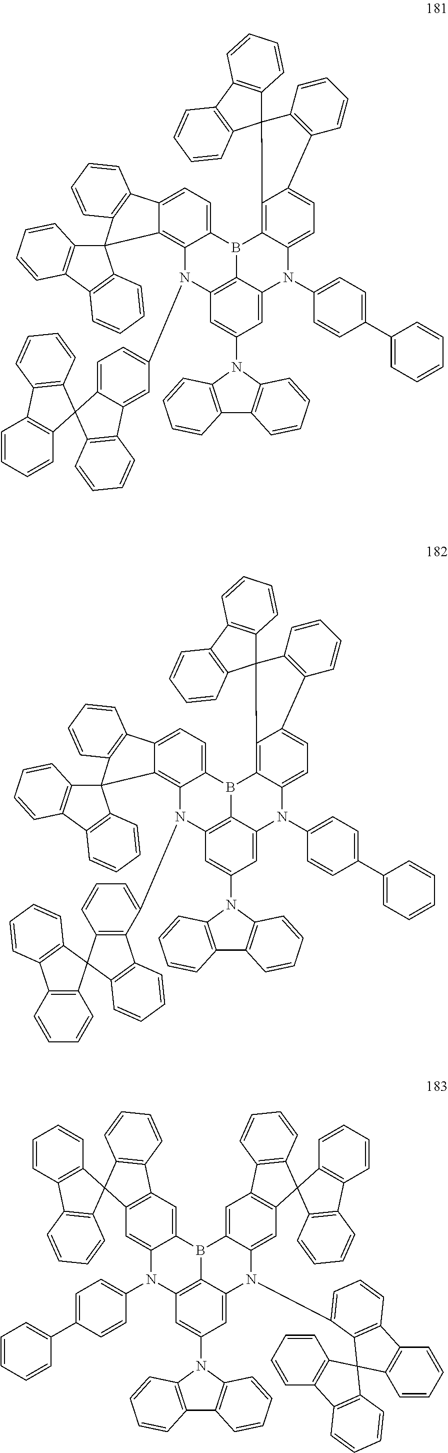 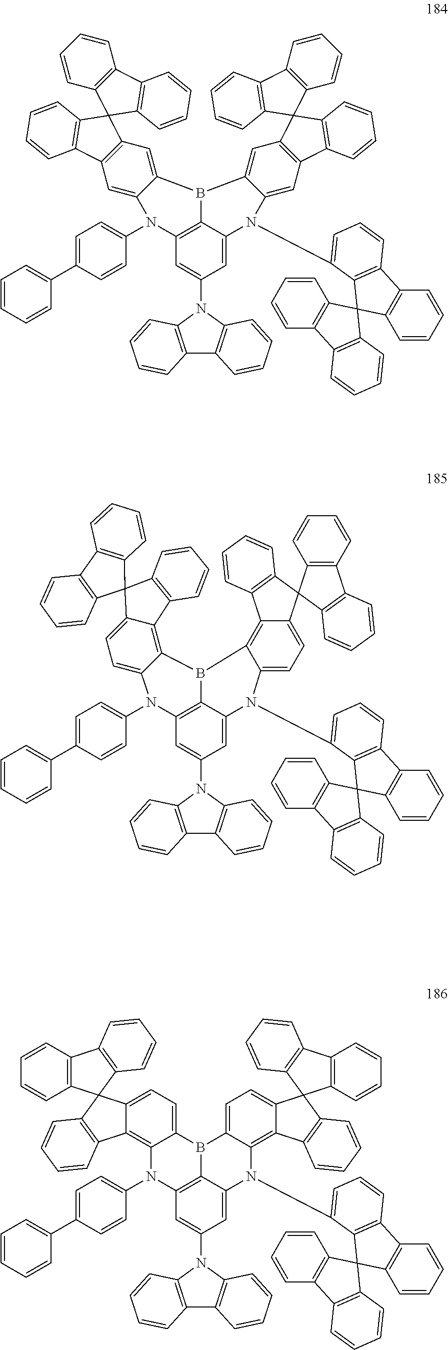 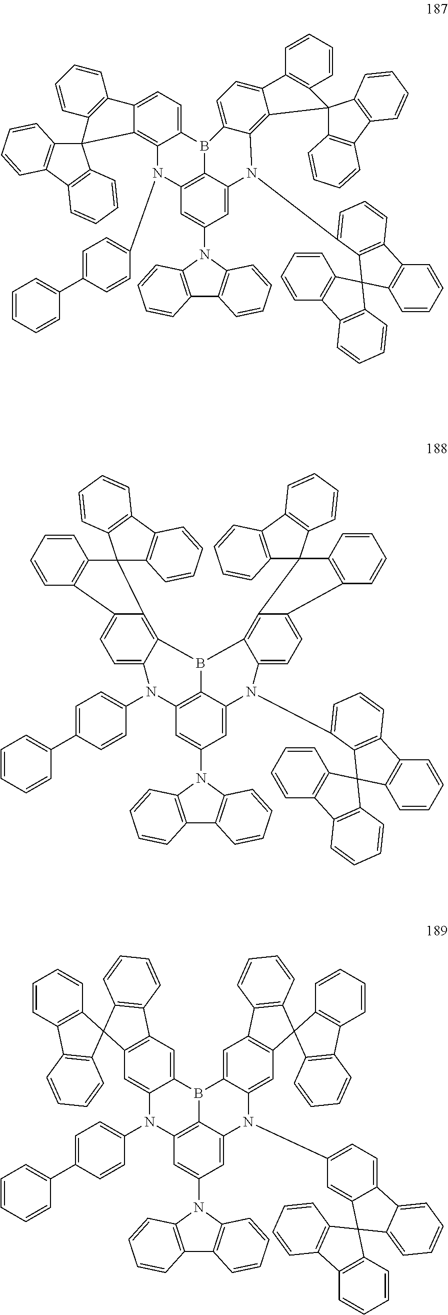 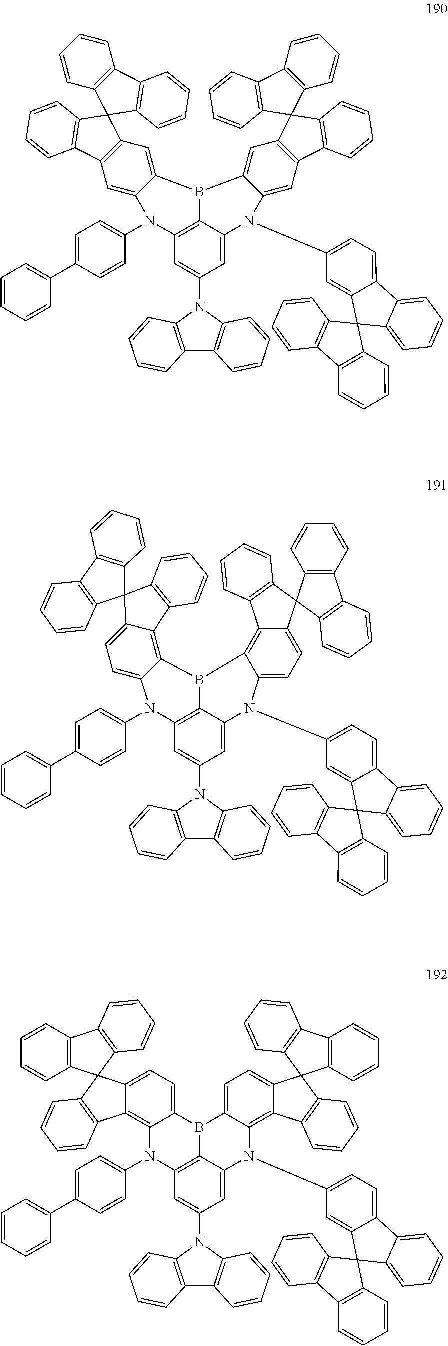 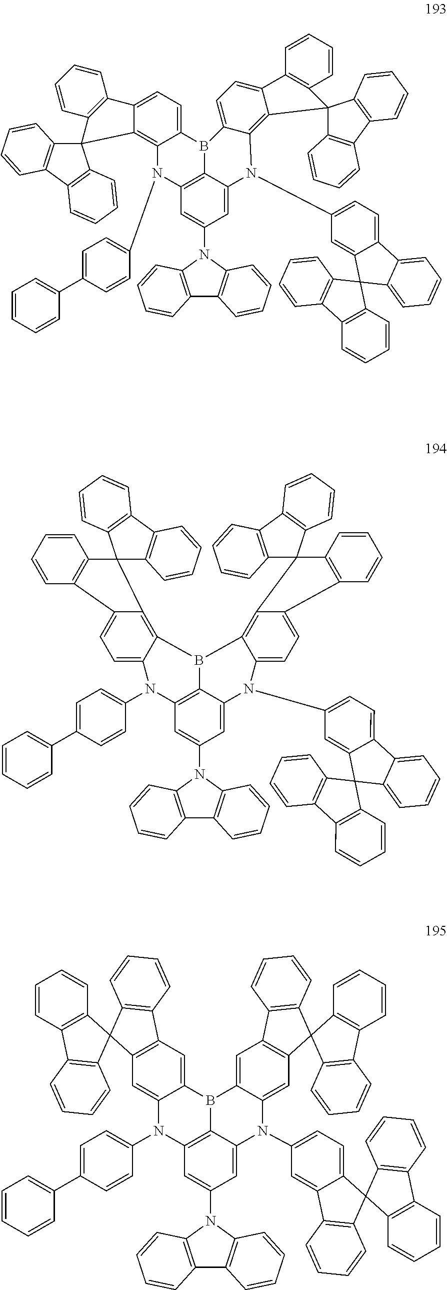 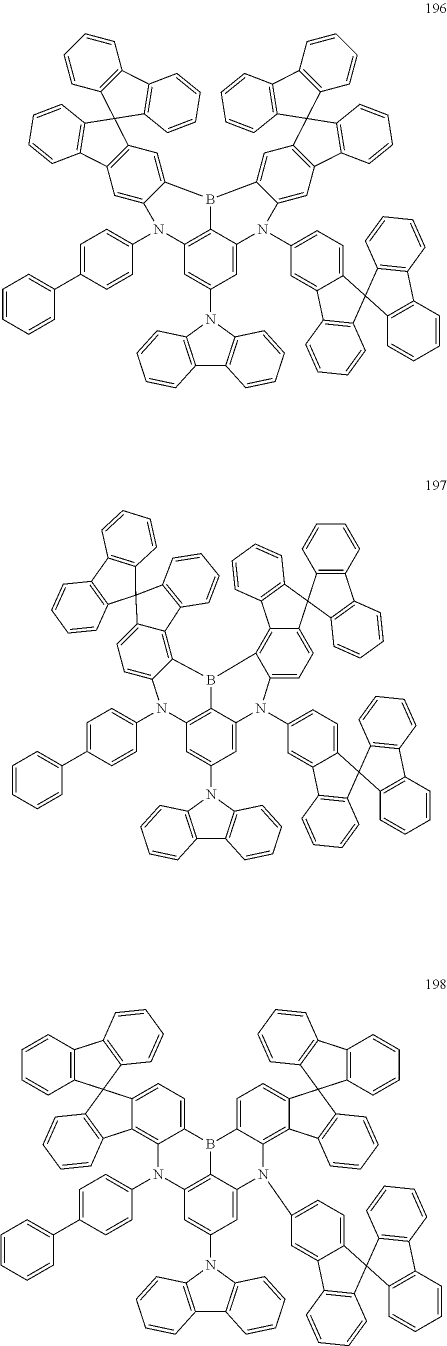 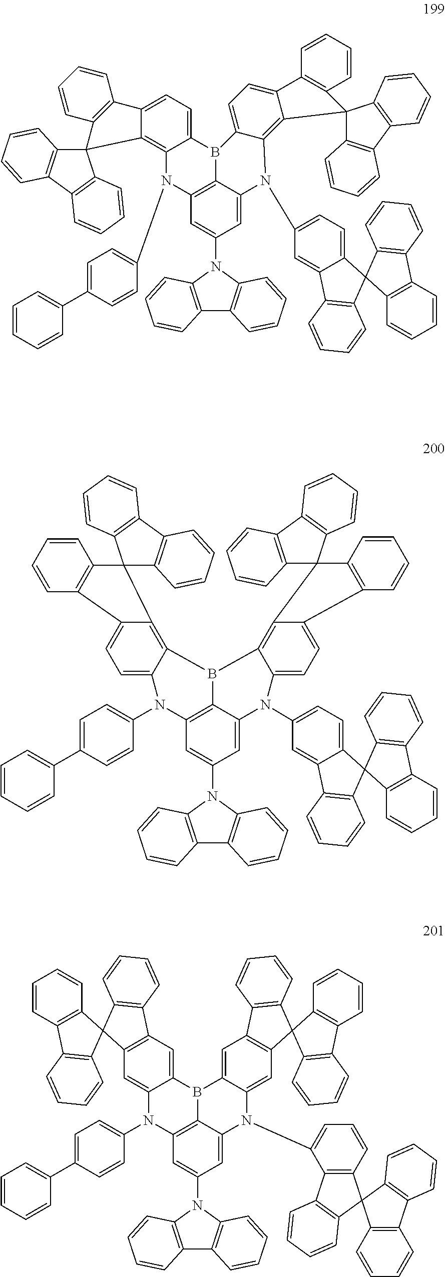 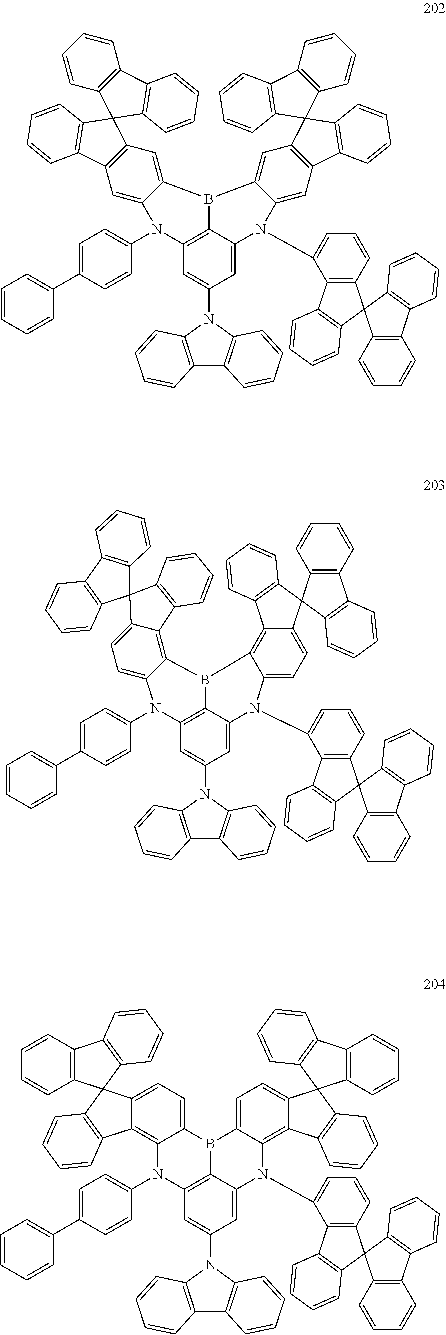 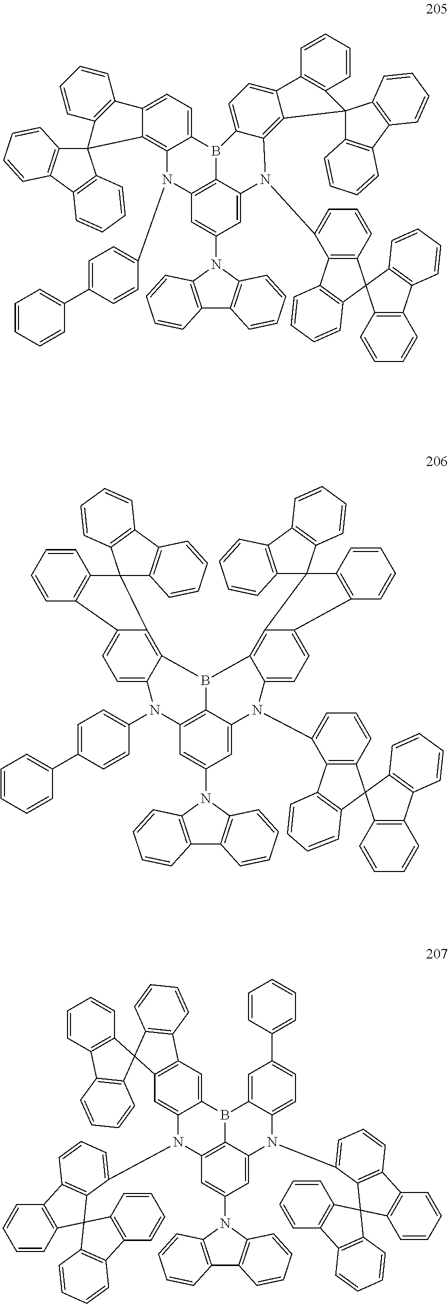 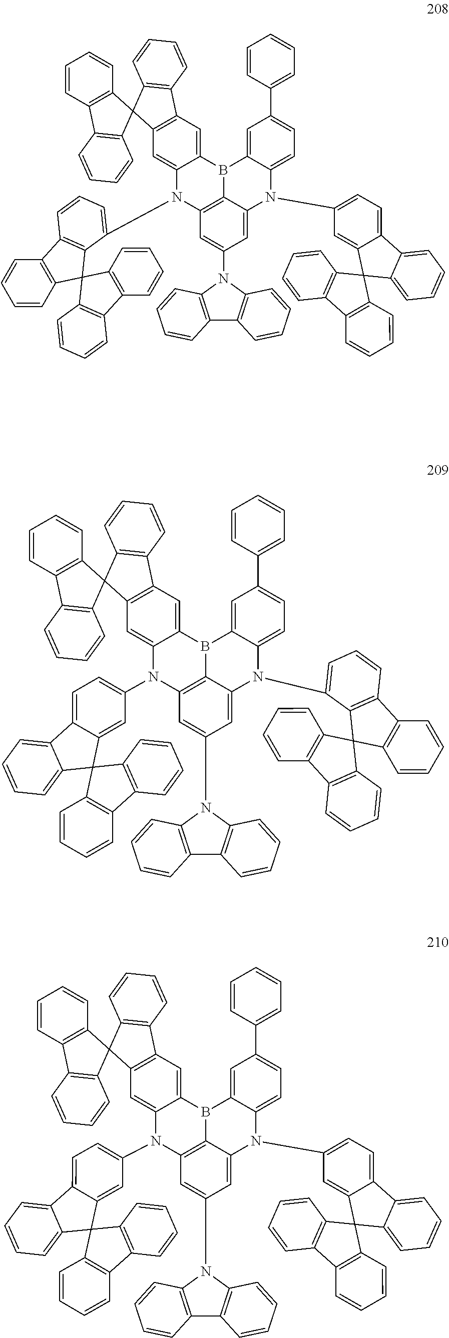 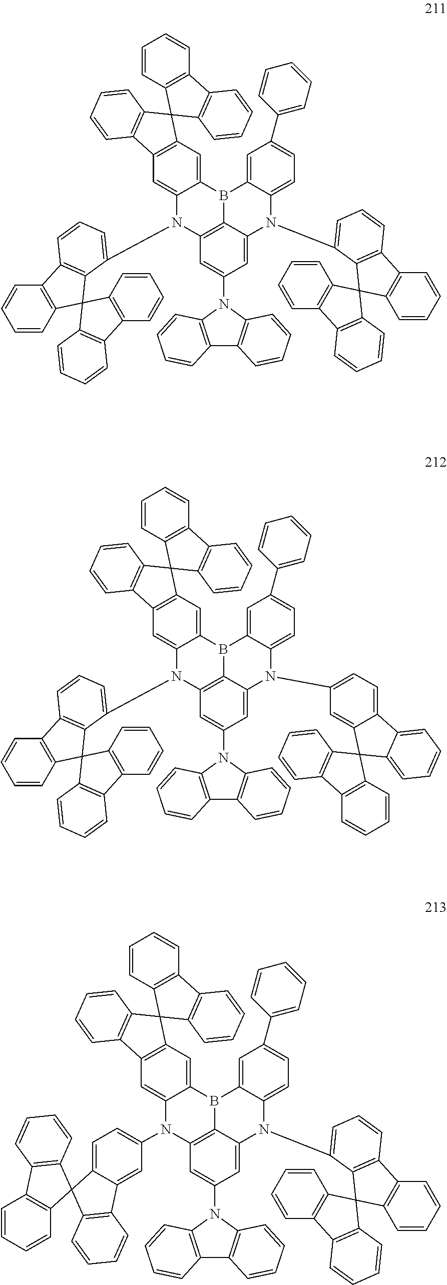 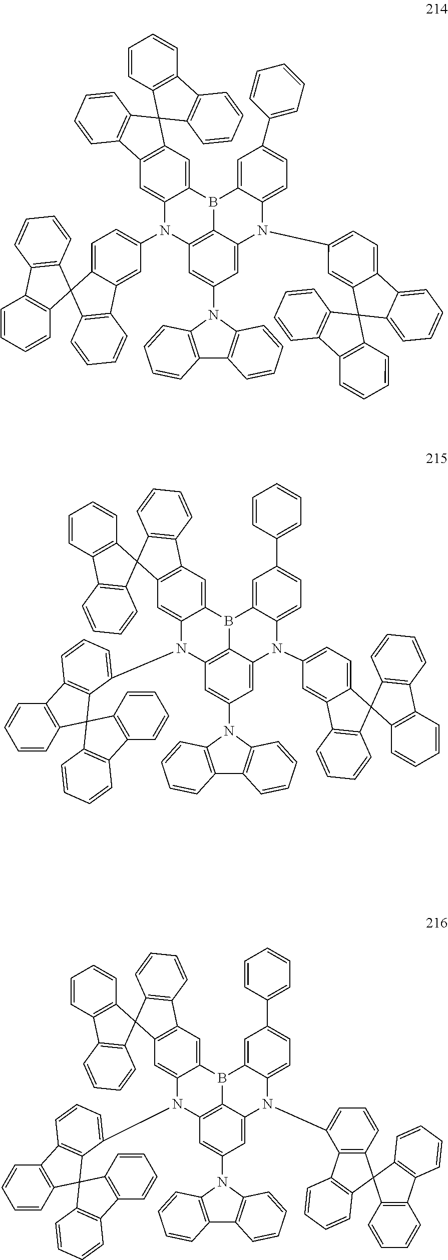 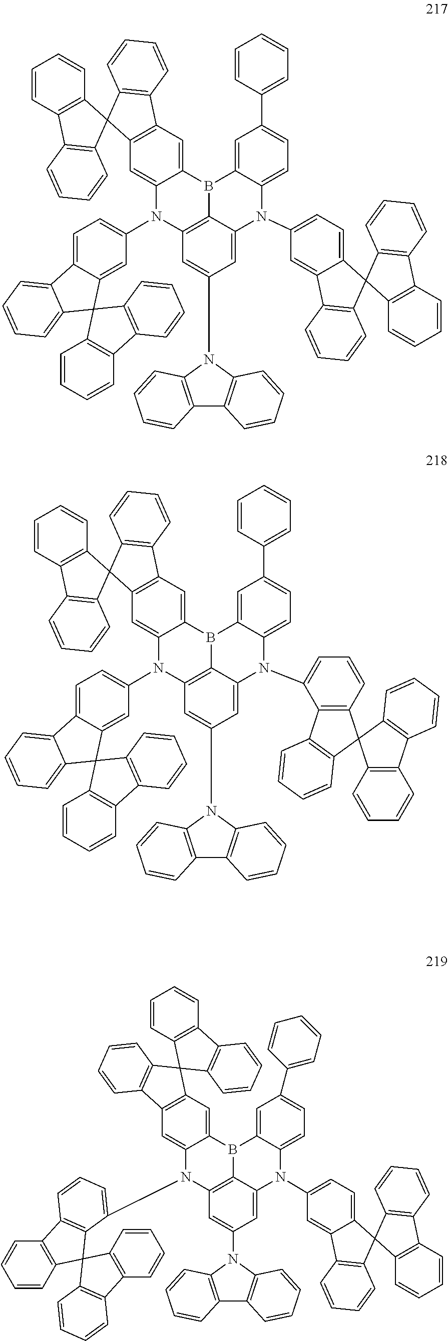 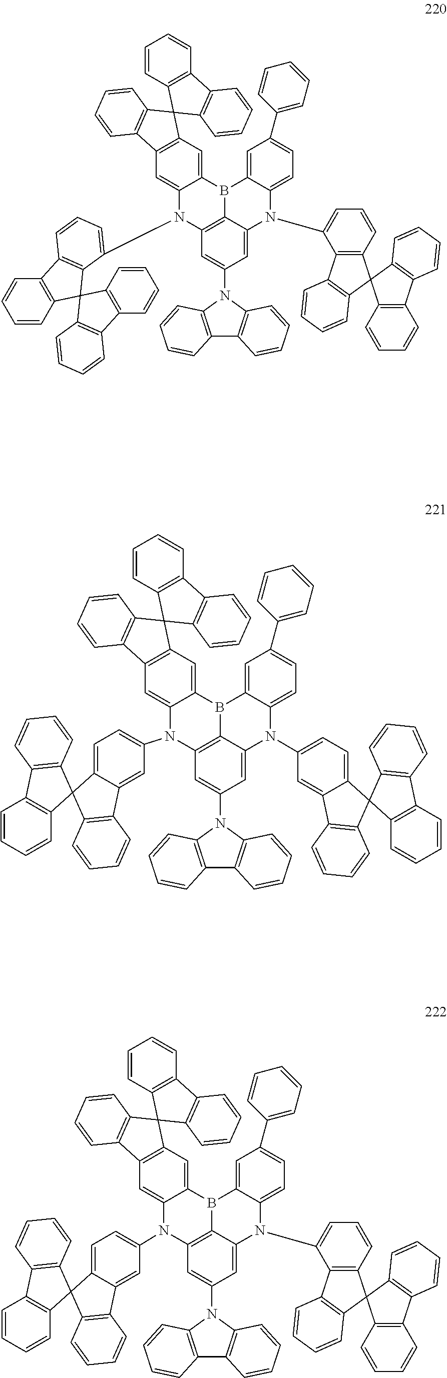 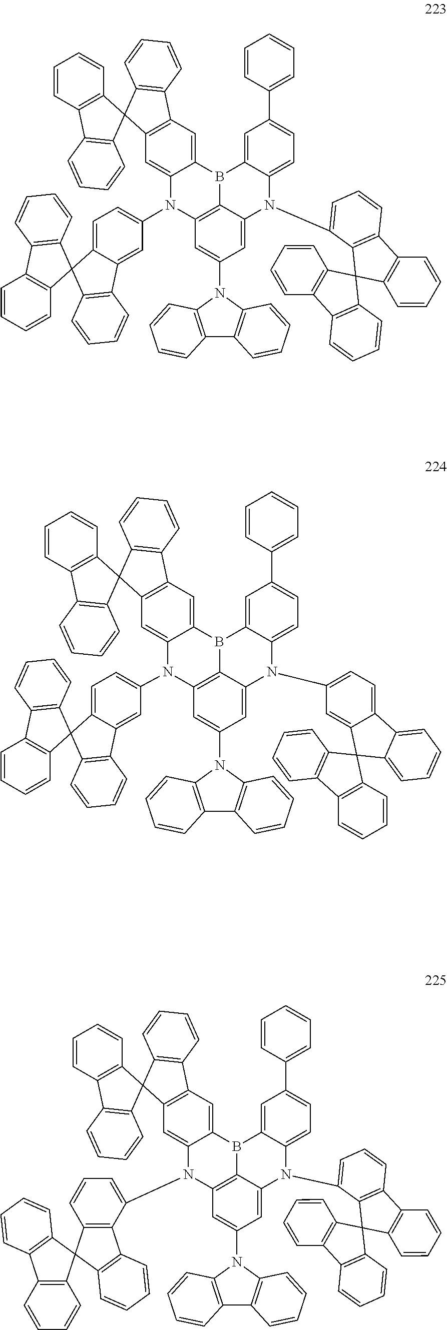 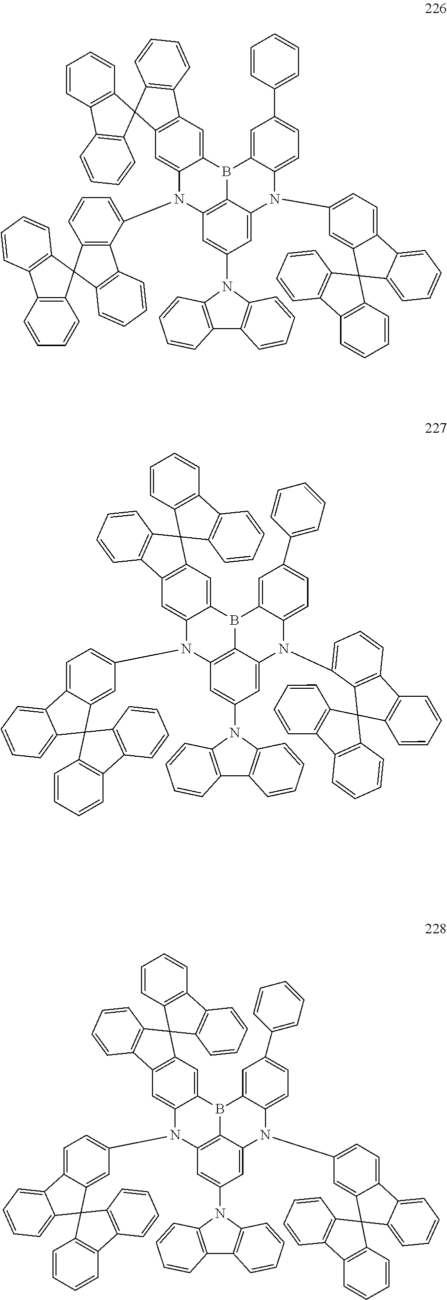 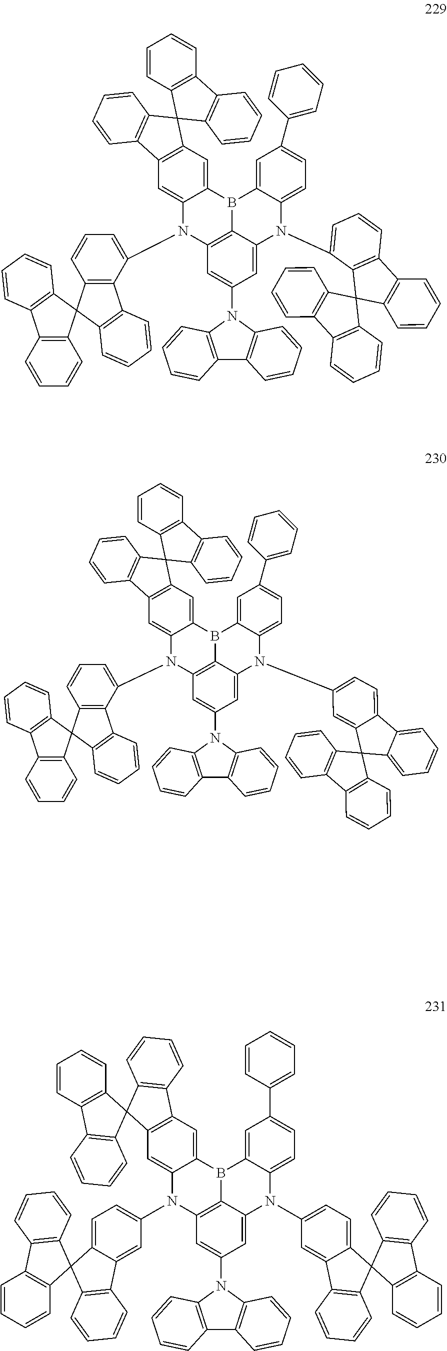 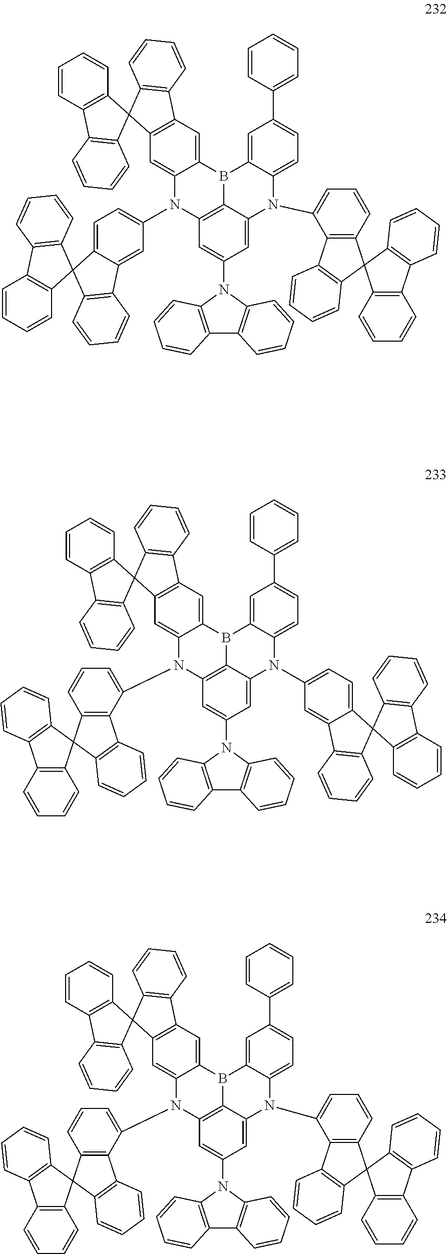 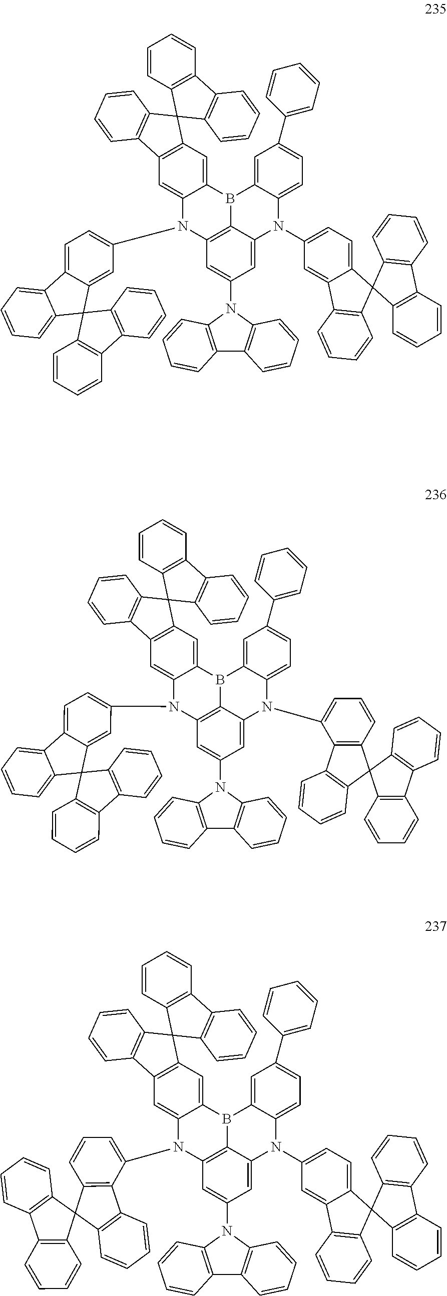 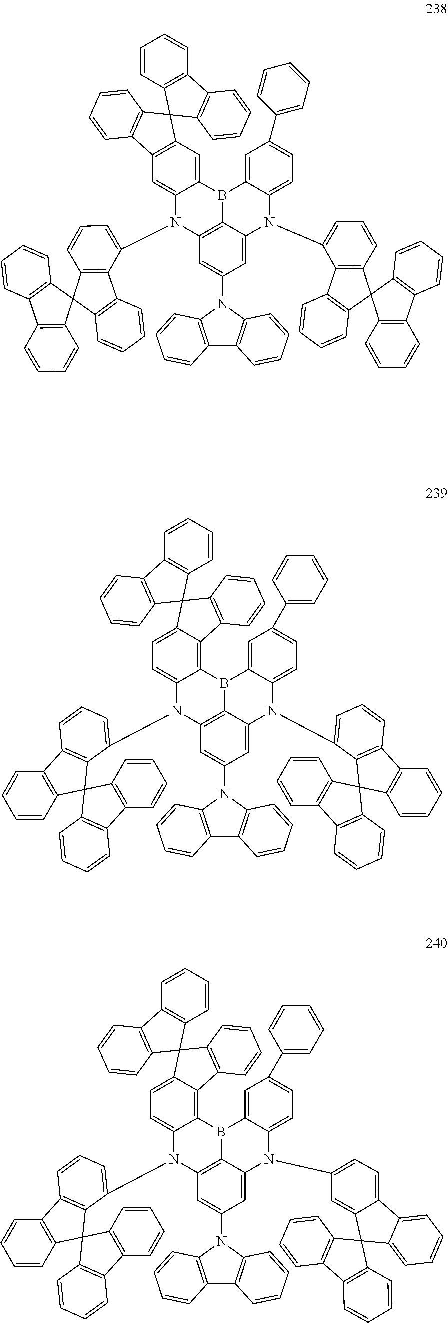 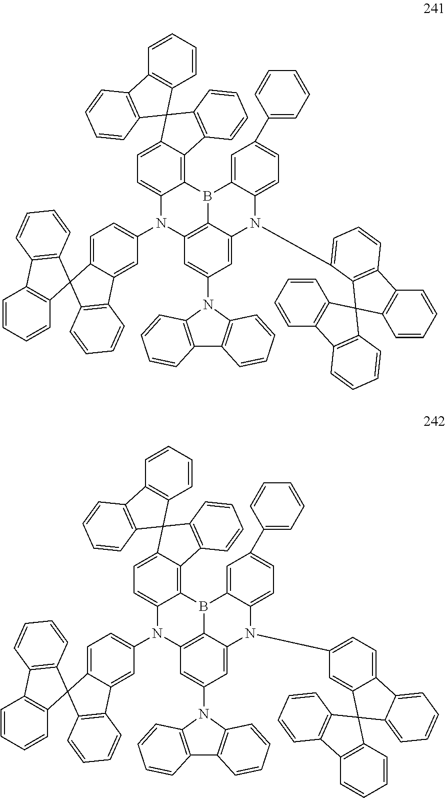 [SMILES: c1ccc(-c2ccc3c(c2)B2c4c(cc(-n5c6ccccc6c6ccccc65)cc4N3c3cccc4c3C3(c5ccccc5-c5ccccc53)c3ccccc3-4)N(c3ccc4c(c3)-c3ccccc3C43c4ccccc4-c4ccccc43)c3ccc4c(c32)-c2ccccc2C42c3ccccc3-c3ccccc32)cc1 ; c1ccc(-c2ccc3c(c2)B2c4c(cc(-n5c6ccccc6c6ccccc65)cc4N(c4ccc5c(c4)-c4ccccc4C54c5ccccc5-c5ccccc54)c4ccc5c(c42)-c2ccccc2C52c4ccccc4-c4ccccc42)N3c2ccc3c(c2)C2(c4ccccc4-c4ccccc42)c2ccccc2-3)cc1] 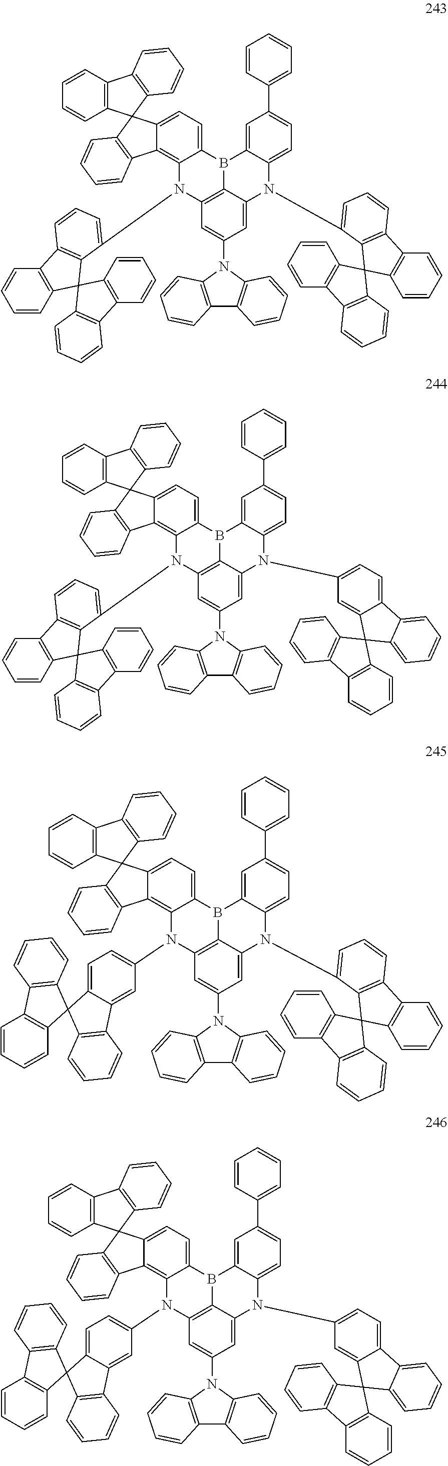 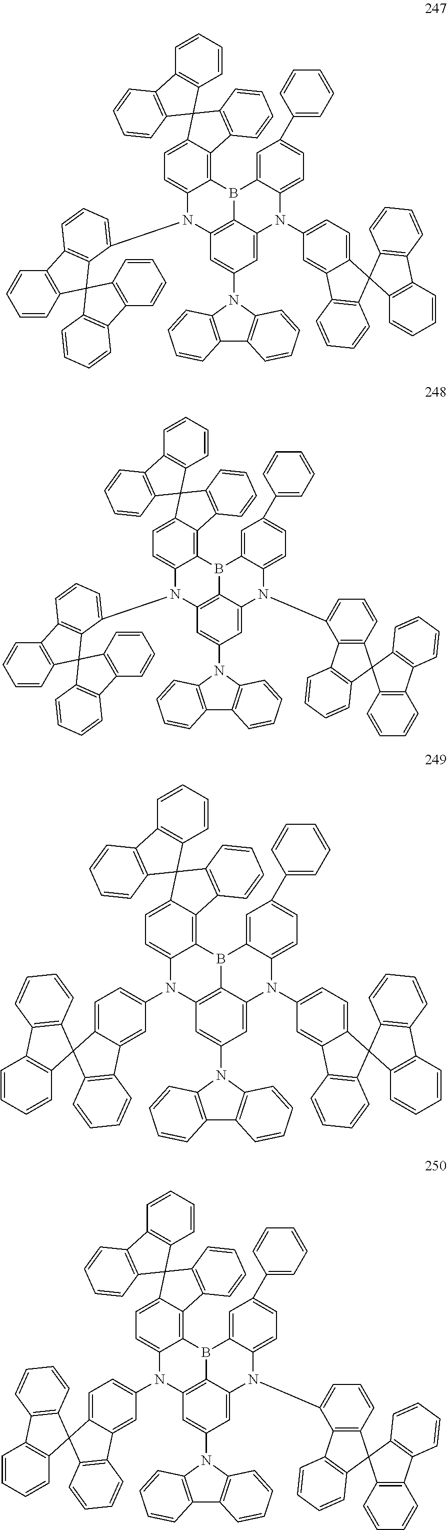 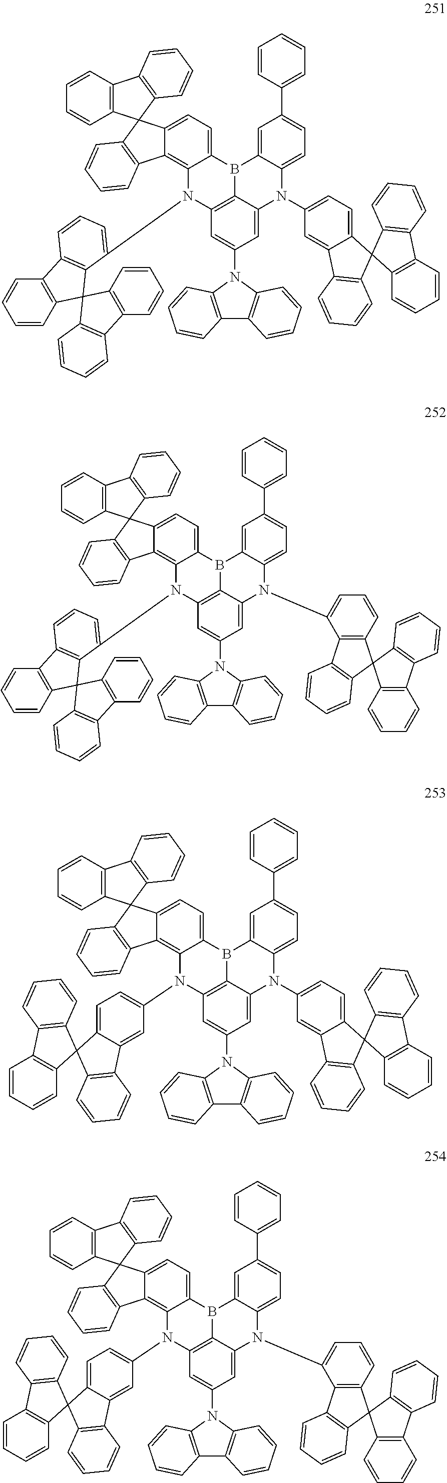 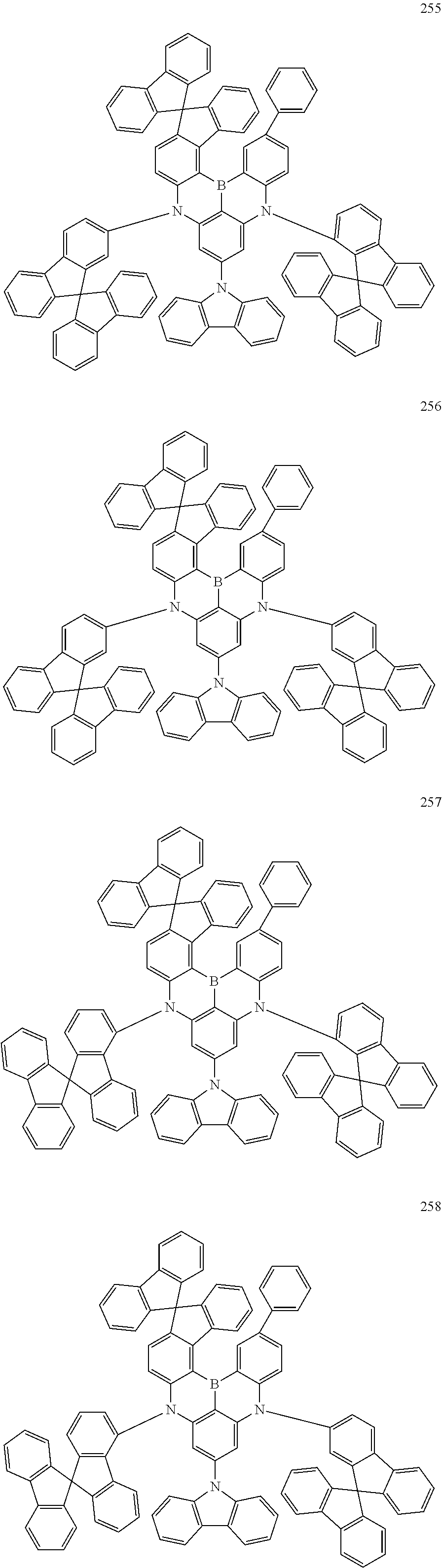 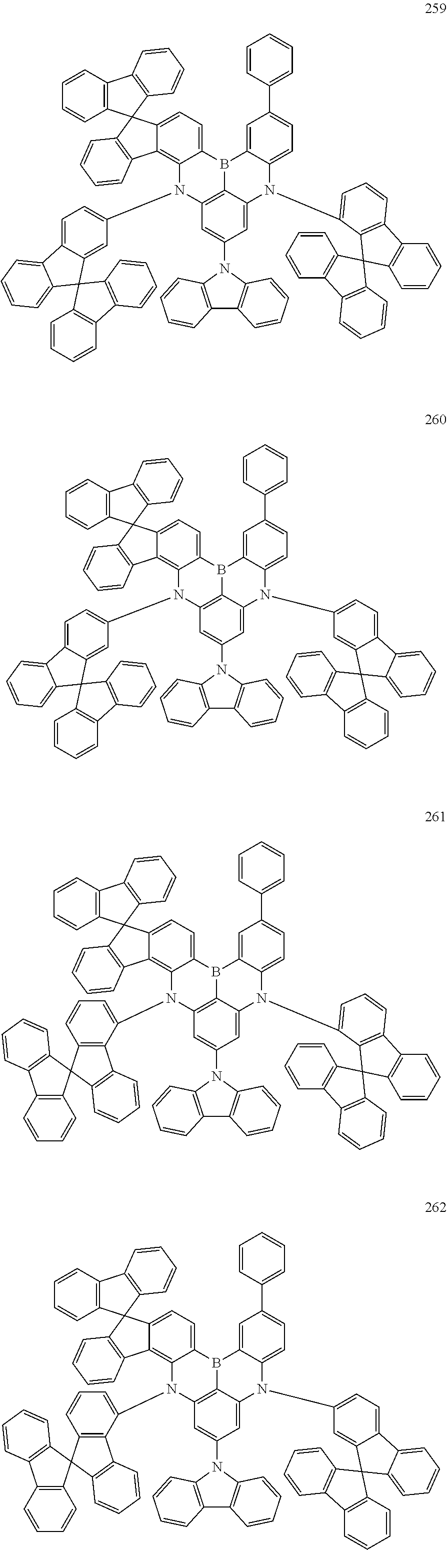 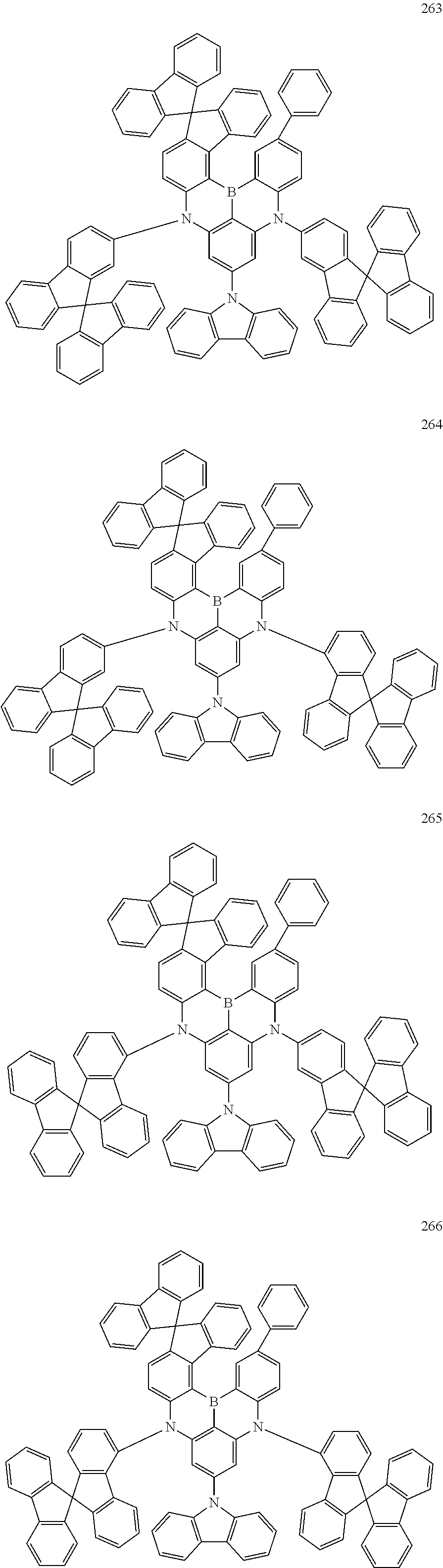 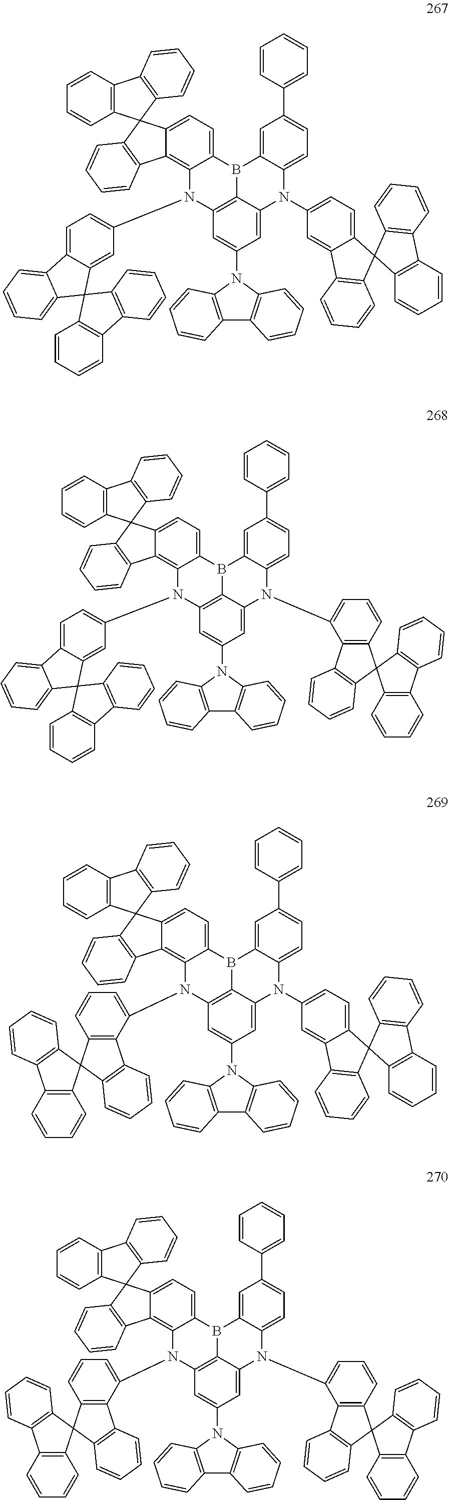 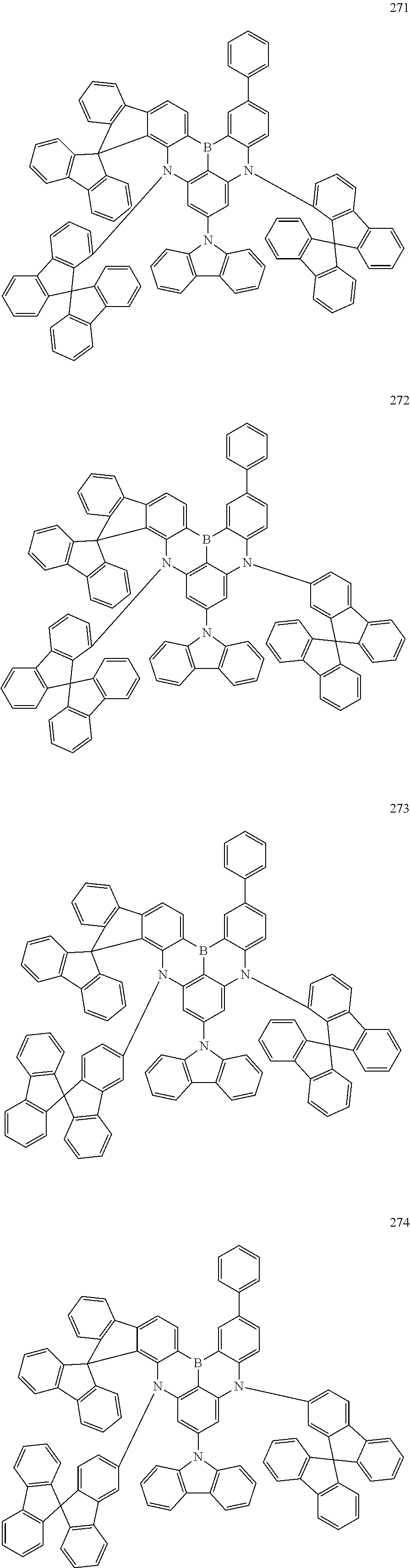 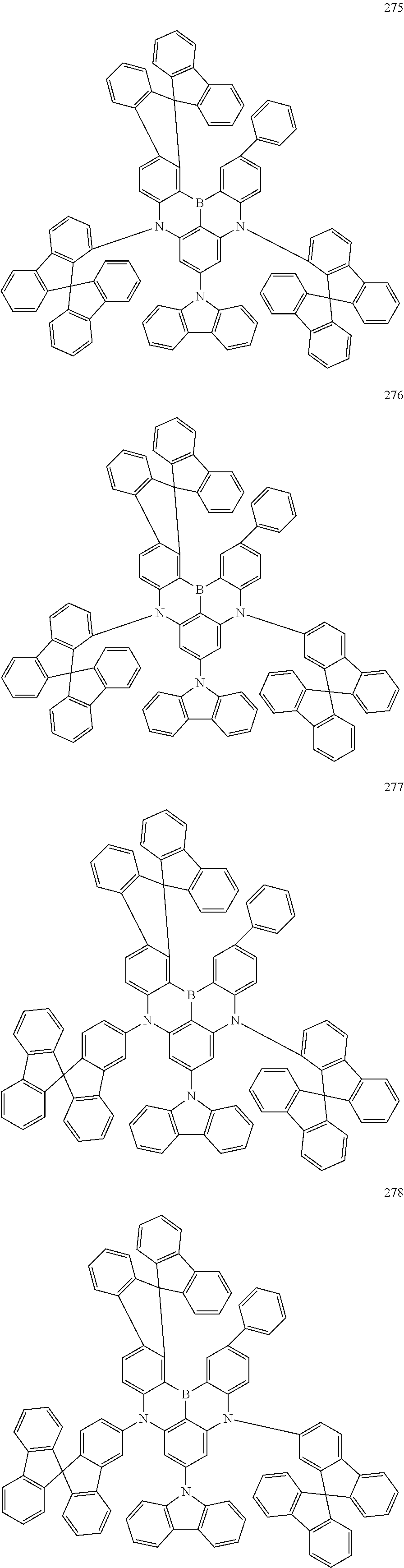 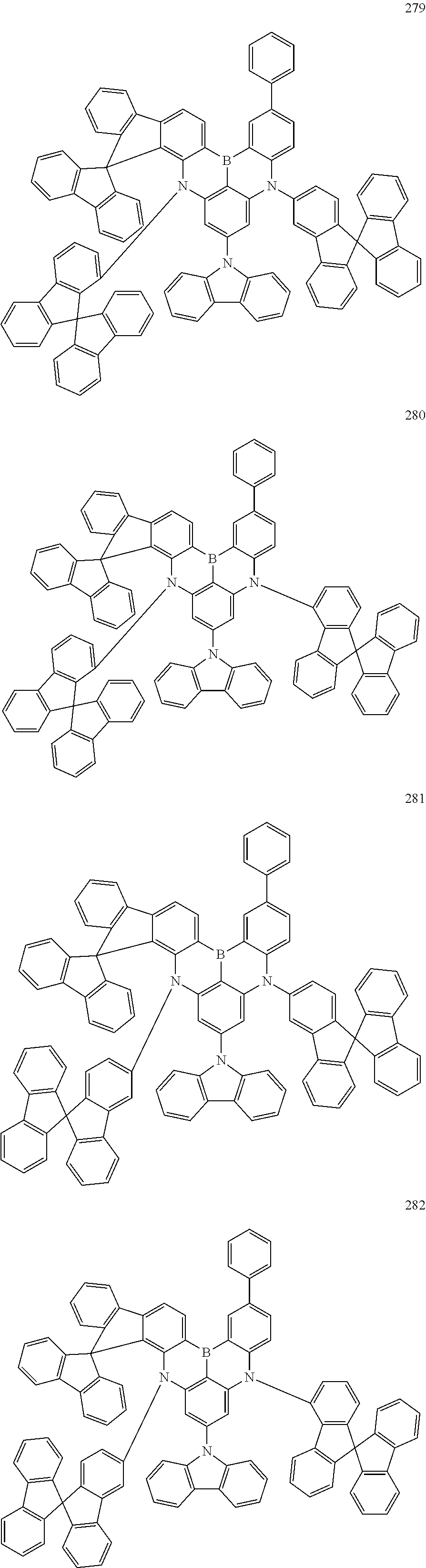 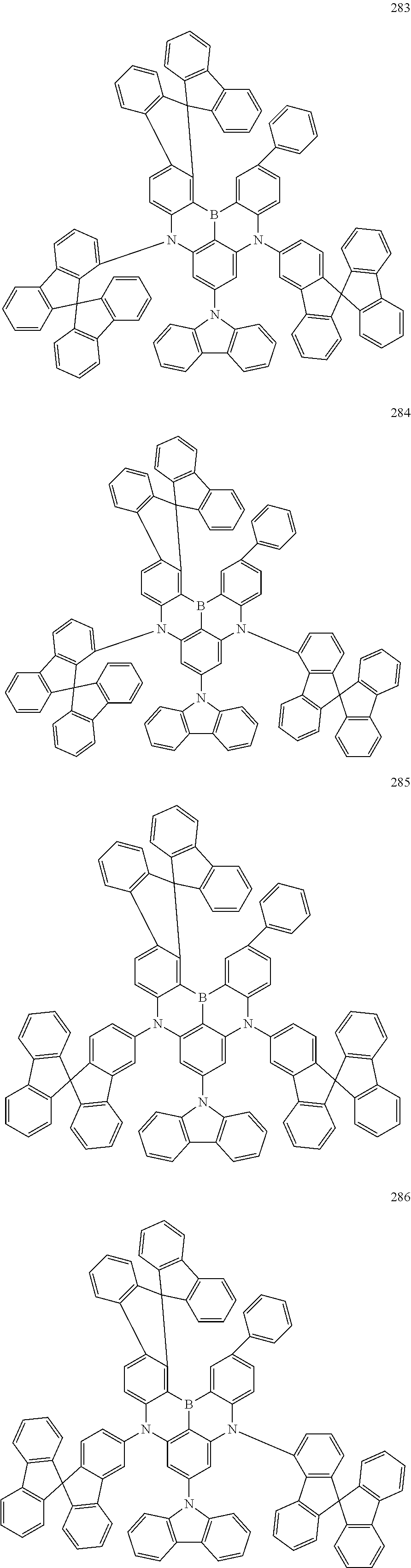 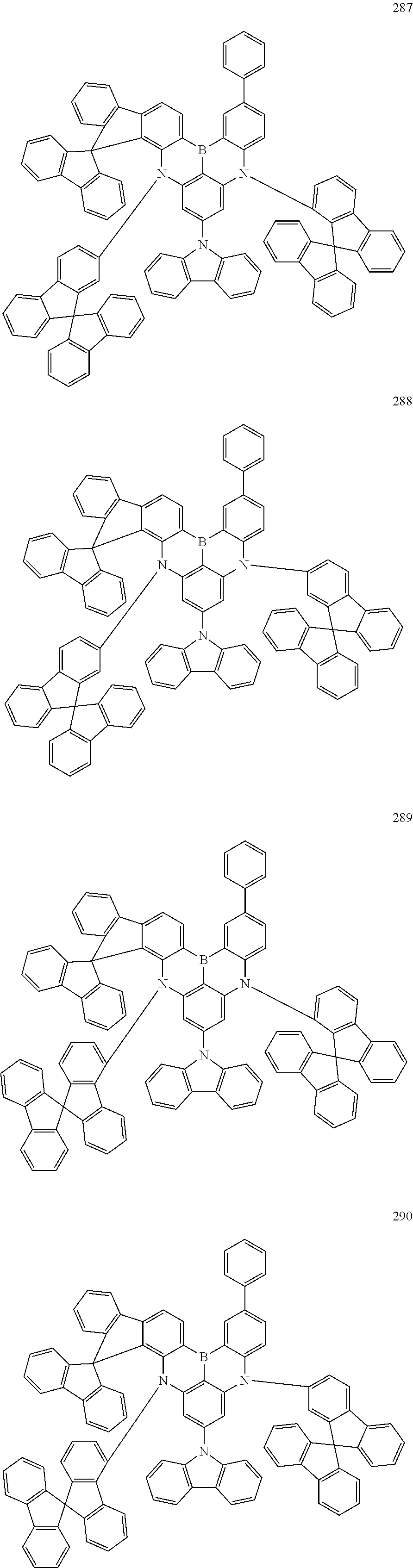 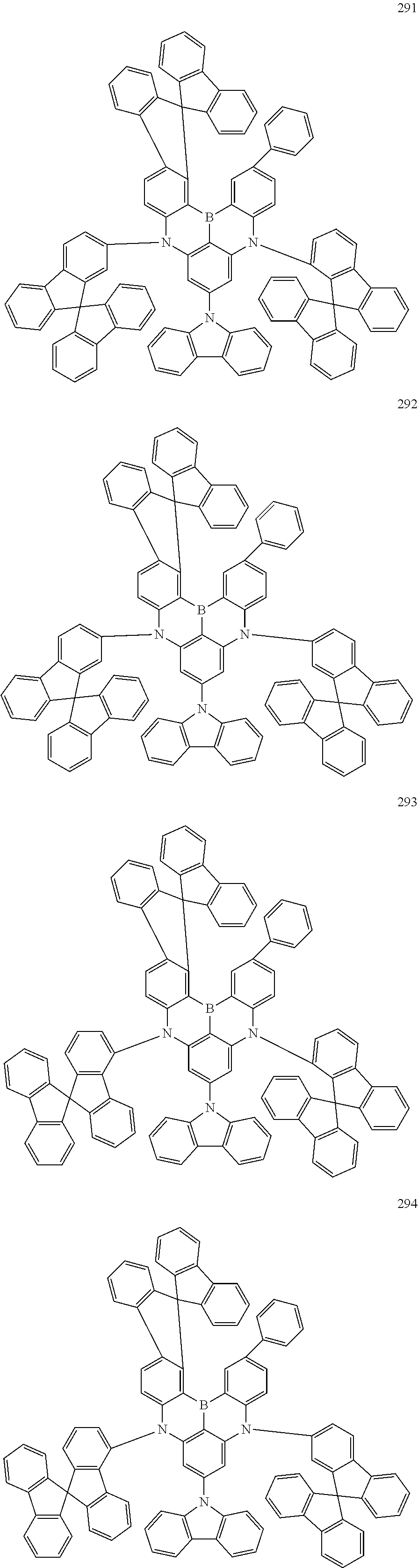 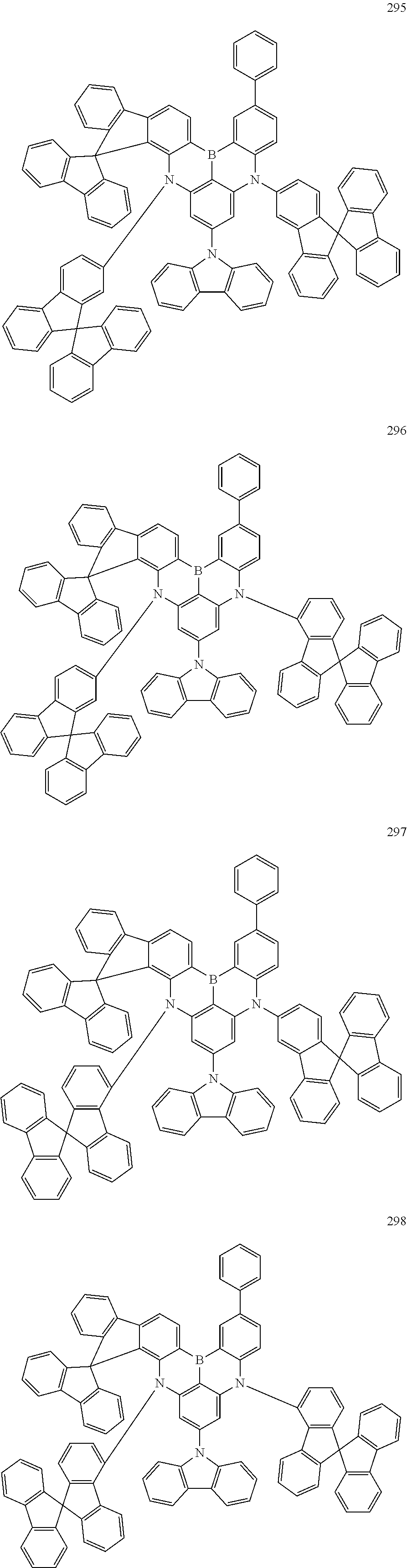 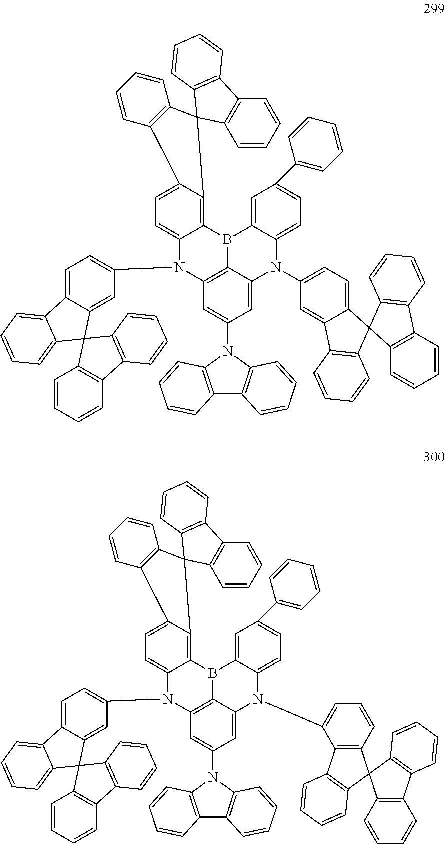 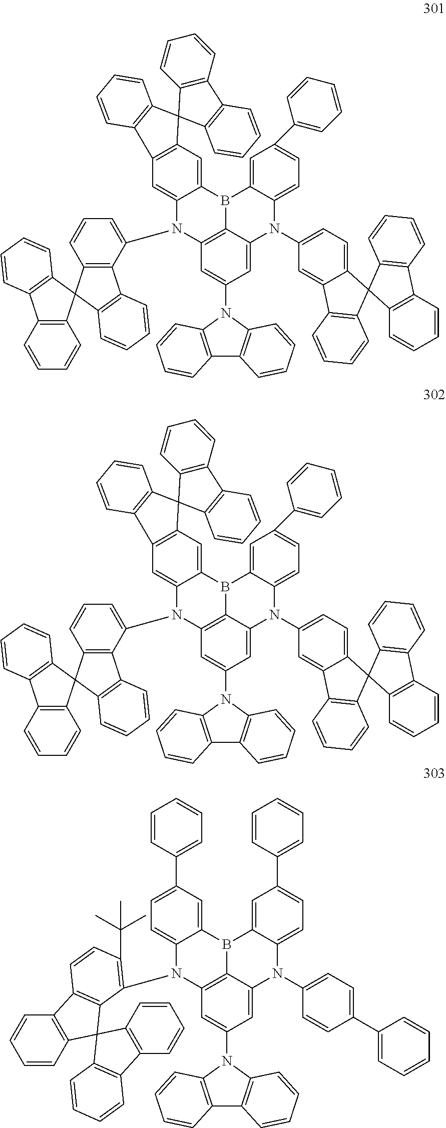 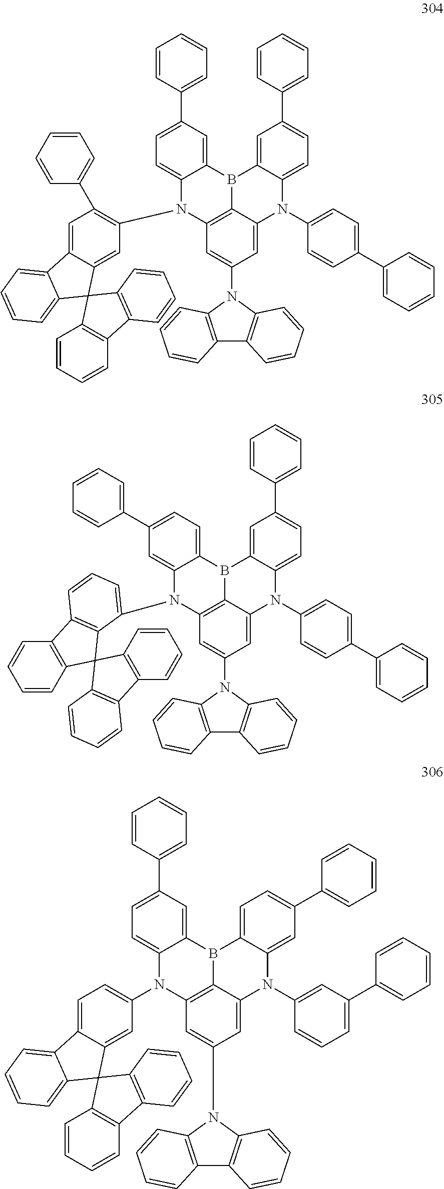 [SMILES: c1ccc(-c2ccc(N3c4ccc(-c5ccccc5)cc4B4c5cc(-c6ccccc6)ccc5N(c5cc6c(cc5-c5ccccc5)-c5ccccc5C65c6ccccc6-c6ccccc65)c5cc(-n6c7ccccc7c7ccccc76)cc3c54)cc2)cc1 ; c1ccc(-c2ccc(N3c4ccc(-c5ccccc5)cc4B4c5ccc(-c6ccccc6)cc5N(c5cccc6c5C5(c7ccccc7-c7ccccc75)c5ccccc5-6)c5cc(-n6c7ccccc7c7ccccc76)cc3c54)cc2)cc1 ; c1ccc(-c2cccc(N3c4cc(-c5ccccc5)ccc4B4c5cc(-c6ccccc6)ccc5N(c5ccc6c(c5)C5(c7ccccc7-c7ccccc75)c5ccccc5-6)c5cc(-n6c7ccccc7c7ccccc76)cc3c54)c2)cc1] 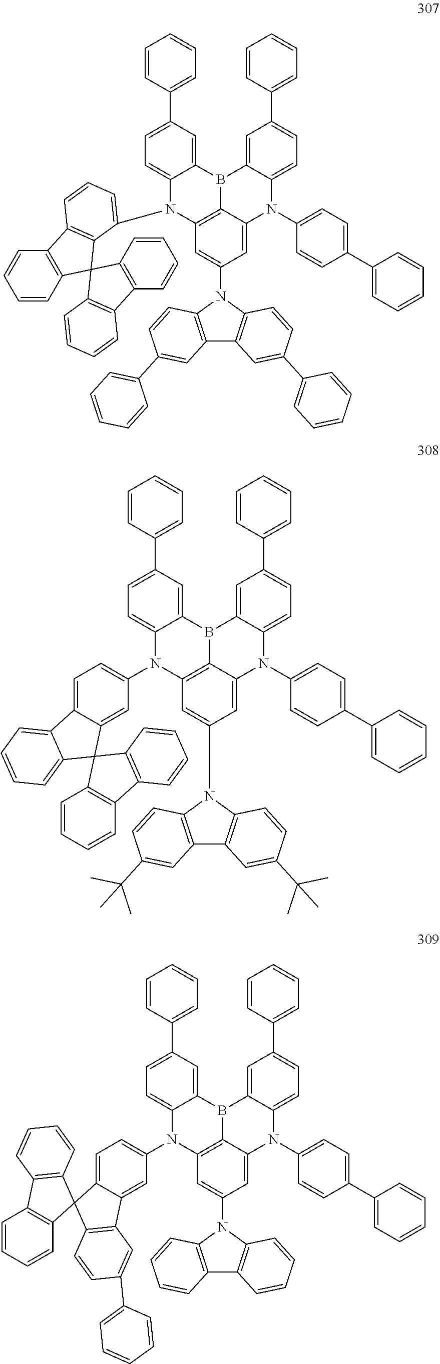 [SMILES: c1ccc(-c2ccc(N3c4ccc(-c5ccccc5)cc4B4c5cc(-c6ccccc6)ccc5N(c5cccc6c5C5(c7ccccc7-c7ccccc75)c5ccccc5-6)c5cc(-n6c7ccc(-c8ccccc8)cc7c7cc(-c8ccccc8)ccc76)cc3c54)cc2)cc1 ; CC(C)(C)c1ccc2c(c1)c1cc(C(C)(C)C)ccc1n2-c1cc2c3c(c1)N(c1ccc4c(c1)C1(c5ccccc5-c5ccccc51)c1ccccc1-4)c1ccc(-c4ccccc4)cc1B3c1cc(-c3ccccc3)ccc1N2c1ccc(-c2ccccc2)cc1 ; c1ccc(-c2ccc(N3c4ccc(-c5ccccc5)cc4B4c5cc(-c6ccccc6)ccc5N(c5ccc6c(c5)-c5cc(-c7ccccc7)ccc5C65c6ccccc6-c6ccccc65)c5cc(-n6c7ccccc7c7ccccc76)cc3c54)cc2)cc1] 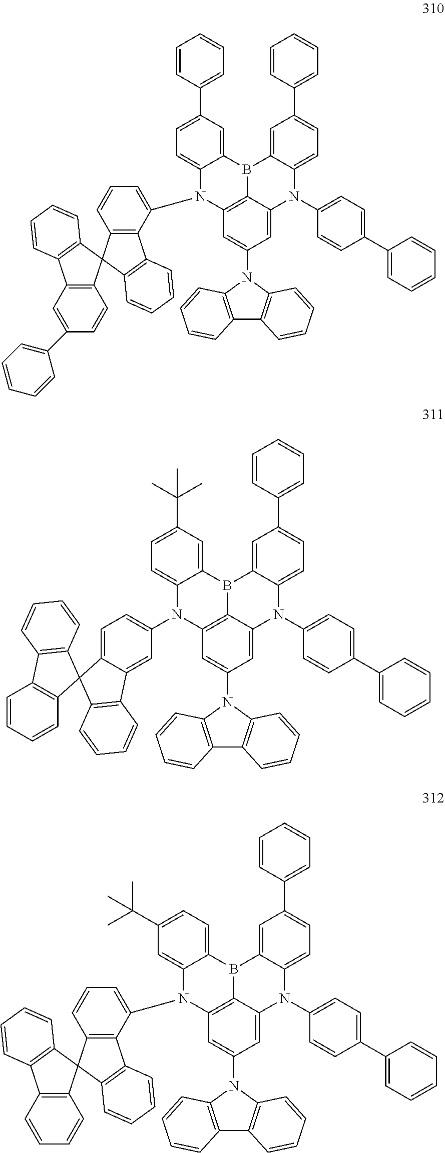 [SMILES: c1ccc(-c2ccc(N3c4ccc(-c5ccccc5)cc4B4c5cc(-c6ccccc6)ccc5N(c5cccc6c5-c5ccccc5C65c6ccccc6-c6cc(-c7ccccc7)ccc65)c5cc(-n6c7ccccc7c7ccccc76)cc3c54)cc2)cc1 ; CC(C)(C)c1ccc2c(c1)B1c3cc(-c4ccccc4)ccc3N(c3ccc(-c4ccccc4)cc3)c3cc(-n4c5ccccc5c5ccccc54)cc(c31)N2c1ccc2c(c1)-c1ccccc1C21c2ccccc2-c2ccccc21 ; CC(C)(C)c1ccc2c(c1)N(c1cccc3c1-c1ccccc1C31c3ccccc3-c3ccccc31)c1cc(-n3c4ccccc4c4ccccc43)cc3c1B2c1cc(-c2ccccc2)ccc1N3c1ccc(-c2ccccc2)cc1] 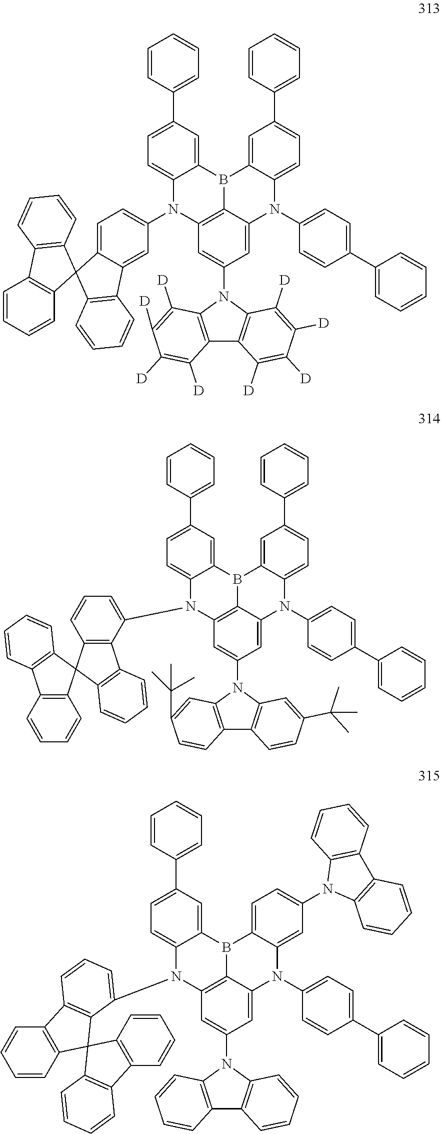 [SMILES: [2H]c1c([2H])c([2H])c2c(c1[2H])c1c([2H])c([2H])c([2H])c([2H])c1n2-c1cc2c3c(c1)N(c1ccc4c(c1)-c1ccccc1C41c4ccccc4-c4ccccc41)c1ccc(-c4ccccc4)cc1B3c1cc(-c3ccccc3)ccc1N2c1ccc(-c2ccccc2)cc1 ; CC(C)(C)c1ccc2c3ccc(C(C)(C)C)cc3n(-c3cc4c5c(c3)N(c3cccc6c3-c3ccccc3C63c6ccccc6-c6ccccc63)c3ccc(-c6ccccc6)cc3B5c3cc(-c5ccccc5)ccc3N4c3ccc(-c4ccccc4)cc3)c2c1 ; c1ccc(-c2ccc(N3c4cc(-n5c6ccccc6c6ccccc65)ccc4B4c5cc(-c6ccccc6)ccc5N(c5cccc6c5C5(c7ccccc7-c7ccccc75)c5ccccc5-6)c5cc(-n6c7ccccc7c7ccccc76)cc3c54)cc2)cc1] 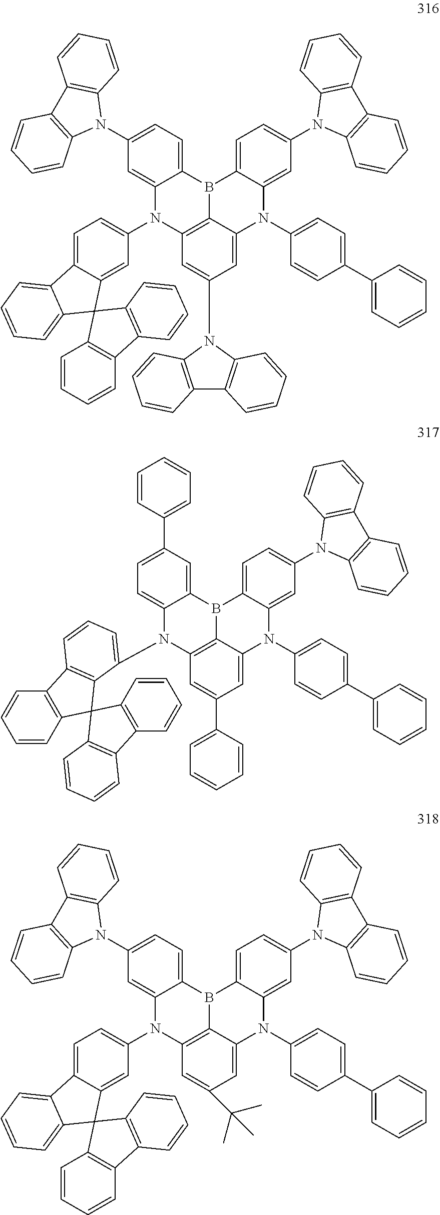 [SMILES: c1ccc(-c2ccc(N3c4cc(-n5c6ccccc6c6ccccc65)ccc4B4c5ccc(-n6c7ccccc7c7ccccc76)cc5N(c5ccc6c(c5)C5(c7ccccc7-c7ccccc75)c5ccccc5-6)c5cc(-n6c7ccccc7c7ccccc76)cc3c54)cc2)cc1 ; c1ccc(-c2ccc(N3c4cc(-n5c6ccccc6c6ccccc65)ccc4B4c5cc(-c6ccccc6)ccc5N(c5cccc6c5C5(c7ccccc7-c7ccccc75)c5ccccc5-6)c5cc(-c6ccccc6)cc3c54)cc2)cc1 ; CC(C)(C)c1cc2c3c(c1)N(c1ccc4c(c1)C1(c5ccccc5-c5ccccc51)c1ccccc1-4)c1cc(-n4c5ccccc5c5ccccc54)ccc1B3c1ccc(-n3c4ccccc4c4ccccc43)cc1N2c1ccc(-c2ccccc2)cc1] 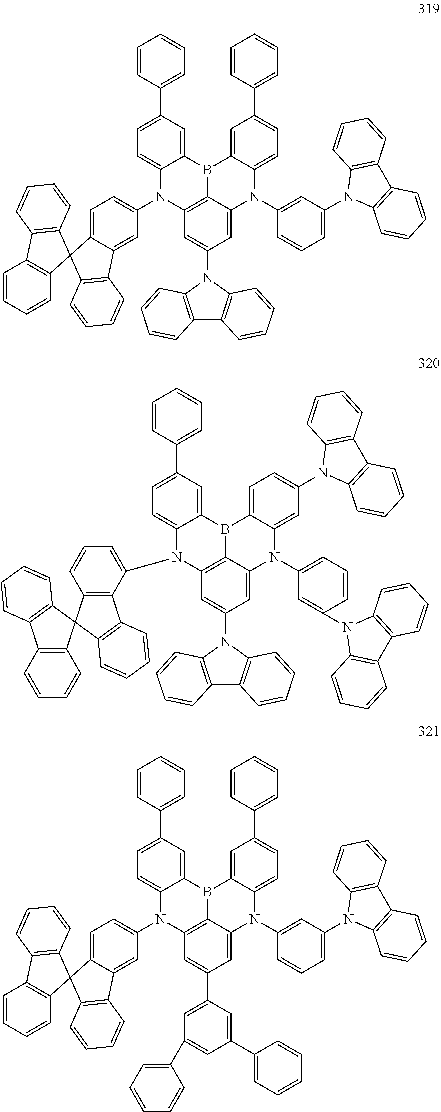 [SMILES: c1ccc(-c2ccc3c(c2)B2c4cc(-c5ccccc5)ccc4N(c4ccc5c(c4)-c4ccccc4C54c5ccccc5-c5ccccc54)c4cc(-n5c6ccccc6c6ccccc65)cc(c42)N3c2cccc(-n3c4ccccc4c4ccccc43)c2)cc1 ; c1ccc(-c2ccc3c(c2)B2c4ccc(-n5c6ccccc6c6ccccc65)cc4N(c4cccc(-n5c6ccccc6c6ccccc65)c4)c4cc(-n5c6ccccc6c6ccccc65)cc(c42)N3c2cccc3c2-c2ccccc2C32c3ccccc3-c3ccccc32)cc1 ; c1ccc(-c2cc(-c3ccccc3)cc(-c3cc4c5c(c3)N(c3ccc6c(c3)-c3ccccc3C63c6ccccc6-c6ccccc63)c3ccc(-c6ccccc6)cc3B5c3cc(-c5ccccc5)ccc3N4c3cccc(-n4c5ccccc5c5ccccc54)c3)c2)cc1] 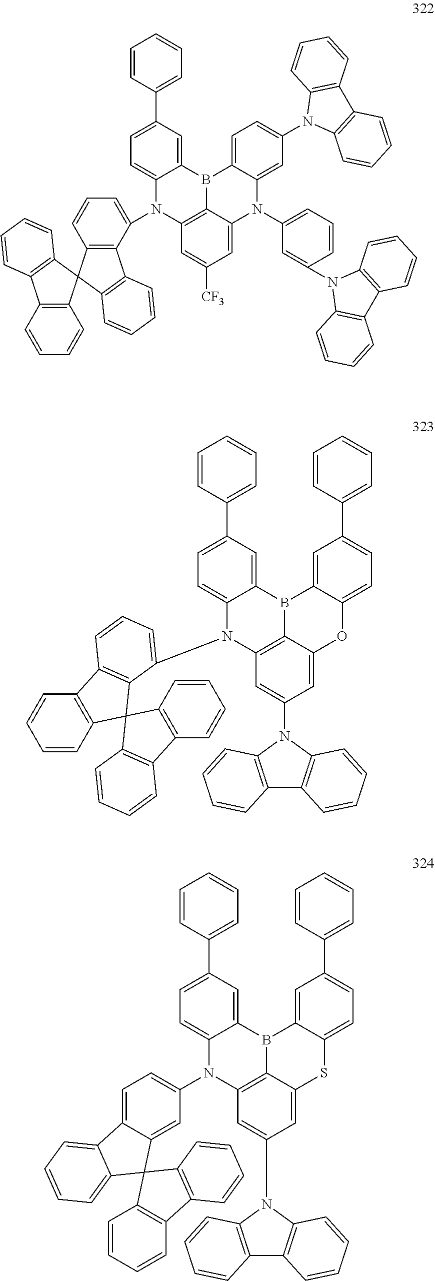 [SMILES: FC(F)(F)c1cc2c3c(c1)N(c1cccc4c1-c1ccccc1C41c4ccccc4-c4ccccc41)c1ccc(-c4ccccc4)cc1B3c1ccc(-n3c4ccccc4c4ccccc43)cc1N2c1cccc(-n2c3ccccc3c3ccccc32)c1 ; c1ccc(-c2ccc3c(c2)B2c4cc(-c5ccccc5)ccc4N(c4cccc5c4C4(c6ccccc6-c6ccccc64)c4ccccc4-5)c4cc(-n5c6ccccc6c6ccccc65)cc(c42)O3)cc1 ; c1ccc(-c2ccc3c(c2)B2c4cc(-c5ccccc5)ccc4N(c4ccc5c(c4)C4(c6ccccc6-c6ccccc64)c4ccccc4-5)c4cc(-n5c6ccccc6c6ccccc65)cc(c42)S3)cc1] 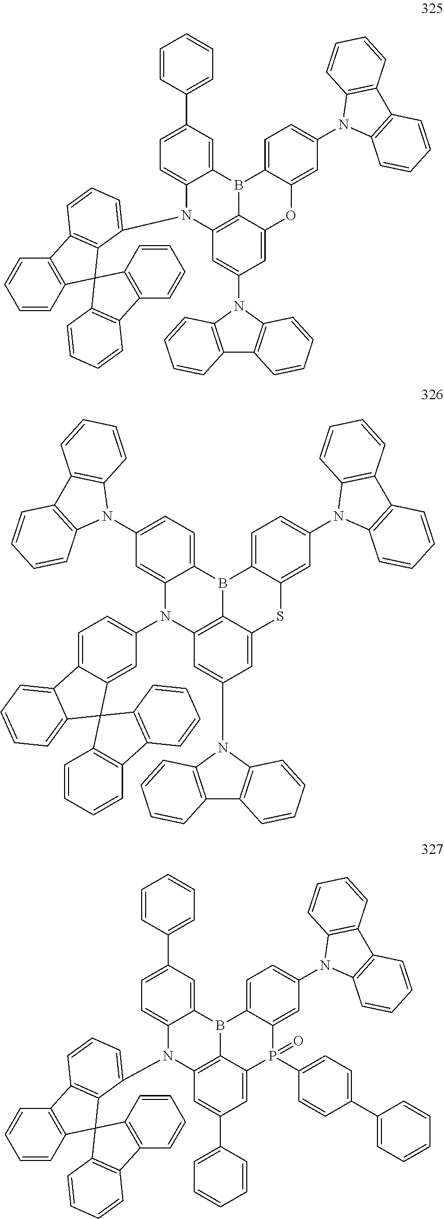 [SMILES: c1ccc(-c2ccc3c(c2)B2c4ccc(-n5c6ccccc6c6ccccc65)cc4Oc4cc(-n5c6ccccc6c6ccccc65)cc(c42)N3c2cccc3c2C2(c4ccccc4-c4ccccc42)c2ccccc2-3)cc1 ; c1ccc2c(c1)-c1ccccc1C21c2ccccc2-c2ccc(N3c4cc(-n5c6ccccc6c6ccccc65)ccc4B4c5ccc(-n6c7ccccc7c7ccccc76)cc5Sc5cc(-n6c7ccccc7c7ccccc76)cc3c54)cc21 ; O=P1(c2ccc(-c3ccccc3)cc2)c2cc(-n3c4ccccc4c4ccccc43)ccc2B2c3cc(-c4ccccc4)ccc3N(c3cccc4c3C3(c5ccccc5-c5ccccc53)c3ccccc3-4)c3cc(-c4ccccc4)cc1c32] 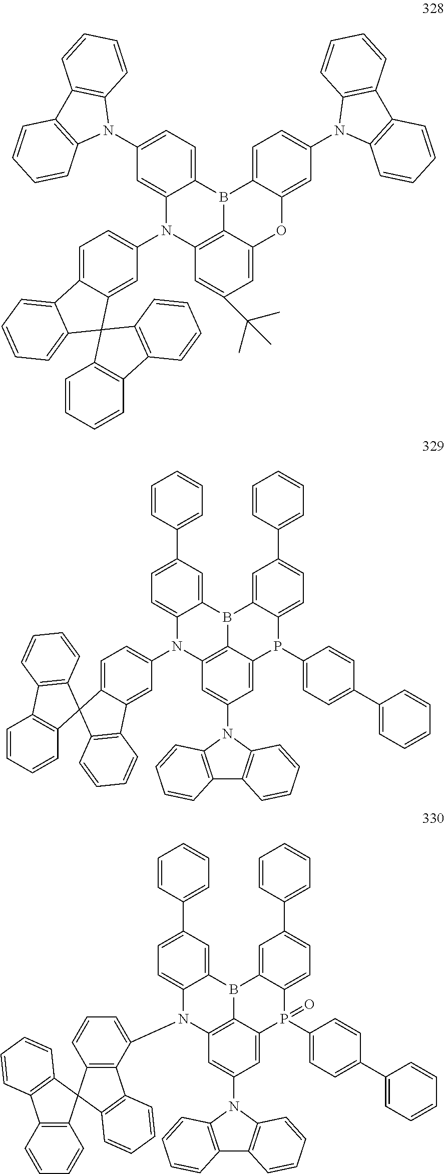 [SMILES: CC(C)(C)c1cc2c3c(c1)N(c1ccc4c(c1)C1(c5ccccc5-c5ccccc51)c1ccccc1-4)c1cc(-n4c5ccccc5c5ccccc54)ccc1B3c1ccc(-n3c4ccccc4c4ccccc43)cc1O2 ; c1ccc(-c2ccc(P3c4ccc(-c5ccccc5)cc4B4c5cc(-c6ccccc6)ccc5N(c5ccc6c(c5)-c5ccccc5C65c6ccccc6-c6ccccc65)c5cc(-n6c7ccccc7c7ccccc76)cc3c54)cc2)cc1 ; O=P1(c2ccc(-c3ccccc3)cc2)c2ccc(-c3ccccc3)cc2B2c3cc(-c4ccccc4)ccc3N(c3cccc4c3-c3ccccc3C43c4ccccc4-c4ccccc43)c3cc(-n4c5ccccc5c5ccccc54)cc1c32] 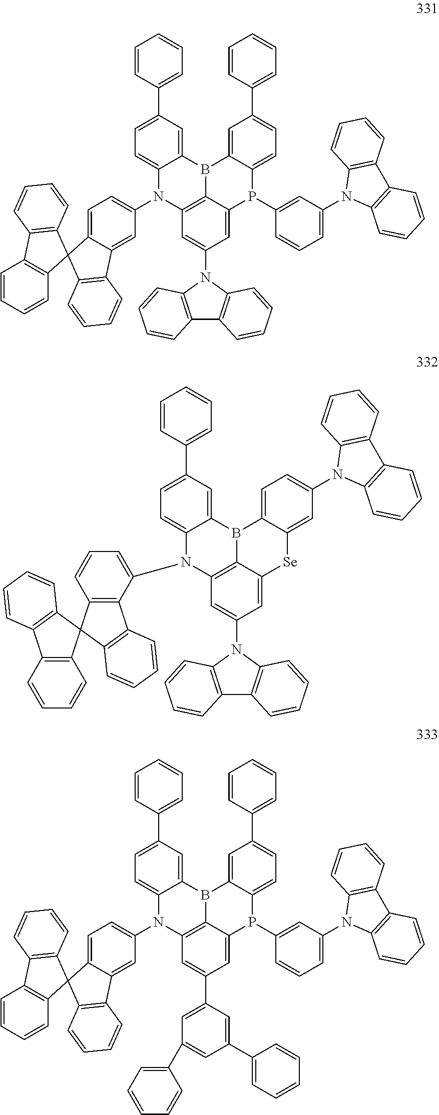 [SMILES: c1ccc(-c2ccc3c(c2)B2c4cc(-c5ccccc5)ccc4P(c4cccc(-n5c6ccccc6c6ccccc65)c4)c4cc(-n5c6ccccc6c6ccccc65)cc(c42)N3c2ccc3c(c2)-c2ccccc2C32c3ccccc3-c3ccccc32)cc1 ; c1ccc(-c2ccc3c(c2)B2c4ccc(-n5c6ccccc6c6ccccc65)cc4[Se]c4cc(-n5c6ccccc6c6ccccc65)cc(c42)N3c2cccc3c2-c2ccccc2C32c3ccccc3-c3ccccc32)cc1 ; c1ccc(-c2cc(-c3ccccc3)cc(-c3cc4c5c(c3)P(c3cccc(-n6c7ccccc7c7ccccc76)c3)c3ccc(-c6ccccc6)cc3B5c3cc(-c5ccccc5)ccc3N4c3ccc4c(c3)-c3ccccc3C43c4ccccc4-c4ccccc43)c2)cc1] 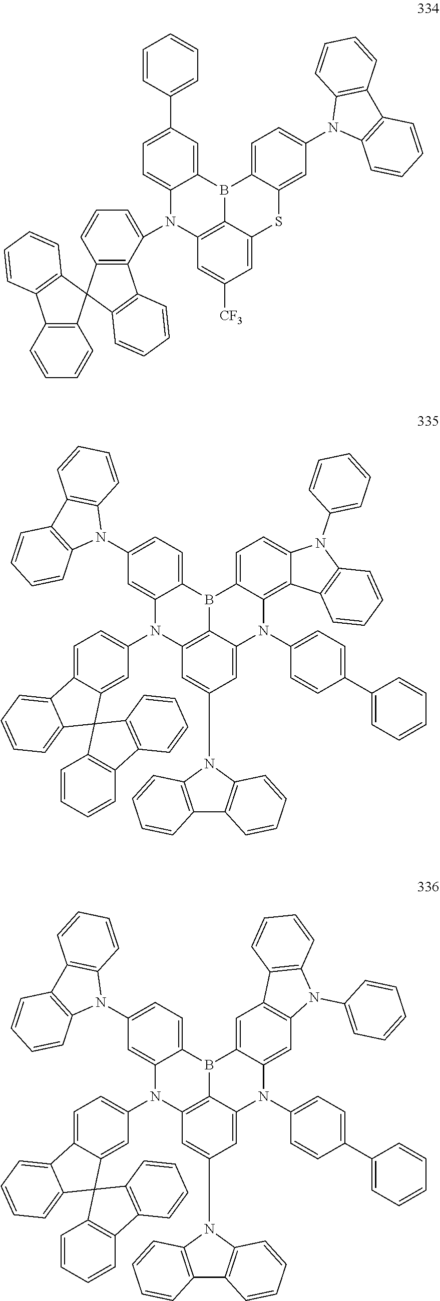 [SMILES: FC(F)(F)c1cc2c3c(c1)N(c1cccc4c1-c1ccccc1C41c4ccccc4-c4ccccc41)c1ccc(-c4ccccc4)cc1B3c1ccc(-n3c4ccccc4c4ccccc43)cc1S2 ; c1ccc(-c2ccc(N3c4cc(-n5c6ccccc6c6ccccc65)cc5c4B(c4ccc(-n6c7ccccc7c7ccccc76)cc4N5c4ccc5c(c4)C4(c6ccccc6-c6ccccc64)c4ccccc4-5)c4ccc5c(c43)c3ccccc3n5-c3ccccc3)cc2)cc1 ; c1ccc(-c2ccc(N3c4cc5c(cc4B4c6ccc(-n7c8ccccc8c8ccccc87)cc6N(c6ccc7c(c6)C6(c8ccccc8-c8ccccc86)c6ccccc6-7)c6cc(-n7c8ccccc8c8ccccc87)cc3c64)c3ccccc3n5-c3ccccc3)cc2)cc1] 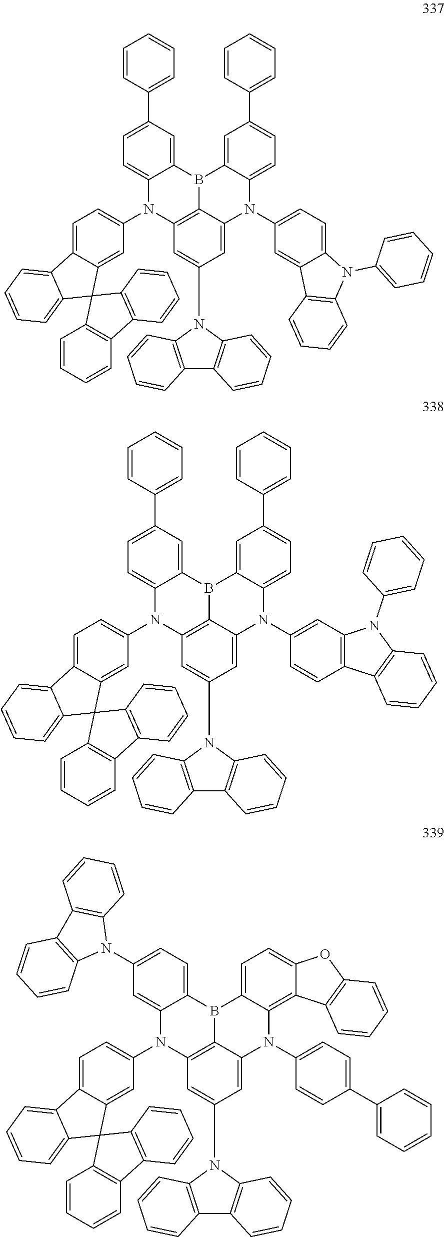 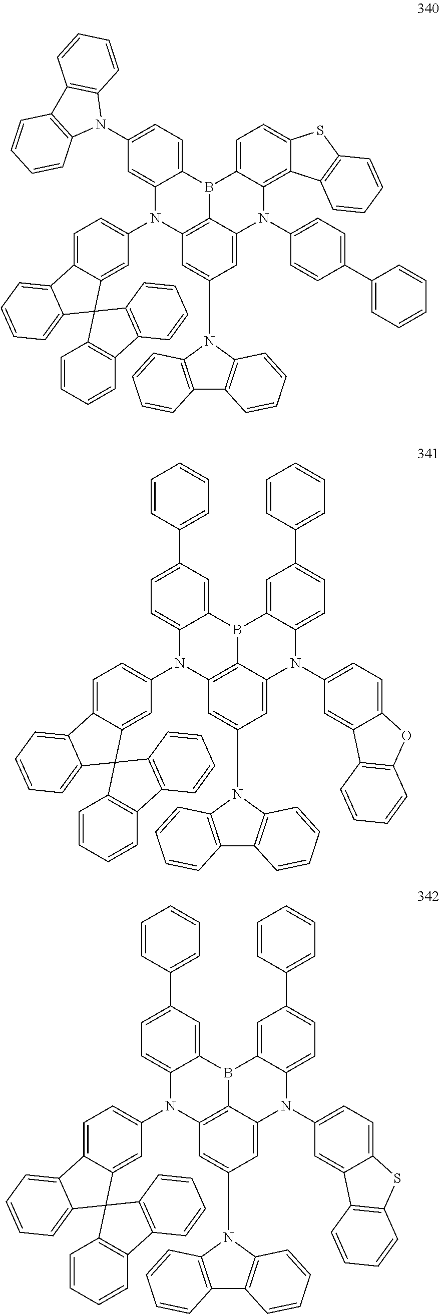 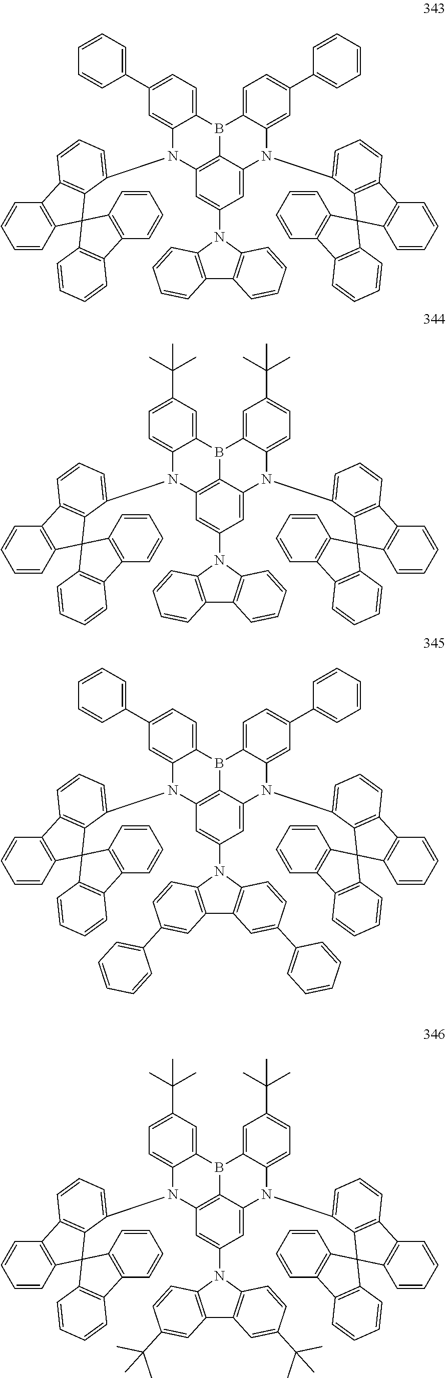 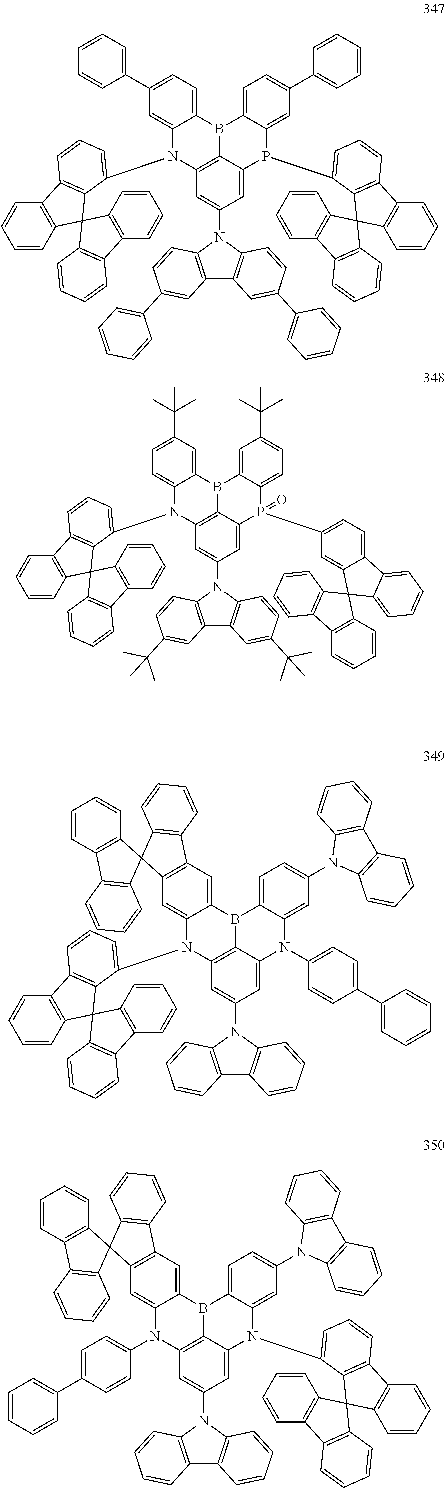 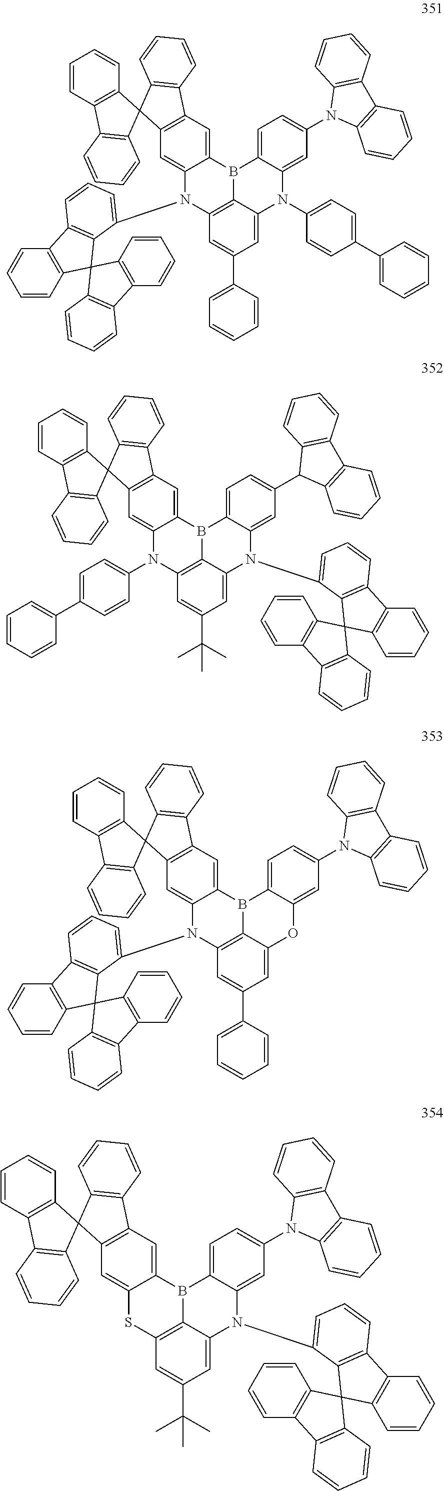 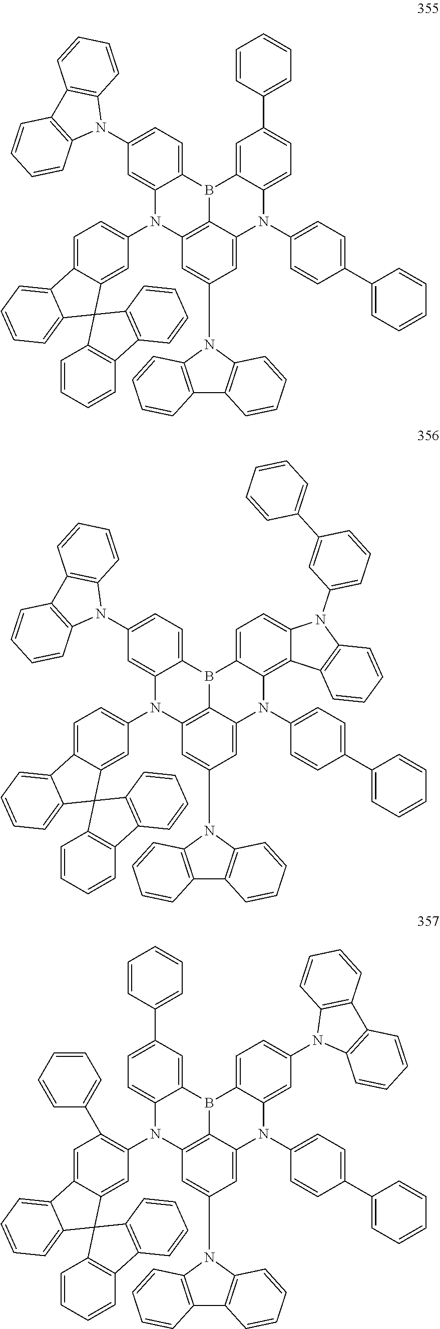 [SMILES: c1ccc(-c2ccc(N3c4ccc(-c5ccccc5)cc4B4c5ccc(-n6c7ccccc7c7ccccc76)cc5N(c5ccc6c(c5)C5(c7ccccc7-c7ccccc75)c5ccccc5-6)c5cc(-n6c7ccccc7c7ccccc76)cc3c54)cc2)cc1 ; c1ccc(-c2ccc(N3c4cc(-n5c6ccccc6c6ccccc65)cc5c4B(c4ccc(-n6c7ccccc7c7ccccc76)cc4N5c4ccc5c(c4)C4(c6ccccc6-c6ccccc64)c4ccccc4-5)c4ccc5c(c43)c3ccccc3n5-c3cccc(-c4ccccc4)c3)cc2)cc1 ; c1ccc(-c2ccc(N3c4cc(-n5c6ccccc6c6ccccc65)ccc4B4c5cc(-c6ccccc6)ccc5N(c5cc6c(cc5-c5ccccc5)-c5ccccc5C65c6ccccc6-c6ccccc65)c5cc(-n6c7ccccc7c7ccccc76)cc3c54)cc2)cc1] [chemical structure]
